(19) United States
(12) Patent Application Publication
(10) Pub. No.: US 2026/0149422 A1
(43) Pub. Date: May 28, 2026

(54) AMPLIFIER CIRCUIT, COMPARATOR, AND SOLID-STATE IMAGING DEVICE

(71) Applicant: SONY SEMICONDUCTOR SOLUTIONS CORPORATION, KANAGAWA (JP)

(72) Inventors: KAZUKI NOMOTO, KANAGAWA (JP); RUITO AIBA, KANAGAWA (JP); MASAAKI BAIRO, KANAGAWA (JP); HIDETOSHI OISHI, KANAGAWA (JP)

(21) Appl. No.: 19/122,037

(22) PCT Filed: Sep. 20, 2023
(86) PCT No.: PCT/JP2023/034083

§ 371 Date: Apr. 17, 2025

(30) Foreign Application Priority Data
Oct. 25, 2022 (JP) 2022-170970

(51) Int. Cl. H03F 3/45; H04N 25/772; H04N 25/778; H04N 25/79

(52) U.S. Cl. CPC H03F 3/45215; H04N 25/772; H04N 25/778; H04N 25/79

(57) ABSTRACT

An amplifier circuit, a comparator, and a solid-state imaging device capable of suppressing RTS noise are provided.

An amplifier circuit in the present disclosure includes an active load and a plurality of input transistors electrically connected to the active load, in which gates of the plurality of input transistors are electrically connected to each other, and the plurality of input transistors includes two or more input transistors connected in series with each other.

### TECHNICAL FIELD

The present disclosure relates to an amplifier circuit, a comparator, and a solid-state imaging device.

### BACKGROUND ART

Countermeasures against random vertical stripe noise generated in an image sensor or the like have been conventionally studied. The random vertical stripe noise is striped noise generated in an image. In addition, the random vertical stripe noise is caused by RTS noise (also referred to as random telegraph signal noise) of an input transistor or the like in a comparator.

A technique for suppressing RTS noise in a circuit of an image sensor including a comparator has been proposed. This signal processing device includes a short circuit unit capable of short-circuiting a gate of an amplification transistor to a potential that reduces a voltage between the gate and a source.

### CITATION LIST

### Patent Document

Patent Document 1: Japanese Patent Application No. 2016-545441

### SUMMARY OF THE INVENTION

### Problems to be Solved by the Invention

The signal processing device is not suitable for miniaturization of design area and low power consumption because the signal processing device includes a short circuit unit in a circuit.

The present disclosure, therefore, provides an amplifier circuit, a comparator, and a solid-state imaging device capable of suppressing RTS noise.

### Solutions to Problems

An amplifier circuit according to a first aspect of the present disclosure includes an active load and a plurality of input transistors electrically connected to the active load, in which gates of the plurality of input transistors are electrically connected to each other, and the plurality of input transistors includes two or more input transistors connected in series with each other. As a result, an input transistor on an active load side operates in a saturation region, and an input transistor on a ground side operates in a linear region. In the linear region, since carriers also pass through a place away from an oxide film interface, a probability of trapping or detrapping is reduced, and RTS noise improves.

Furthermore, in the first aspect, the two or more input transistors may include a first input transistor and a second input transistor having a drain electrically connected to a source of the first input transistor. As a result, an input transistor on an active load side operates in a saturation region, and an input transistor on a ground side operates in a linear region. In the linear region, since carriers also pass through a place away from an oxide film interface, a probability of trapping or detrapping is reduced, and RTS noise improves.

Furthermore, in the first aspect, the two or more input transistors may further include a third input transistor having a drain electrically connected to a source of the second input transistor. As a result, an input transistor on an active load side operates in a saturation region, and an input transistor on a ground side operates in a linear region. In the linear region, since carriers also pass through a place away from an oxide film interface, a probability of trapping or detrapping is reduced, and RTS noise improves.

Furthermore, in the first aspect, an active region that functions as the source of the first input transistor may be an active region different from an active region that functions as the drain of the second input transistor. As a result, an input transistor on an active load side operates in a saturation region, and an input transistor on a ground side operates in a linear region. In the linear region, since carriers also pass through a place away from an oxide film interface, a probability of trapping or detrapping is reduced, and RTS noise improves.

Furthermore, in the first aspect, an active region that functions as the source of the first input transistor may be a same active region as an active region that functions as the drain of the second input transistor. As a result, design area of the amplifier circuit is reduced, and transconductance characteristics can be improved. Furthermore, in a solid-state imaging device or the like using the amplifier circuit, high resolution based on further miniaturization can be achieved, or sensor characteristics can be improved while maintaining the number of pixels.

Furthermore, in the first aspect, the plurality of input transistors may include two or more input transistors of a first group connected in series with each other and two or more input transistors of a second group connected in series with each other, and all or a subset of the two or more input transistors of the first group and all or a subset of the two or more input transistors of the second group may be connected in parallel to each other. This increases gate width of the input transistors, thereby improving transconductance characteristics of the input transistors. As a result, thermal noise characteristics of the transistors improve, and the RTS noise improves.

Furthermore, in the first aspect, each of the plurality of input transistors may have a planar structure or a fin structure. As a result, controllability of gates of input transistors 3 improves, and the transconductance characteristics improve. As a result, thermal noise characteristics of the input transistors improve, and the RTS noise improves. Furthermore, by employing the fin type, an effect of an increase in a voltage threshold due to a substrate bias effect is suppressed, which improves the RTS noise.

Furthermore, in the first aspect, the two or more input transistors may include a first input transistor and a second input transistor having a gate length different from a gate length of the first input transistor. As a result, by reducing area of the input transistor in the saturation region connected to the active load, a probability of trapping or detrapping becomes lower than in a case where gate length of the input transistors connected in series with each other is equally divided. The RTS noise of the amplifier circuit, therefore, improves.

Furthermore, in the first aspect, the gate length of the first input transistor may be the shortest among the two or more input transistors, a drain of the first input transistor may be electrically connected to the active load and a first power supply, and a source of the second input transistor may be electrically connected to a second power supply. As a result, by reducing area of the input transistor in the saturation region connected to the active load, a probability of trapping or detrapping becomes lower than in a case where gate length of the input transistors connected in series with each other is equally divided. The RTS noise of the amplifier circuit, therefore, improves.

Furthermore, in the first aspect, the two or more input transistors may be NMOS and a voltage of the first power supply may be higher than a voltage of the second power supply, or the two or more input transistors may be PMOS and the voltage of the second power supply may be higher than the voltage of the first power supply. As a result, by reducing the area of the input transistor in the saturation region connected to the active load in the amplifier circuit, the probability of trapping or detrapping becomes lower than in a case where the gate length of the input transistors connected in series with each other is equally divided. The RTS noise of the amplifier circuit, therefore, improves.

Furthermore, in the first aspect, at least one of the two or more input transistors may have a voltage threshold different from voltage thresholds of others of the two or more input transistors. The amplifier circuit, therefore, improves the RTS noise by using input transistors of different voltage thresholds.

A comparator according to a second aspect of the present disclosure includes a first amplifier circuit to which a reference signal is input, a second amplifier circuit to which a comparison signal is input, and a tail portion that controls a tail current, the tail portion being electrically connected to the first amplifier circuit and the second amplifier circuit, in which each of the first amplifier circuit and the second amplifier circuit includes an active load and a plurality of input transistors electrically connected to the active load, gates of the plurality of input transistors are electrically connected to each other, and the plurality of input transistors may include two or more input transistors connected in series with each other. As a result, in the comparator, a signal/noise ratio (S/N ratio) improves as the RTS noise improves. As a result, random vertical stripe noise improves.

Furthermore, in the second aspect, the tail portion may include a plurality of transistors electrically connected to the first amplifier circuit and the second amplifier circuit, gates of the plurality of transistors of the tail portion may be electrically connected to each other, and the plurality of transistors of the tail portion may include two or more transistors connected in series with each other. As a result, the comparator can reduce RTS noise generated in the tail current control transistor. Improvement of the signal/noise ratio (S/N ratio) accompanying the reduction of the RTS noise leads to achievement of high image quality in the solid-state imaging device using the comparator or the like.

A solid-state imaging device according to a third aspect of the present disclosure includes a pixel array in which a plurality of pixels each including a photoelectric conversion unit is arranged in a matrix and an AD conversion unit that converts pixel signals output from the pixels of the pixel array from analog signals to digital signals, the AD conversion unit including a comparator, in which the comparator includes a first amplifier circuit to which a reference signal is input, a second amplifier circuit to which the analog signal is input as a comparison signal, and a tail portion that controls a tail current, the tail portion being electrically connected to the first amplifier circuit and the second amplifier circuit, each of the first amplifier circuit and the second amplifier circuit includes an active load, and a plurality of input transistors electrically connected to the active load, gates of the plurality of input transistors are electrically connected to each other, and the plurality of input transistors includes two or more input transistors connected in series with each other. As a result, in the solid-state imaging device, random vertical stripe noise improves, and the S/N ratio improves. Furthermore, it is possible to improve sensor characteristics, such as achievement of high resolution (miniaturization) without deterioration in characteristics.

Furthermore, in the third aspect, a first substrate provided with the photoelectric conversion unit and a pixel transistor and a second substrate provided with the comparator may be included. As a result, the stacked solid-state imaging device can reduce RTS noise generated from the comparator. Improvement of the S/N ratio accompanying the reduction of the RTS noise leads to achievement of high image quality in the stacked solid-state imaging device.

Furthermore, in the third aspect, a first substrate provided with the photoelectric conversion unit and a second substrate provided with a pixel transistor and the comparator may be included, and the first substrate and the second substrate may be stacked on each other with an insulating layer interposed therebetween. As a result, a 3D stacked solid-state imaging device can reduce RTS noise generated from the comparator. Improvement of the S/N ratio accompanying the reduction of the RTS noise leads to achievement of high image quality in the 3D stacked solid-state imaging device.

Furthermore, in the third aspect, the first substrate may be disposed on the second substrate. As a result, a 3D stacked solid-state imaging device can reduce RTS noise generated from the comparator. Improvement of the S/N ratio accompanying the reduction of the RTS noise leads to achievement of high image quality in the 3D stacked solid-state imaging device.

Furthermore, in the third aspect, a first substrate provided with the photoelectric conversion unit, a second substrate provided with a pixel transistor, and a third substrate provided with the comparator may be included, and the first substrate and the second substrate may be stacked on each other with an insulating layer interposed therebetween. As a result, a 3D stacked solid-state imaging device can reduce RTS noise generated from the comparator. Improvement of the S/N ratio accompanying the reduction of the RTS noise leads to achievement of high image quality in the 3D stacked solid-state imaging device.

Furthermore, in the third aspect, the first substrate may be disposed on the second substrate, and the second substrate may be disposed on the third substrate. As a result, a 3D stacked solid-state imaging device can reduce RTS noise generated from the comparator. Improvement of the S/N ratio accompanying the reduction of the RTS noise leads to achievement of high image quality in the 3D stacked solid-state imaging device.

Furthermore, in the third aspect, the solid-state imaging device may be provided in an electronic device that receives data output from the solid-state imaging device. As a result, random vertical stripe noise improves, and high resolution can be achieved.

### BRIEF DESCRIPTION OF DRAWINGS

FIG. 1 is an example of an amplifier circuit according to a first embodiment.

FIG. 2 is another example of the amplifier circuit according to the first embodiment.

FIG. 3 is still another example of the amplifier circuit according to the first embodiment.

FIG. 4 is an example of an amplifier circuit according to a second embodiment.

FIG. 5 is a cross-sectional view of the amplifier circuit according to the second embodiment.

FIG. 6 is another example of the amplifier circuit according to the second embodiment.

FIG. 7 is an example of an amplifier circuit according to a third embodiment.

FIG. 8 is an example of an amplifier circuit according to a fourth embodiment.

FIG. 9 is another example of the amplifier circuit according to the fourth embodiment.

FIG. 10 is an example of a comparator according to a fifth embodiment.

FIG. 11 is an example of a solid-state imaging device according to a sixth embodiment.

FIG. 12 is an example of a solid-state imaging device according to a seventh embodiment.

FIG. 13 is an example of a solid-state imaging device according to an eighth embodiment.

FIG. 14 is a cross-sectional view illustrating a structure of a solid-state imaging device according to a ninth embodiment.

FIG. 15 is a circuit diagram illustrating configuration of the solid-state imaging device according to the ninth embodiment.

FIG. 16 is a block diagram illustrating an example of a functional configuration of a solid-state imaging device according to a tenth embodiment.

FIG. 17 is a schematic plan view illustrating a schematic configuration of the imaging device illustrated in FIG. 16.

FIG. 18 is a schematic view illustrating a cross-sectional configuration taken along line III-III′ illustrated in FIG. 17.

FIG. 19 is an equivalent circuit diagram of a pixel sharing unit illustrated in FIG. 16.

FIG. 20 is a diagram illustrating an example of a connection mode between a plurality of pixel sharing units and a plurality of vertical signal lines.

FIG. 21 is a schematic cross-sectional view illustrating an example of a specific configuration of the imaging device illustrated in FIG. 18.

FIG. 22A is a schematic diagram illustrating an example of a planar configuration of a main part of a first substrate illustrated in FIG. 21.

FIG. 22B is a schematic diagram illustrating a planar configuration of pad portions together with the main part of the first substrate illustrated in FIG. 22A.

FIG. 23 is a schematic diagram illustrating an example of a planar configuration of a second substrate (semiconductor layer) illustrated in FIG. 21.

FIG. 24 is a schematic diagram illustrating an example of a planar configuration of main parts of a pixel circuit and the first substrate together with a first wiring layer illustrated in FIG. 21.

FIG. 25 is a schematic diagram illustrating an example of a planar configuration of the first wiring layer and a second wiring layer illustrated in FIG. 21.

FIG. 26 is a schematic diagram illustrating an example of a planar configuration of the second wiring layer and a third wiring layer illustrated in FIG. 21.

FIG. 27 is a schematic diagram illustrating an example of a planar configuration of the third wiring layer and a fourth wiring layer illustrated in FIG. 21.

FIG. 28 is a schematic diagram for explaining paths of input signals to the imaging device illustrated in FIG. 18.

FIG. 29 is a schematic diagram for explaining signal paths of pixel signals of the imaging device illustrated in FIG. 18.

FIG. 30 is a schematic diagram illustrating a modification of the planar configuration of the second substrate (semiconductor layer) illustrated in FIG. 23.

FIG. 31 is a schematic diagram illustrating a planar configuration of main parts of a first wiring layer and a first substrate together with a pixel circuit illustrated in FIG. 30.

FIG. 32 is a schematic diagram illustrating an example of a planar configuration of a second wiring layer together with the first wiring layer illustrated in FIG. 31.

FIG. 33 is a schematic diagram illustrating an example of a planar configuration of a third wiring layer together with the second wiring layer illustrated in FIG. 32.

FIG. 34 is a schematic diagram illustrating an example of a planar configuration of a fourth wiring layer together with the third wiring layer illustrated in FIG. 33.

FIG. 35 is a schematic diagram illustrating a modification of the planar configuration of the first substrate illustrated in FIG. 22A.

FIG. 36 is a schematic diagram illustrating an example of a planar configuration of a second substrate (semiconductor layer) stacked on the first substrate illustrated in FIG. 35.

FIG. 37 is a schematic diagram illustrating an example of a planar configuration of a first wiring layer together with a pixel circuit illustrated in FIG. 36.

FIG. 38 is a schematic diagram illustrating an example of a planar configuration of a second wiring layer together with the first wiring layer illustrated in FIG. 37.

FIG. 39 is a schematic diagram illustrating an example of a planar configuration of a third wiring layer together with the second wiring layer illustrated in FIG. 38.

FIG. 40 is a schematic diagram illustrating an example of a planar configuration of a fourth wiring layer together with the third wiring layer illustrated in FIG. 39.

FIG. 41 is a schematic diagram illustrating another example of the planar configuration of the first substrate illustrated in FIG. 35.

FIG. 42 is a schematic diagram illustrating an example of a planar configuration of a second substrate (semiconductor layer) stacked on the first substrate illustrated in FIG. 41.

FIG. 43 is a schematic diagram illustrating an example of a planar configuration of a first wiring layer together with a pixel circuit illustrated in FIG. 42.

FIG. 44 is a schematic diagram illustrating an example of a planar configuration of a second wiring layer together with the first wiring layer illustrated in FIG. 43.

FIG. 45 is a schematic diagram illustrating an example of a planar configuration of a third wiring layer together with the second wiring layer illustrated in FIG. 44.

FIG. 46 is a schematic diagram illustrating an example of a planar configuration of a fourth wiring layer together with the third wiring layer illustrated in FIG. 45.

FIG. 47 is a schematic cross-sectional view illustrating another example of the imaging device illustrated in FIG. 18.

FIG. 48 is a schematic diagram for explaining paths of input signals to the imaging device illustrated in FIG. 47.

FIG. 49 is a schematic diagram for explaining signal paths of pixel signals of the imaging device illustrated in FIG. 47.

FIG. 50 is a schematic cross-sectional view illustrating another example of the imaging device illustrated in FIG. 21.

FIG. 51 is a diagram illustrating another example of an equivalent circuit illustrated in FIG. 19.

FIG. 52 is a schematic plan view illustrating another example of a pixel isolation portion illustrated in FIG. 22A and the like.

FIG. 53 is a diagram illustrating an example of a schematic configuration of an imaging system including the imaging device according to one of the above embodiments and the modifications thereof.

FIG. 54 is a diagram illustrating an example of an imaging procedure of the imaging system illustrated in FIG. 53.

FIG. 55 is a block diagram illustrating an example of a schematic configuration of a vehicle control system.

FIG. 56 is an explanatory diagram illustrating an example of installation positions of an outside-vehicle information detecting unit and an imaging section.

FIG. 57 is a diagram illustrating an example of a schematic configuration of an endoscopic surgery system.

FIG. 58 is a block diagram illustrating an example of a functional configuration of a camera head and a CCU.

### MODE FOR CARRYING OUT THE INVENTION

Embodiments of the present disclosure will be described hereinafter with reference to the drawings.

### First Embodiment

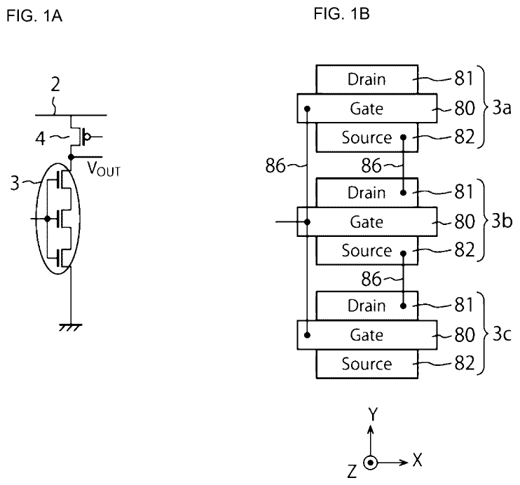

FIG. 1 is an example of an amplifier circuit according to a first embodiment.

FIG. 1A is a circuit diagram illustrating circuit configuration of the amplifier circuit, and FIG. 1B is a plan view illustrating a planar structure of the amplifier circuit.

FIG. 1B illustrates an X axis, a Y axis, and a Z axis perpendicular to each other. An X direction and a Y direction correspond to a lateral direction (horizontal direction), and a Z direction corresponds to a longitudinal direction (vertical direction). In addition, a +Z direction corresponds to an upward direction, and a −Z direction corresponds to a downward direction. Note that the −Z direction may strictly match a gravity direction, but need not necessarily strictly match the gravity direction.

An amplifier circuit 2 of FIG. 1A is a source-installed amplifier circuit 2 including an active load 4. The amplifier circuit 2 includes a plurality of NMOS input transistors 3 and a PMOS active load 4. FIG. 1B is a plan view of a part of the circuit diagram of FIG. 1A corresponding to the input transistors 3. In FIG. 1B, the three input transistors 3 will be referred to as an input transistor 3a, an input transistor 3b, and an input transistor 3c in order from the top. In the following description, the input transistor 3a is an example of a first input transistor of the present disclosure, the input transistor 3b is an example of a second input transistor of the present disclosure, and the input transistor 3c is an example of a third input transistor of the present disclosure.

For example, in a solid-state imaging device, the amplifier circuit 2 is used not only to amplify a pixel signal read from a pixel supply unit but also for a comparator of an AD converter (ADC). The comparator includes, for example, a differential pair circuit and a tail current control transistor (tail portion) electrically connected to the differential pair circuit. The amplifier circuit 2 is, for example, a differential pair circuit, and is used for amplification of a reference signal and amplification of a comparison signal. A reference signal amplifier circuit is an example of a first amplifier circuit of the present disclosure, and a comparison signal amplifier circuit is an example of a second amplifier circuit of the present disclosure.

In the amplifier circuit 2 of FIG. 1A, the input transistors 3 are provided in different active regions, and sources and drains are alternately connected in series with each other. For example, as illustrated in FIG. 1B, an active region that functions as a source 82 of the input transistor 3a is provided in a region different from an active region that functions as a drain 81 of the input transistor 3b, and these active regions are electrically connected to each other by a wire 86. An active region that functions as a source 82 of the input transistor 3b is provided in a region different from an active region that functions as a drain 81 of the input transistor 3c, and these active regions are electrically connected to each other by another wire 86. Furthermore, gates 80 of the input transistors 3 are connected to each other, and are electrically connected to each other by, for example, another wire 86. Furthermore, as illustrated in FIG. 1B, the drain 81, the gate 80, and the source 82 of each of the first to third input transistors 3a to 3c are linearly arranged in the Y-axis direction.

The number of these input transistors 3 is not limited to three, and any number of input transistors 3 may be connected in series with each other. For example, in a case where an input transistor 3d is added, it is conceivable that the source 82 of the input transistor 3c and a drain of the input transistor 3d are electrically connected in series with each other, and the gates 80 of the input transistors 3a to 3d are electrically connected to each other. Alternatively, the drain 81 of the input transistor 3a and a source of the input transistor 3d may be electrically connected in series with each other, and the gates 80 of the input transistors 3a to 3d may be electrically connected to each other. In addition, in the amplifier circuit 2, all the input transistors 3 need not be alternately arranged in series, and it is only required to include a structure in which two or more input transistors 3 are arranged in series with each other.

With the configuration of FIG. 1, an input transistor 3 on an active load 4 side (in this example, the input transistor 3a) operates in a saturation region, and an input transistor 3 on a ground side (in this example, the second and input transistor 3c) operates in a linear region. In the linear region, since carriers also pass through a place away from an oxide film interface, a probability of trapping or detrapping is reduced, and RTS noise improves.

Furthermore, by using the comparator including the amplifier circuit 2 of FIG. 1, a signal/noise ratio (S/N ratio) of the comparator improves as the RTS noise improves. As a result, random vertical stripe noise improves.

Furthermore, by using the solid-state imaging device including the comparator described above, the solid-state imaging device similarly improves random vertical stripe noise and the S/N ratio. Furthermore, it is possible to improve sensor characteristics, such as achievement of high resolution (miniaturization) without deterioration in characteristics.

Furthermore, by using the above-described solid-state imaging device for an electronic device, random vertical stripe noise improves, and high resolution can be achieved.

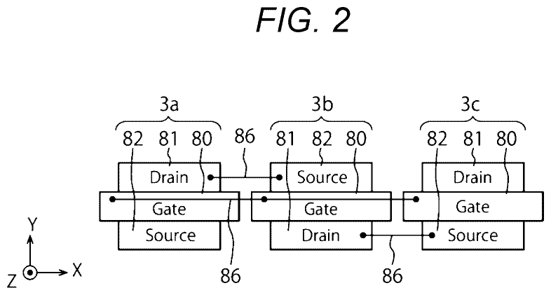

FIG. 2 is another example of the amplifier circuit 2 according to the first embodiment.

In the example of FIG. 2, three input transistors 3 will be referred to as an input transistor 3a, an input transistor 3b, and an input transistor 3c in order from the left. In the amplifier circuit 2 of FIG. 2, as in FIG. 1, the three input transistors 3 are provided in different active regions, and the drains 81 and the sources 82 are alternately connected in series with each other. For example, an active region that functions as the drain 81 of the input transistor 3a is provided in a region different from an active region that functions as the source 82 of the input transistor 3b, and these active regions are electrically connected to each other by a wire 86. An active region that functions as the drain 81 of the input transistor 3b is provided in a region different from an active region that functions as the source 82 of the input transistor 3c, and these active regions are electrically connected to each other by another wire.

In addition, unlike the configuration in FIG. 1, the drains 81 and the sources 82 of the input transistors 3 are connected in series with each other in the X-axis direction. In addition, gates 80 of the plurality of input transistors 3 are connected to each other. For example, the gates are electrically connected to each other by another wire 86. In this structure, the gates 80 of the input transistors 3 are linearly arranged in the X-axis direction, and constituted by one polysilicon or metal gate.

In addition, the number of these input transistors 3 is not limited to three, and any number of input transistors 3 may be connected to each other. In addition, in the amplifier circuit 2, all the input transistors 3 need not be alternately arranged in series, and it is only required to include a structure in which two or more input transistors 3 are arranged in series with each other.

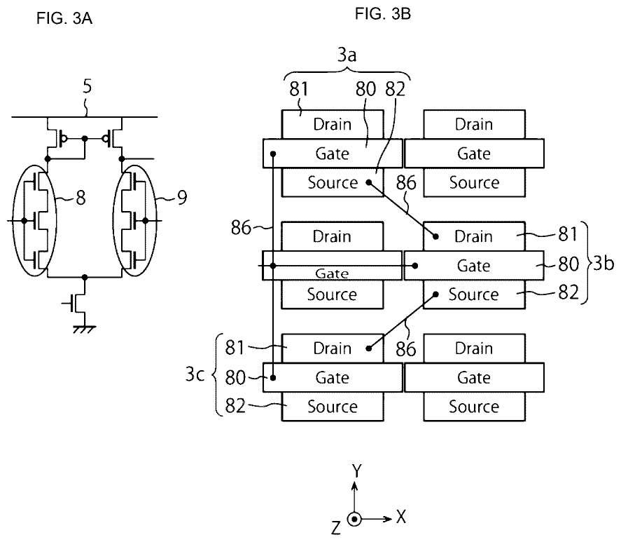

FIG. 3 is still another example of the amplifier circuit according to the first embodiment.

FIG. 3A is a circuit diagram of a comparator 5, and FIG. 3B is a plan view of a part of the circuit diagram corresponding to input transistors 3 in a reference signal amplifier circuit 8 and a comparison signal amplifier circuit 9.

As illustrated in FIG. 3B, in this example, the three input transistors 3 in the reference signal amplifier circuit 8 and the three input transistors 3 in the comparison signal amplifier circuit 9 in the comparator 5 are arranged in a staggered manner. Here, configuration of the reference signal amplifier circuit 8 will be described. In this example, the three input transistors 3 will be referred to as an input transistor 3a, an input transistor 3b, and an input transistor 3c in order from the top.

In the reference signal amplifier circuit 8, the three transistors are arranged in different active regions in a staggered manner, and sources 82 and drains 81 of the plurality of input transistors 3 are alternately connected to each other. For example, as illustrated in FIG. 3B, an active region that functions as the source 82 of the input transistor 3a is provided in a staggered manner in a region different from an active region that functions as the drain 81 of the input transistor 3b, and these active regions are electrically connected to each other by a wire 86. An active region that functions as the source 82 of the input transistor 3b is provided in a staggered manner in a region different from an active region that functions as the drain 81 of the input transistor 3c, and these active regions are electrically connected to each other by another wire 86. In addition, gates 80 of the input transistors 3 are electrically connected to each other by another wire 86.

In addition, the number of these input transistors 3 is not limited to three, and any number of input transistors 3 may be connected to each other. In addition, in the amplifier circuit 2, the drains 81 and the sources 82 of all the input transistors 3 need not be alternately arranged, and it is only required that the amplifier circuit 2 have a structure in which the drains 81 and the sources 82 of two or more input transistors 3 are alternately arranged.

With the configuration of FIG. 3, a degree of freedom of design layout of the circuit can be improved. Furthermore, since matching characteristics of each input transistor 3 can be improved, the S/N ratio of the comparator 5 improves.

### Second Embodiment

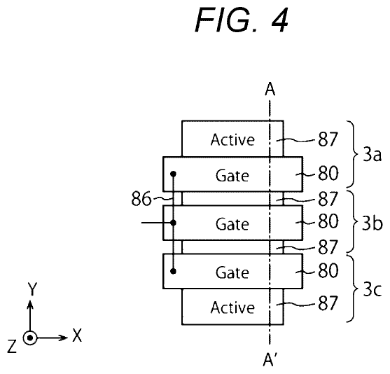

FIG. 4 is an example of an amplifier circuit according to a second embodiment.

FIG. 4 is a plan view of a part of an amplifier circuit 2 similar to that of FIG. 1 corresponding to input transistors 3.

In this example, the three input transistors 3 will be referred to as an input transistor 3a, an input transistor 3b, and an input transistor 3c in order from the top. In the amplifier circuit 2 of FIG. 4, a plurality of input transistors 3 is connected in series to each other by the same active region 87.

For example, the active region 87 that functions as a source of the input transistor 3a is the same active region 87 as the active region 87 that functions as a drain of the input transistor 3b. The active region 87 that functions as a source of the input transistor 3b is the same active region 87 as the active region 87 that functions as a drain of the input transistor 3c. In addition, gates 80 of the plurality of input transistors 3 are connected to each other. For example, the gates are electrically connected to each other by another wire 86.

In addition, the number of these input transistors 3 is not limited to three, and any number of input transistors 3 may be connected to each other. In addition, in the amplifier circuit 2, all the input transistors 3 need not be alternately arranged in series, and it is only required to include a structure in which two or more input transistors 3 are arranged in series with each other.

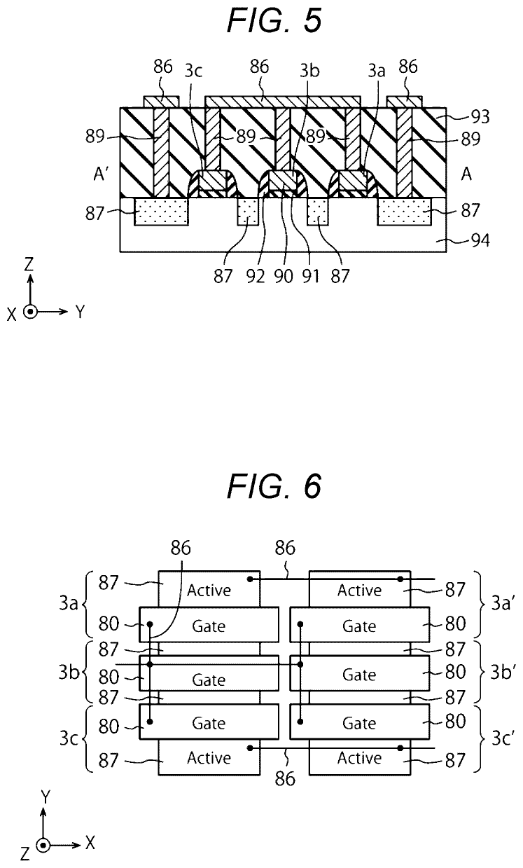

FIG. 5 is a cross-sectional view of the amplifier circuit according to the second embodiment.

FIG. 5 illustrates an A-A′ cross-sectional view of FIG. 4. A gate electrode 90 of each input transistor 3 is formed on a substrate 94 via a gate insulating film 91, and sidewall insulating films 92 of each input transistor 3 are formed on side surfaces of the gate electrode 90. An interlayer insulating film 93 is formed on the substrate 94 in such a way as to cover each input transistor 3. In addition, each of contact plugs 89 is formed in the interlayer insulating film 93, and is formed on one of the gate electrodes 90 or one of parts of the active region 87. As illustrated in FIG. 5, the input transistors 3a to 3c are connected to each other by the same active region 87. In addition, the gate electrodes 90 of the input transistors 3a to 3c are electrically connected to each other by the wire 86 formed on the contact plugs 89. FIG. 5 illustrates three wires 86 formed in the same wiring layer.

With the configuration of FIG. 5, design area of the amplifier circuit 2 is smaller than that in FIG. 1, and transconductance characteristics can be improved. Furthermore, in a solid-state imaging device or the like using the amplifier circuit 2, high resolution based on further miniaturization can be achieved, or sensor characteristics can be improved while maintaining the number of pixels.

FIG. 6 is another example of the amplifier circuit according to the second embodiment.

Input transistors 3 illustrated in the plan view of FIG. 6 include three input transistors 3 of a first group connected in series to each other and three input transistors 3 of a second group connected in series to each other. In this example, input transistors 3 in a left group in FIG. 6 will be referred to as input transistors of a first group, and input transistors 3 in a right group will be referred to as input transistors of a second group. As in FIG. 5, the three input transistors 3 of the first group and the second group are connected in series with each other by the same active region 87. In addition, parts of the two or more input transistors 3 of the first group and parts of the two or more input transistors 3 of the second group are connected in parallel to each other. The three input transistors 3 of the first group will be referred to as an input transistor 3a, an input transistor 3b, and an input transistor 3c in order from the top. In addition, the three input transistors 3 of the second group will be referred to as an input transistor 3a', an input transistor 3b', and an input transistor 3c′ in order from the top.

The number of input transistors 3 of the first group and the second group is not limited to three, and any number of input transistors 3 can be connected to each other. In addition, in the amplifier circuit 2, all the input transistors 3 need not be alternately arranged in series, and it is only required to include a structure in which two or more input transistors 3 are arranged in series with each other. In addition, a subset of or all of, that is, any number of input transistors of the first group and input transistors of the second group may be connected in parallel to each other.

With the configuration of FIG. 6, since gate width of the input transistor 3 is increased, transconductance characteristics of the input transistor 3 improve. As a result, thermal noise characteristics of the transistors improve, and the RTS noise improves.

### Third Embodiment

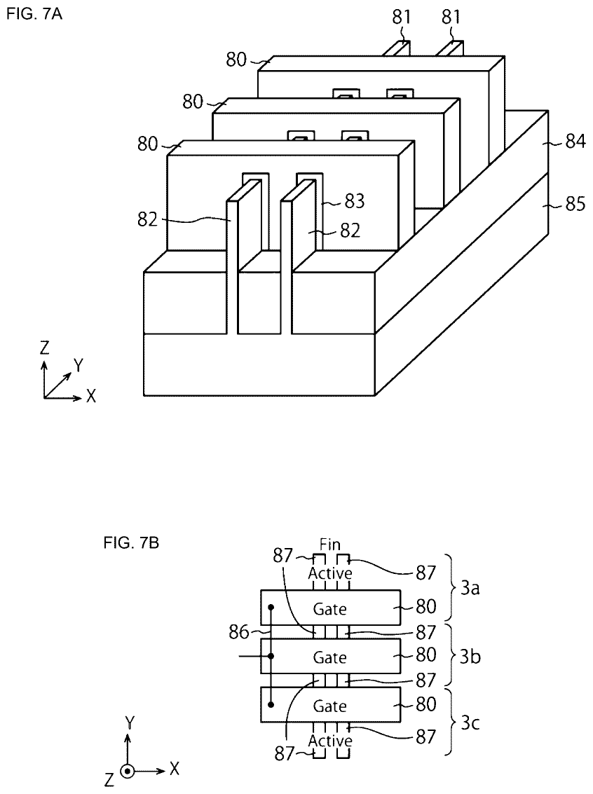

FIG. 7 is an example of an amplifier circuit according to a third embodiment.

FIG. 7A is a perspective view of a part of an amplifier circuit 2 according to the present embodiment corresponding to input transistors 3, and FIG. 7B is a plan view of the part corresponding to the input transistors 3.

In FIG. 7B, the three input transistors 3 will be referred to as an input transistor 3a, an input transistor 3b, and an input transistor 3c in order from the top. In FIG. 7B, as in FIG. 4, the three input transistors 3 are connected in series with each other to each other by the same active region 87. For example, the active region 87 that functions as a source of the input transistor 3a is the same active region 87 as the active region 87 that functions as a drain of the input transistor 3b. In addition, gates (gate electrodes) 80 of the plurality of input transistors 3 are electrically connected to each other.

For example, the gates are electrically connected to each other by another wire 86. Each of the amplifier circuits 2 according to the first and second embodiments has a planar structure, whereas the amplifier circuit 2 according to the third embodiment has a fin structure as illustrated in FIG. 7A. As illustrated in FIG. 7A, in this example, an insulating film 84 is provided on a silicon substrate 85, and a drain (drain region) 81 and a source (source region) 82 are provided under the gates 80 via gate insulating films 83.

In addition, the number of these input transistors 3 is not limited to three, and any number of input transistors 3 may be connected to each other. In addition, in the amplifier circuit 2, all the input transistors 3 need not be alternately arranged in series, and it is only required to include a structure in which two or more input transistors 3 are arranged in series with each other.

With the configuration of FIG. 7, since controllability of the gates 80 of the input transistors 3 improves, transconductance characteristics improve. As a result, thermal noise characteristics of the input transistor 3 improve, and the RTS noise improves. Furthermore, by employing the fin type, an effect of an increase in a voltage threshold due to a substrate bias effect is suppressed, which improves the RTS noise.

### Fourth Embodiment

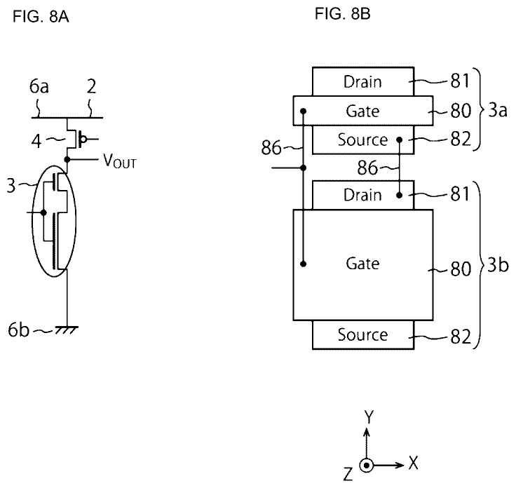

FIG. 8 is an example of an amplifier circuit according to a fourth embodiment.

FIG. 8A is a circuit diagram of an amplifier circuit 2, and FIG. 8B is a plan view of a part of the circuit diagram corresponding to input transistors 3.

In the example of FIG. 8B, the two input transistors 3 will be referred to as an input transistor 3a and an input transistor 3b in order from the top. As illustrated in FIG. 8B, the input transistor 3a and the input transistor 3b have different gate lengths. In this example, the input transistor 3a connected to an active load 4 has the shortest gate length. In addition, a source 82 of the input transistor 3a and a drain 81 of the input transistor 3b are connected in series with each other. In addition, gates 80 of the input transistors 3 are electrically connected to each other. For example, the gates 80 are electrically connected to each other by a wire 86. In addition, as illustrated in FIG. 8B, the drains 81, the gates 80, and the sources 82 of the input transistors 3a and 3b are linearly arranged in the Y-axis direction. In addition, the drain 81 of the input transistor 3a is connected to a first power supply 6a via the active load 4. The source 82 of the input transistor 3b is connected to a second power supply 6b (in this example, ground). In addition, the source 82 of the input transistor 3b may be connected to the second power supply 6b via another circuit such as a tail current control transistor.

In addition, the number of these input transistors 3 is not limited to two, and any number of input transistors 3 may be connected to each other. In addition, in a case where three or more input transistors 3 are used, three or more gate lengths may be included, and a transistor having the shortest gate length may be connected to the active load 4. In addition, in the amplifier circuit 2, all the input transistors 3 need not be alternately arranged in series, and it is only required to include a structure in which two or more input transistors 3 are arranged in series with each other.

In addition, with respect to a relationship between each input transistor 3 and the power supplies, the amplifier circuit 2 may have a configuration in which the input transistor 3a and the input transistor 3b are NMOS, and a voltage of the first power supply 6a is higher than that of the second power supply 6b. In addition, the amplifier circuit 2 may have a configuration in which the input transistor 3a and the input transistor 3b are PMOS, and the voltage of the second power supply 6b is higher than that of the first power supply 6a, instead.

With the configuration of FIG. 8, since area of the input transistor 3 in a saturation region connected to the active load 4 is reduced in the amplifier circuit 2, a probability of trapping or detrapping becomes lower than in a case where gate length of the input transistors 3 connected in series with each other is equally divided. RTS noise of the amplifier circuit 2, therefore, improves. In addition, since the amplifier circuit 2 uses the input transistors 3 having different voltage thresholds, the RTS noise improves.

In general, RTS noise tends to decrease as a value of a voltage threshold becomes smaller. Even in a case where the input transistors 3 are designed to have the same gate length in this example, too, therefore, the RTS noise improves if transistors having small voltage thresholds are used as the input transistors 3. From a viewpoint of element reliability of a transistor, on the other hand, the shortest gate length that can be designed in a design rule generally tends to be greater as the value of the voltage threshold becomes smaller. Although total gate length of the input transistors 3 is the same as that in a case where a single input transistor 3 is used for the amplifier circuit 2 since the RTS noise improves as gate area of the input transistor 3 in the saturation region connected to the active load 4 becomes smaller in this example, there is a case where the RTS noise further improves in a case where a transistor having a high voltage threshold that can be designed with a shorter gate length is used for as input transistor 3 in the saturation region connected to the active load 4 and transistors having small voltage thresholds are used as the input transistors 3 in the linear region.

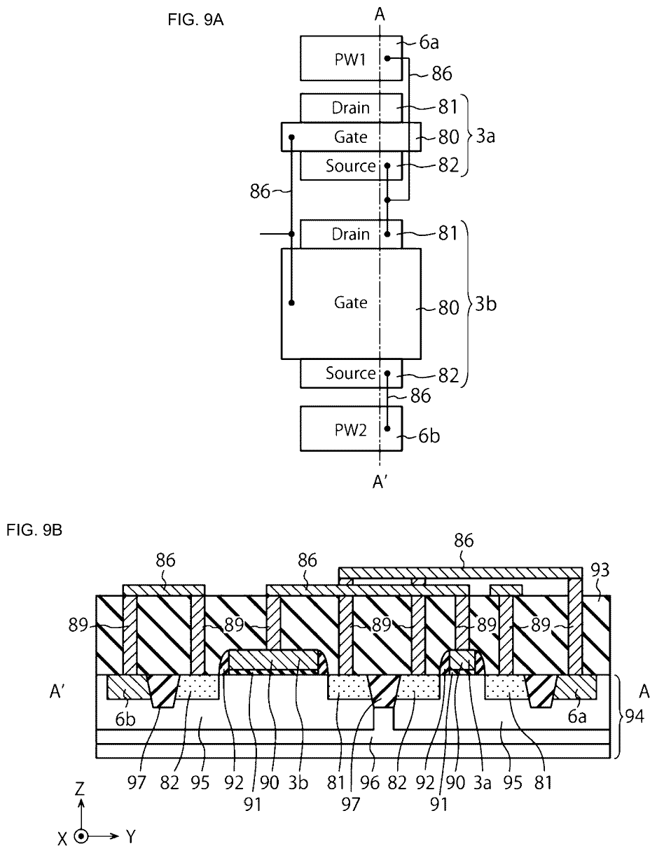

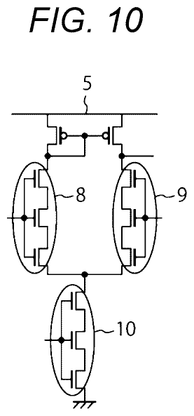

FIG. 9 is another example of the amplifier circuit according to the fourth embodiment.

FIG. 9A is a plan view of a part of an amplifier circuit 2 corresponding to input transistors 3, and FIG. 9B is an A-A′ cross-sectional view thereof.

In the example of FIG. 9A, the two input transistors 3 will be referred to as an input transistor 3a and an input transistor 3b in order from the top. The input transistor 3a and the input transistor 3b have different gate lengths. In this example, the input transistor 3a connected to an active load 4 has the shortest gate length. In addition, a source of the input transistor 3a and a drain of the input transistor 3b are connected in series with each other. In addition, gates 80 of the input transistors 3 are connected to each other.

In addition, as illustrated in FIG. 9B, back gates of the input transistor 3a and the input transistor 3b are separated from each other and connected to the same potential as corresponding sources 82. In this example, a p-well 95 for each input transistor 3 is formed in the substrate 94 on an n-well 96. In addition, a gate electrode 90, a gate insulating film 91, and sidewall insulating films 92 of each input transistor 3 are formed on a different p-well 95. In addition, element isolation insulators 97 are formed on the p-wells 95 in order to insulate the elements such as a first power supply 6a and a drain 81 or a second power supply 6b and a source 82 from each other. The element isolation insulators 97 are also called shallow trench isolation (STI) insulating films. An interlayer insulating film 93 is formed on the p-wells 95 in such a way as to cover each input transistor 3. In addition, each of contact plugs 89 is formed in the interlayer insulating film 93, and is formed on any one of gate electrodes 90, drains 81, sources 82, the first power supply 6a, and the second power supply 6b. In addition, the gate electrodes 90 of the input transistors 3a and 3b are electrically connected to each other by a wire 86 formed on the contact plugs 89. FIG. 9B illustrates four wires 86 formed in the same wiring layer (however, one of these wires 86 is illustrated at a position higher than the other three wires 86 for easy viewing of the drawing.).

In addition, the number of these input transistors 3 is not limited to two, and any number of input transistors 3 may be connected to each other. In addition, in the amplifier circuit 2, all the input transistors 3 need not be alternately arranged in series, and it is only required to include a structure in which two or more input transistors 3 are arranged in series with each other.

In addition, with respect to a relationship between each input transistor 3 and the power supplies, the amplifier circuit 2 may have a configuration in which the input transistor 3a and the input transistor 3b are NMOS, and a voltage of the first power supply 6a is higher than that of the second power supply 6b. In addition, the amplifier circuit 2 may have a configuration in which the input transistor 3a and the input transistor 3b are PMOS, and the voltage of the second power supply 6b is higher than that of the first power supply 6a, instead.

With the configuration of FIG. 9, since the back gates of the input transistor 3a and the input transistor 3b are connected to the same potential as the corresponding sources, an effect of a voltage threshold due to a substrate bias effect is suppressed, which improves the RTS noise.

### Fifth Embodiment

FIG. 10 illustrates an example of a comparator according to a fifth embodiment.

A circuit diagram of FIG. 10 illustrates a comparator 5 including a tail current control transistor 10 that controls a tail current. In this example, in the tail current control transistor 10 connected to a differential pair circuit, three input transistors 3 are connected in series with each other, and gates of the three input transistors 3 are electrically connected to each other. The tail current control transistor 10 may use any of the amplifier circuits 2 according to the first to fourth embodiments (including modifications) described above.

In addition, in the tail current control transistor 10, the number of input transistors 3 is not limited to three, and any number of input transistors 3 may be connected to each other. In the amplifier circuit 2, all the input transistors 3 need not be alternately arranged in series, and it is only required to include a structure in which two or more input transistors 3 are arranged in series with each other.

With this structure, the comparator 5 can reduce RTS noise generated in the tail current control transistor 10. Improvement of the S/N ratio accompanying the reduction of the RTS noise leads to achievement of high image quality in a solid-state imaging device or the like using the comparator 5.

### Sixth Embodiment

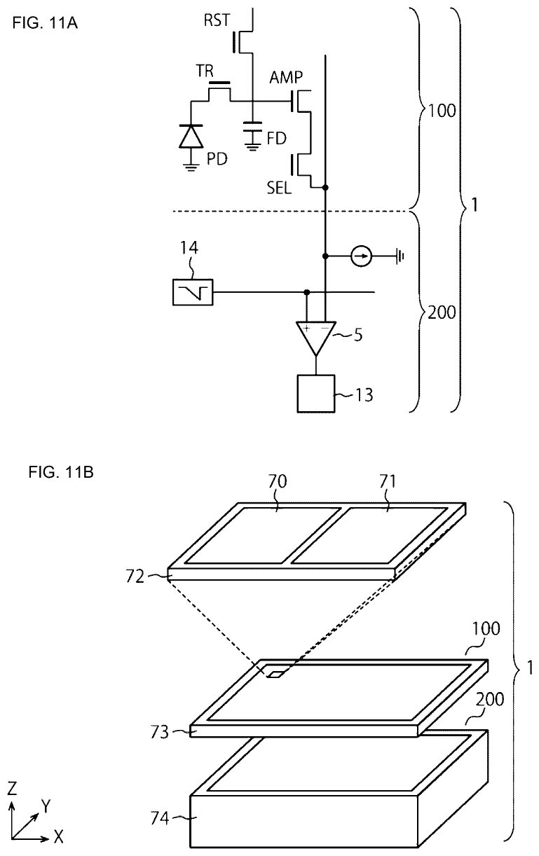

FIG. 11 is an example of a solid-state imaging device according to a sixth embodiment.

FIG. 11A is a circuit diagram of a solid-state imaging device 1 according to the present embodiment, and FIG. 11B is a schematic diagram of the solid-state imaging device 1.

As illustrated in FIG. 11B, the stacked solid-state imaging device 1 includes a first substrate 100 including a pixel array 73 in which a plurality of pixels 72, each of which includes a photoelectric conversion unit 70 and a pixel transistor 71, are gathered. The stacked solid-state imaging device 1 also includes a second substrate 200 including a logic circuit 74. The first substrate 100 is disposed on the second substrate 200.

As illustrated in FIG. 11A, the first substrate 100 includes a photodiode PD as the photoelectric conversion unit 70 and a transfer transistor TR, a reset transistor RST, an amplification transistor AMP, and a selection transistor SEL as the pixel transistor 71, and further includes a floating diffusion FD. In addition, the second substrate 200 includes a comparator 5, a counter circuit 13, and a ramp generator 14 as components of the logic circuit 74. In the present embodiment, the solid-state imaging device 1 includes a comparator 5 including the amplifier circuit 2 described in one of the first to fourth embodiments or the comparator 5 described in the fifth embodiment on the second substrate.

The photodiode PD performs photoelectric conversion of incident light. An anode of the photodiode PD is electrically connected to a ground potential, and a cathode of the photodiode PD is electrically connected to the transfer transistor TR.

Entry of light to the photodiode PD will be referred to as exposure of the photodiode PD.

The transfer transistor TR transfers charge generated as a result of the photoelectric conversion to the floating diffusion FD. One of a source and a drain of the transfer transistor TR is electrically connected to the photodiode PD, and the other of the source and the drain of the transfer transistor TR is electrically connected to the floating diffusion FD, the reset transistor RST, and the amplification transistor AMP.

The reset transistor RST discharges the charge from the floating diffusion portion FD and resets a potential of the floating diffusion portion FD to a power supply voltage (VDD) before the exposure of the photodiode PD starts. One of a source and a drain of the reset transistor RST is electrically connected to the power supply voltage, and the other of the source and the drain of the reset transistor RST is electrically connected to the transfer transistor TR, the floating diffusion FD, and the amplification transistor AMP.

The floating diffusion FD accumulates the charge transferred by the transfer transistor TR. The floating diffusion FD functions as a capacitor. The floating diffusion FD is electrically connected to the transfer transistor TR, the reset transistor RST, and the amplification transistor AMP.

The amplification transistor AMP receives the charge transferred to the floating diffusion FD at a gate thereof, and outputs the charge to the selection transistor SEL using a source follower. The gate of the amplification transistor AMP is electrically connected to the transfer transistor TR, the floating diffusion FD, and the reset transistor RST. One of a source and a drain of the amplification transistor AMP is electrically connected to the power supply voltage, and the other of the source and the drain of the amplification transistor AMP is electrically connected to the selection transistor SEL.

The selection transistor SEL can electrically connect the amplification transistor AMP and a vertical signal line to each other. In a case where the selection transistor SEL is turned on, the amplification transistor AMP and the vertical signal line are electrically connected to each other, and in a case where the selection transistor SEL is turned off, the amplification transistor AMP and the vertical signal line are electrically insulated from each other. One of a source and a drain of the selection transistor SEL is electrically connected to the amplification transistor AMP, and the other of the source and the drain of the selection transistor SEL is electrically connected or connectable to the vertical signal line.

With this structure, the stacked solid-state imaging device 1 can reduce RTS noise generated from the comparator 5. Improvement of the S/N ratio accompanying the reduction of the RTS noise leads to achievement of high image quality in the stacked solid-state imaging device 1.

### Seventh Embodiment

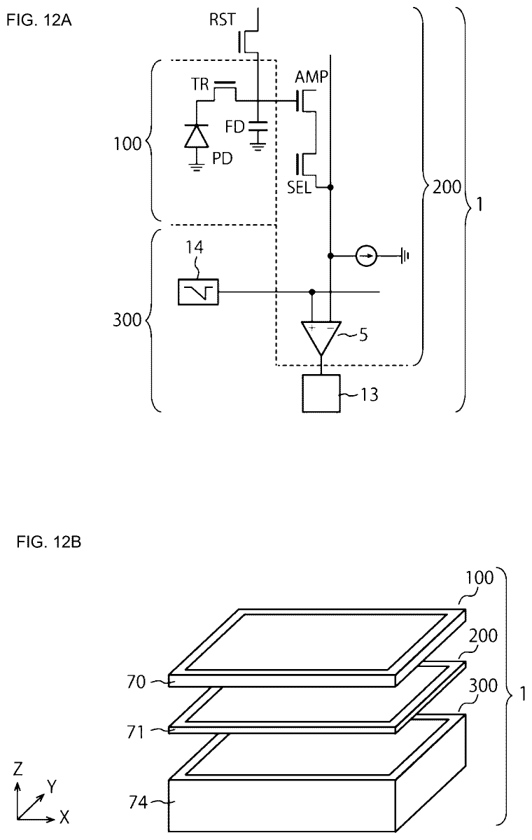

FIG. 12 is an example of a solid-state imaging device according to a seventh embodiment.

FIG. 12A is a circuit diagram of a solid-state imaging device 1 according to the present embodiment, and FIG. 12B is a schematic diagram of the solid-state imaging device 1.

As illustrated in FIG. 12B, the 3D stacked solid-state imaging device 1 includes a first substrate 100 including a photoelectric conversion unit 70, a second substrate 200 including a pixel transistor 71, and a third substrate 300 including a logic circuit 74. The first substrate 100 and the second substrate 200 are stacked with an insulating layer interposed therebetween. In addition, the first substrate 100 is disposed on the second substrate 200, and the second substrate 200 is disposed on the third substrate 300. Some pixel transistors 71 may be included in the first substrates 100 instead of the second substrates 200.

As illustrated in FIG. 12A, the first substrate 100 includes a photodiode PD, a transfer transistor TR, and a floating diffusion FD. In addition, the second substrate 200 includes a reset transistor RST, an amplification transistor AMP, a selection transistor SEL, and a comparator 5. In addition, the third substrate 300 includes a counter circuit 13 and a ramp generator 14. In the present embodiment, the solid-state imaging device 1 includes a comparator 5 including the amplifier circuit 2 described in one of the first to fourth embodiments or the comparator 5 described in the fifth embodiment on the second substrate. In addition, in addition, the solid-state imaging device 1 may include a fourth substrate including a memory circuit under the third substrate 300.

With this structure, the 3D stacked solid-state imaging device 1 can reduce the RTS noise generated from the comparator 5. Improvement of the S/N ratio accompanying the reduction of the RTS noise leads to achievement of high image quality in the 3D stacked solid-state imaging device 1.

### Eighth Embodiment

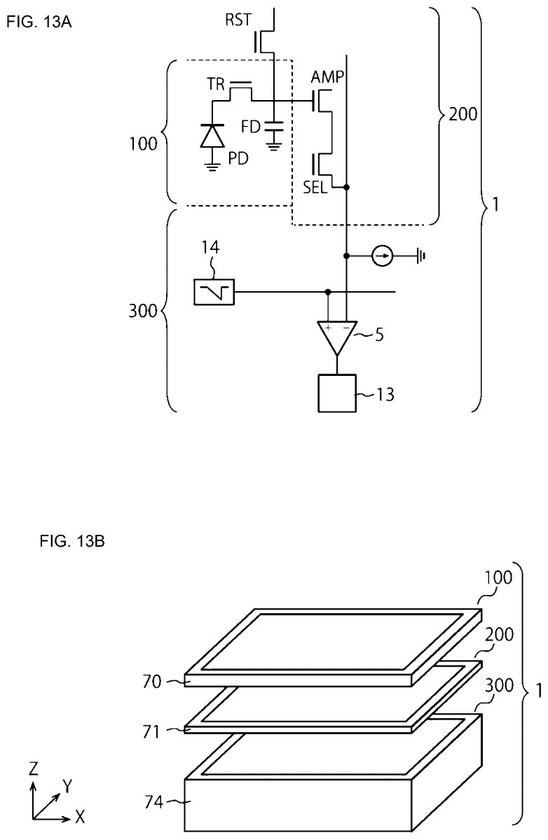

FIG. 13 is an example of a solid-state imaging device according to an eighth embodiment. FIG. 13A is a circuit diagram of a solid-state imaging device 1 according to the present embodiment, and FIG. 13B is a schematic diagram of the solid-state imaging device 1.

As illustrated in FIG. 13B, the 3D stacked solid-state imaging device 1 includes a first substrate 100 including a photoelectric conversion unit 70, a second substrate including a pixel transistor 71, and a third substrate including a logic circuit 74. The first substrate 100 and the second substrate 200 are stacked with an insulating layer interposed therebetween. In addition, the first substrate 100 is disposed on the second substrate 200, and the second substrate 200 is disposed on the third substrate 300. Some pixel transistors 71 may be included in the first substrates 100 instead of the second substrates 200.

As illustrated in FIG. 13A, the first substrate 100 includes a photodiode PD, a transfer transistor TR, and a floating diffusion FD. In addition, the second substrate 200 includes a reset transistor RST, an amplification transistor AMP, and a selection transistor SEL. In addition, the third substrate 300 includes a comparator 5, a counter circuit 13, and a ramp generator 14. In the present embodiment, the solid-state imaging device 1 includes a comparator 5 including the amplifier circuit 2 described in one of the first to fourth embodiments or the comparator 5 described in the fifth embodiment on the second substrate. In addition, the solid-state imaging device 1 may include a fourth substrate including a memory circuit under the third substrate 300.

With this structure, the 3D stacked solid-state imaging device 1 can reduce the RTS noise generated from the comparator 5. Improvement of the S/N ratio accompanying the reduction of the RTS noise leads to achievement of high image quality in the 3D stacked solid-state imaging device 1.

### Ninth Embodiment

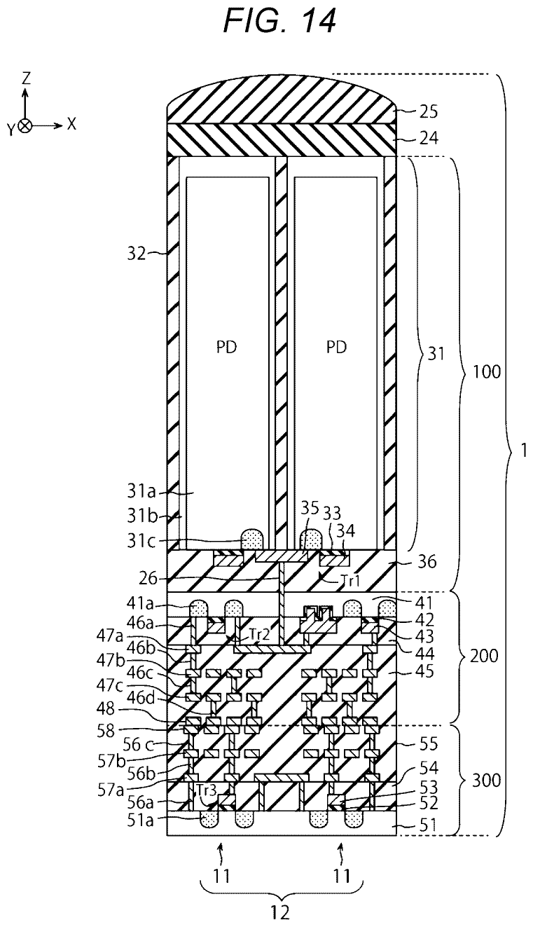

FIG. 14 is a cross-sectional view illustrating a structure of a solid-state imaging device according to a ninth embodiment.

FIG. 14 illustrates a cross section of two pixels 11 (one pixel sharing unit 12) included in a 3D stacked solid-state imaging device 1 having a function of an AD converter.

FIG. 14 illustrates an X axis, a Y axis, and a Z axis perpendicular to each other. An X direction and a Y direction correspond to a lateral direction (horizontal direction), and a Z direction corresponds to a longitudinal direction (vertical direction). In addition, a +Z direction corresponds to an upward direction, and a −Z direction corresponds to a downward direction. Note that the −Z direction may strictly match a gravity direction, but need not necessarily strictly match the gravity direction.

As illustrated in FIG. 14, the solid-state imaging device 1 according to the present embodiment includes a first substrate 100, a second substrate 200, a third substrate 300, a filter layer 24, an on-chip lens layer 25, and a through plug 26. The first substrate 100 is disposed on the second substrate 200, and the second substrate 200 is disposed on the third substrate 300. The filter layer 24 and the on-chip lens layer 25 are sequentially formed on the first substrate 100. The through plug 26 is formed in the first substrate 100 and the second substrate 200 in such a way as to penetrate a boundary surface between the first substrate 100 and the second substrate 200.

The first substrate 100 includes a semiconductor substrate 31, an element isolation insulating film 32, a gate insulating film 33 and a gate electrode 34 of each of transistors Tr1, an electrode portion 35, an interlayer insulating film 36, and a photodiode PD of each of pixels 11. The semiconductor substrate 31 includes an n-type region 31a, a p-type region 31b, and a floating diffusion portion 31c for each pixel 11.

The second substrate 200 includes a semiconductor substrate 41, a gate insulating film 42 and a gate electrode 43 of each of transistors Tr2, an interlayer insulating film 44, an interlayer insulating film 45, a plurality of plugs 46a to 46d, a plurality of wiring layers 47a to 47c, and a plurality of pads 48. The semiconductor substrate 41 includes a plurality of diffusion regions 41a.

The third substrate 300 includes a semiconductor substrate 51, a gate insulating film 52 and a gate electrode 53 of each of transistors Tr3, an interlayer insulating film 54, an interlayer insulating film 55, a plurality of plugs 56a to 56c, a plurality of wiring layers 57a and 57b, and a plurality of pads 58. The semiconductor substrate 51 includes a plurality of diffusion regions 51a.

The semiconductor substrate 31 is, for example, a silicon (Si) substrate. In FIG. 14, a surface (lower surface) of the semiconductor substrate 31 in a −Z direction is a front surface of the semiconductor substrate 31, and a surface (upper surface) of the semiconductor substrate 31 in a +Z direction is a back surface of the semiconductor substrate 31. Since the solid-state imaging device according to the present embodiment is of a back-illuminated type, a back surface of the semiconductor substrate 31 is a light incident surface (light reception surface) of the semiconductor substrate 31.

The semiconductor substrate 31 includes a photodiode PD for each pixel 11. The photodiode PD of each pixel 11 is mainly formed by a p-n junction between the n-type region 31a and the p-type region 31b, and functions as a photoelectric conversion unit. The photodiode PD of each pixel 11 receives light from a back surface side of the semiconductor substrate 31, generates signal charge corresponding to the amount of light received, and accumulates the generated signal charge in the floating diffusion portion 31c.

The element isolation insulating film 32 is provided in the semiconductor substrate 31, and penetrates the semiconductor substrate 31 between the front surface and the back surface of the semiconductor substrate 31. The element isolation insulating film 32 is, for example, a silicon oxide film (SiO2 film). The solid-state imaging device according to the present embodiment may further include a light shielding layer (for example, a tungsten (W) layer) embedded in the element isolation insulating film 32. The element isolation insulating film 32 has a mesh shape surrounding the plurality of pixels 11 described above for each pixel 11 in plan view.

The first substrate 100 includes the plurality of transistors Tr1. These transistors Tr1 include, for example, pixel transistors such as transfer transistors TR. The gate insulating film 33 and the gate electrode 34 of each transistor Tr1 are sequentially formed on the front surface of the semiconductor substrate 31. The gate insulating film 33 is, for example, a SiO2 film. The gate electrode 34 is, for example, a poly-Si layer.

The electrode portion 35 is formed on the front surface of the semiconductor substrate 31 and is in contact with the floating diffusion portion 31c. The electrode portion 35 is, for example, a poly-Si layer. The gate electrode 34 and the electrode portion 35 according to the present embodiment are formed by processing the same material.

The interlayer insulating film 36 is formed on the front surface of the semiconductor substrate 31 and covers the gate electrode 34 and the electrode portion 35. The interlayer insulating film 36 is, for example, a SiO2 film.

The semiconductor substrate 41 is, for example, a Si substrate. The semiconductor substrate 41 is disposed on a lower surface of the interlayer insulating film 36. In FIG. 14, a surface (lower surface) of the semiconductor substrate 41 in the −Z direction is a front surface of the semiconductor substrate 41, and a surface (upper surface) of the semiconductor substrate 41 in the +Z direction is a back surface of the semiconductor substrate 41.

The second substrate 200 includes the plurality of transistors Tr2. These transistors Tr2 include, for example, pixel transistors such as reset transistors RST, amplification transistors AMP, and selection transistors SEL. The gate insulating film 42 and the gate electrode 43 of each transistor Tr2 are sequentially formed on the front surface of the semiconductor substrate 41. As illustrated in FIG. 14, the gate insulating film 42 and the gate electrode 43 of at least some of the transistors Tr2 may be embedded in a trench formed in the semiconductor substrate 41. The gate insulating film 42 is, for example, a SiO2 film. The gate electrode 43 is, for example, a poly-Si layer. Each of the diffusion regions 41a in the semiconductor substrate 41 functions as, for example, a source region or a drain region of one of the transistors Tr2.

The interlayer insulating film 44 is formed on the front surface of the semiconductor substrate 41 and covers the gate electrode 43. The interlayer insulating film 45 is formed on a lower surface of the interlayer insulating film 44. These interlayer insulating films 44 and 45 are, for example, SiO2 films.

The plugs 46a to 46d, the wiring layers 47a to 47c, and the pads 48 are formed in the interlayer insulating films 44 and 45. Specifically, the wiring layers 47a to 47c are sequentially formed below the semiconductor substrate 41. The pads 48 are formed below the wiring layers 47a to 47c, and located on a lower surface of the second substrate 200. Each plug 46a is a contact plug that electrically connects the diffusion region 41a or the gate electrode 43 and the wiring layer 47a to each other. Each plug 46b is a via plug that electrically connects the wiring layer 47a and the wiring layer 47b to each other. Each plug 46c is a via plug that electrically connects the wiring layer 47b and the wiring layer 47c to each other. Each plug 46d is a via plug that electrically connects the wiring layer 47c and one of the pads 48 to each other.

The semiconductor substrate 51 is, for example, a Si substrate. The semiconductor substrate 51 is disposed below the interlayer insulating films 44 and 45 with the interlayer insulating films 54 and 55 interposed therebetween. In FIG. 14, a surface (upper surface) of the semiconductor substrate 51 in the +Z direction is a front surface of the semiconductor substrate 51, and a surface (lower surface) of the semiconductor substrate 51 in the −Z direction is a back surface of the semiconductor substrate 51.

The third substrate 300 includes the plurality of transistors Tr3. These transistors Tr3 form, for example, a logic circuit. The gate insulating film 52 and the gate electrode 53 of each transistor Tr3 are sequentially formed on the front surface of the semiconductor substrate 51. The gate insulating film 52 is, for example, a SiO2 film. The gate electrode 53 is, for example, a poly-Si layer. Each of the diffusion regions 51a in the semiconductor substrate 51 functions as, for example, a source region or a drain region of one of the transistors Tr3.

The interlayer insulating film 54 is formed on the front surface of the semiconductor substrate 51 and covers the gate electrode 53. The interlayer insulating film 55 is formed on an upper surface of the interlayer insulating film 54. These interlayer insulating films 54 and 55 are, for example, SiO2 films. As illustrated in FIG. 14, the interlayer insulating film 55 is bonded to a lower surface of the interlayer insulating film 45.

The plugs 56a to 56c, the wiring layers 57a and 57b, and the pads 58 are formed in the interlayer insulating films 54 and 55. Specifically, the wiring layers 57a and 57b are sequentially formed above the semiconductor substrate 51. The pads 58 are formed above the wiring layers 57a and 57b, and are located on an upper surface of the third substrate 300. Each plug 56a is a contact plug that electrically connects the diffusion region 51a or the gate electrode 53 and the wiring layer 57a to each other. Each plug 56b is a via plug that electrically connects the wiring layer 57a and the wiring layer 57b to each other. Each plug 56c is a via plug that electrically connects the wiring layer 57b and one of the pads 58 to each other. As illustrated in FIG. 14, the pads 58 are bonded to lower surfaces of the pads 48 and electrically connected to the pads 48.

The solid-state imaging device 1 according to the present embodiment has a three-layer structure including the first, second, and third substrates 100 to 300. The solid-state imaging device 1 according to the present embodiment further includes the filter layer 24 and the on-chip lens layer 25 on the first substrate 100, and includes the through plug 26 in the first and second substrates 100 and 200.

The filter layer 24 includes a plurality of filters having an effect of transmitting light having a predetermined wavelength. For example, filters for red (R), green (G), and blue (B) are arranged above photodiodes PD of red, green, and blue pixels 11, respectively. Moreover, a filter for infrared light may be arranged above a photodiode PD of a pixel 11 for infrared light.

The on-chip lens layer 25 includes a plurality of on-chip lenses having an effect of collecting incident light. In the present embodiment, light incident on each of the on-chip lens is collected by the on-chip lens, transmitted through the corresponding filter, and incident on the corresponding photodiode PD. The photodiode PD converts the light into charge through photoelectric conversion to generate signal charge. The generated signal charge is accumulated in the floating diffusion portion 31c.

The through plug 26 is formed in the interlayer insulating film 36, the semiconductor substrate 41, and the interlayer insulating film 44. The through plug 26 is a contact plug that electrically connects the electrode portion 35 and the wiring layer 47a to each other. The first substrate 100 and the second substrate 200 according to the present embodiment are electrically connected to each other via the through plug 26. The second substrate 200 and the third substrate 300 according to the present embodiment, on the other hand, are electrically connected to each other via the pads 48 and 58.

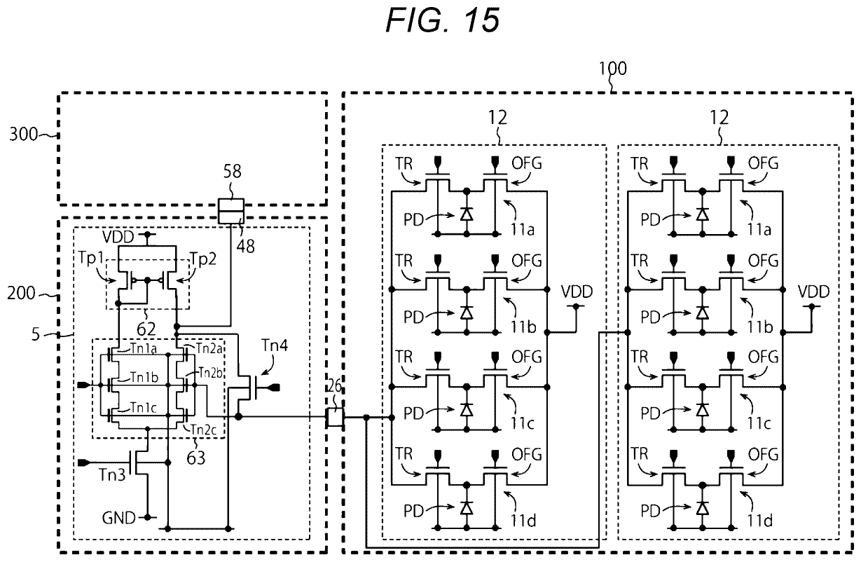

FIG. 15 is a circuit diagram illustrating configuration of a solid-state imaging device according to a ninth embodiment.

FIG. 15 illustrates the first substrate 100, the second substrate 200, and the third substrate 300. As described above, the first substrate 100 and the second substrate 200 illustrated in FIG. 15 are electrically connected to each other via the through plug 26, and the second substrate 200 and the third substrate 300 illustrated in FIG. 15 are electrically connected to each other via the pads 48 and 58.

As illustrated in FIG. 15, the first substrate 100 includes a photodiode PD for each pixel 11. FIG. 15 illustrates photodiodes PD of eight pixels 11a to 11d of two pixel sharing units 12. A cathode of each photodiode PD is electrically connected to the through plug 26 via a corresponding transfer transistor TR, and electrically connected to a power supply wire (VDD) via a corresponding overflow gate transistor OFG. An anode of each photodiode PD, on the other hand, is electrically connected to another power supply wire or a ground wire. The transfer transistor TR and the overflow gate transistor OFG are included in the above-described transistor Tr1 (FIG. 15).

In the present embodiment, the solid-state imaging device 1 includes a comparator 5 including the amplifier circuit 2 described in one of the first to third embodiments or the comparator 5 described in the fourth embodiment on the second substrate 200. The comparator 5 is provided in an AD converter of a column signal processing unit, compares a pixel signal with a reference signal, and outputs a result of the comparison between these signals. The comparator 5 includes transistors Tp1 and Tp2 that are PMOS transistors, and transistors Tn1a to Tn1c, Tn2a to Tn3c, Tn3, and Tn4 that are NMOS transistors. These transistors Tp1, Tp2, Tn1a to Tn1c, Tn2a to Tn3c, Tn3, and Tn4 are included in the above-described transistor Tr2 (FIG. 14).

The transistors Tp1 and Tp2 form an active load 62. A gate of the transistor Tp1 is electrically connected to a gate of the transistor Tp2. Sources of the transistors Tp1 and Tp2 are electrically connected to the power supply wire (VDD). A drain of the transistor Tp1 is electrically connected to a drain of the transistor Tn1a and the gates of the transistors Tp1 and Tp2. A drain of the transistor Tp2 is electrically connected to drains of the transistors Tn2 and Tn4 and the pad 48. The active load 62 is a current mirror circuit that causes a current corresponding to a mirror ratio to flow through the transistors Tp1 and Tp2.

The transistors Tn1a, Tn1b, Tn1c, Tn2a, Tn2b, and Tn2c form a differential pair circuit 63. Gates of the input transistors Tn1a to Tn1c are electrically connected in common to each other. In addition, the gates of the input transistors Tn1a to Tn1c are also electrically connected to a reference signal wire. Gates of the input transistors Tn2a to Tn2c are electrically connected in common to each other. In addition, the gates of the input transistors Tn2a to Tn2c are electrically connected to a comparison signal wire (through plug 26), and electrically connected to a source of the transistor Tn4. Sources and drains of each of sets of the three input transistors Tn1a to Tn1c and Tn2a to Tn2c are connected in series with each other. In addition, the sources of the transistors Tn1c and Tn2c are electrically connected to a drain of the transistor Tn3. The differential pair circuit 63 outputs a result (voltage difference) of comparison between a comparison signal and a reference signal to a node between the transistor Tp2 and the transistor Tn2a, and outputs the result to the pad 48 from the node.

The transistor Tn3 is a tail portion and functions as a current source. A gate of the transistor Tn3 is electrically connected to a wire for applying a predetermined voltage. A source of the transistor Tn3 is electrically connected to the ground wire (GND). This current source maintains an entire current flowing through the transistors Tn1a to Tn1c and Tn2a to Tn2c at a predetermined value.

The transistor Tn4 is disposed between the through plug 26 and the node described above, and functions as an AZ transistor. A gate of the transistor Tn4 is electrically connected to a reset signal wire. A source of the transistor Tn4 is electrically connected to the through plug 26. A drain of the transistor Tn4 is electrically connected to the node described above. The AZ transistor electrically connects the through plug 26 (floating diffusion portion 31c) and the node described above to each other before an output signal is detected, and performs an auto-zero operation.

With this structure, the RTS noise generated from the comparator 5 can be reduced. Improvement of the S/N ratio accompanying the reduction of the RTS noise leads to achievement of high image quality in the 3D stacked solid-state imaging device 1 having a function of an AD converter.

### Tenth Embodiment

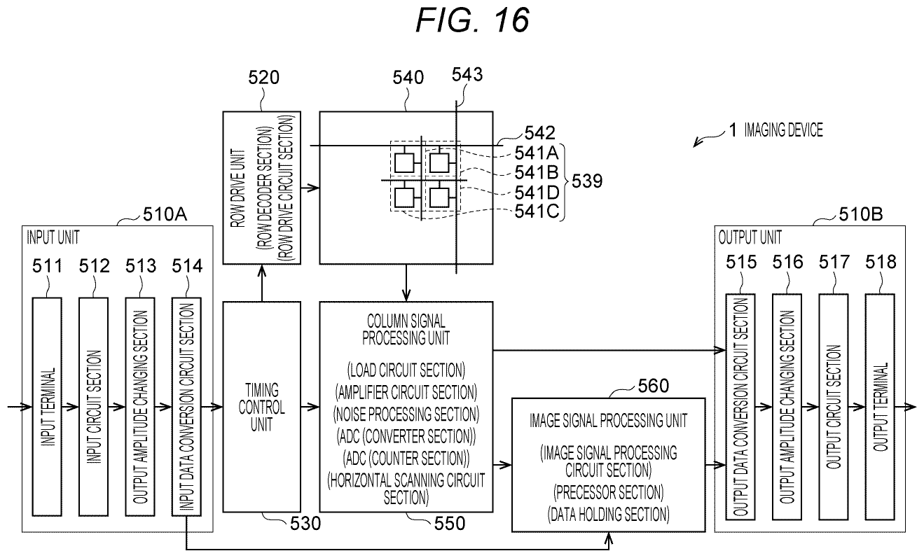

FIG. 16 is a block diagram illustrating an example of a functional configuration of a solid-state imaging device according to a tenth embodiment.

### 1. Embodiment

### [Functional Configuration of Solid-State Imaging Device 1]

The solid-state imaging device 1 of FIG. 16 includes, for example, an input unit 510A, a row drive unit 520, a timing control unit 530, a pixel array unit 540, a column signal processing unit 550, an image signal processing unit 560, and an output unit 510B.

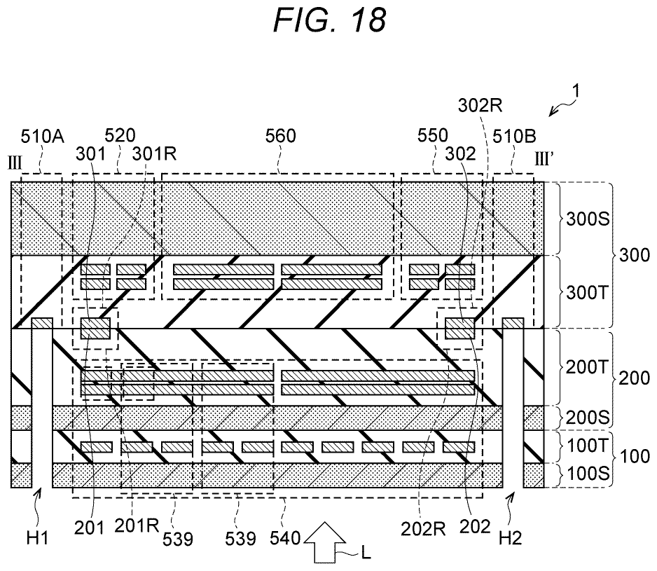

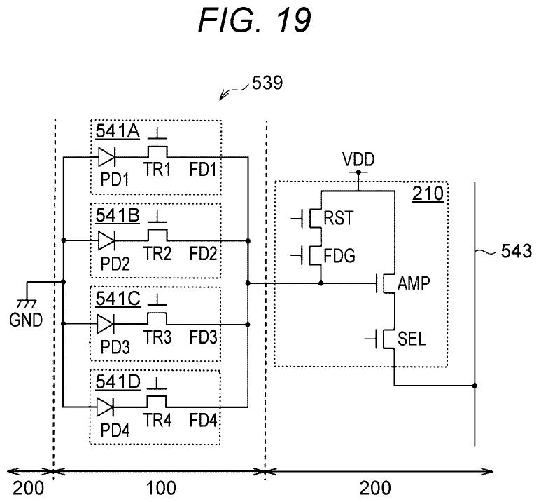

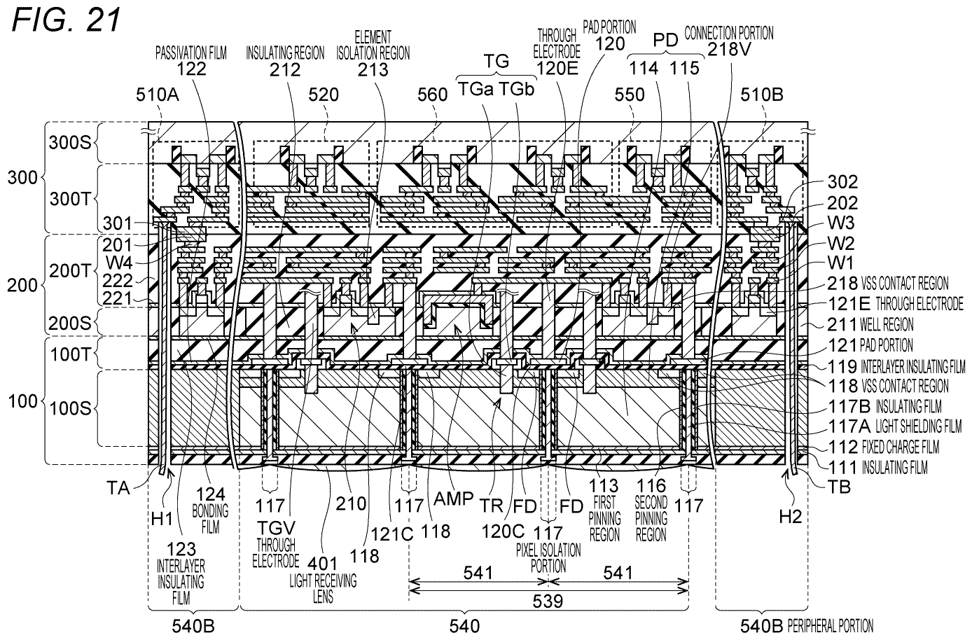

In the pixel array unit 540, pixels 541 are repeatedly arranged in an array. More specifically, a pixel sharing unit 539 including a plurality of pixels is a unit of repetition, and is repeatedly arranged in an array in a row direction and a column direction. Note that, in the present specification, the row direction will also be referred to as an H direction, and the column direction perpendicular to the row direction will also be referred to as a V direction for convenience. In the example of FIG. 16, each pixel sharing unit 539 includes four pixels (pixels 541A, 541B, 541 C, and 541D). Each of the pixels 541A, 541B, 541C, and 541D includes a photodiode PD (illustrated in FIG. 21 and the like referred to later). The pixel sharing unit 539 is a unit in which one pixel circuit (a pixel circuit 210 in FIG. 18 referred to later) is shared. In other words, one pixel circuit (the pixel circuit 210 described later) is provided for every four pixels (pixels 541A, 541B, 541C, and 541D). By operating the pixel circuit in a time division manner, pixel signals of the individual pixels 541A, 541B, 541C, and 541D are sequentially read. The pixels 541 A, 541B, 541C, and 541D are arranged in, for example, two rows and two columns. In the pixel array unit 540, a plurality of row drive signal lines 542 and a plurality of vertical signal lines (column readout lines) 543 are provided together with the pixels 541A, 541B, 541C, and 541D. The row drive signal line 542 drives the pixels 541 included in each of the plurality of pixel sharing units 539 arranged in the pixel array unit 540 side by side in the row direction. In the pixel sharing unit 539, each of the pixels arranged side by side in the row direction is driven. As will be described in detail later with reference to FIG. 19, the pixel sharing unit 539 is provided with a plurality of transistors. In order to drive each of the plurality of transistors, a plurality of row drive signal lines 542 is connected to one pixel sharing unit 539. The pixel sharing unit 539 is connected to one of the vertical signal lines (column readout lines) 543. A pixel signal is read from each of the pixels 541A, 541B, 541C, and 541D included in the pixel sharing unit 539 via the vertical signal line (column readout line) 543.

The row drive unit 520 includes, for example, a row address control section that determines a position of a row for driving pixels, that is, a row decoder section, and a row drive circuit section that generates signals for driving the pixels 541A, 541B, 541C, and 541D.

The column signal processing unit 550 includes, for example, a load circuit section that is connected to the vertical signal line 543 and that forms a source follower circuit with the pixels 541A, 541B, 541C, and 541D (pixel sharing unit 539). The column signal processing unit 550 may include an amplifier circuit section that amplifies pixel signals read from the pixel sharing unit 539 via the vertical signal line 543. The column signal processing unit 550 may include a noise processing section. In the noise processing section, for example, a noise level of a system is removed from the signals read from the pixel sharing unit 539 as a result of photoelectric conversion.

The column signal processing unit 550 includes, for example, an AD converter. In the AD converter, the signals read from the pixel sharing unit 539 or analog signals subjected to the noise processing described above are converted into digital signals. The AD converter includes, for example, a comparator 5 and a counter circuit. The comparator 5 compares an analog signal to be converted with a reference signal to be compared. In the counter circuit, a time until a result of comparison in the comparator 5 is inverted is measured. The column signal processing unit 550 may include a horizontal scanning circuit unit that performs control for scanning a column to be read. The comparator 5 may be a comparator 5 including the amplifier circuit 2 described in the first to fourth embodiments or the comparator 5 described in the fifth embodiment.

The timing control unit 530 supplies a signal for controlling timing to the row drive unit 520 and the column signal processing unit 550 on the basis of the reference clock signal and the timing control signal input to the device.

The image signal processing unit 560 is a circuit that performs various types of signal processing on data obtained as a result of photoelectric conversion, that is, data obtained as a result of an imaging operation by the solid-state imaging device 1. The image signal processing unit 560 includes, for example, an image signal processing circuit section and a data holding section. The image signal processing unit 560 may include a processor section.

An example of the signal processing performed by the image signal processing unit 560 is tone curve correction processing for providing a large number of gradations in a case where imaging data obtained as a result of AD conversion is data obtained by capturing an image of a dark subject and reducing the number of gradations in a case where imaging data obtained as a result of AD conversion is data obtained by capturing an image of a bright subject. In this case, it is desirable to store characteristic data regarding a tone curve in the data holding section of the image signal processing unit 560 in advance to determine how the tone curve corrects gradation of imaging data.

The input unit 510A is, for example, used to input the reference clock signal, the timing control signal, the characteristic data, and the like described above from the outside of the device to the solid-state imaging device 1. The timing control signal is, for example, a vertical synchronization signal, a horizontal synchronization signal, or the like. The characteristic data is, for example, to be stored in the data holding section of the image signal processing unit 560. The input unit 510A includes, for example, an input terminal 511, an input circuit section 512, an input amplitude changing section 513, an input data conversion circuit section 514, and a power supply section (not illustrated).

The input terminal 511 is an external terminal for inputting data. The input circuit section 512 is used to take a signal input to the input terminal 511 into the solid-state imaging device 1. In the input amplitude changing section 513, amplitude of a signal taken in by the input circuit section 512 is changed to an amplitude that can be easily used in the solid-state imaging device 1. In the input data conversion circuit section 514, arrangement of data strings of input data is changed. The input data conversion circuit section 514 includes, for example, a serial-to-parallel conversion circuit. In this serial-to-parallel conversion circuit, a serial signal received as input data is converted into a parallel signal. Note that, in the input unit 510A, the input amplitude changing section 513 and the input data conversion circuit section 514 may be omitted. The power supply section supplies power set to various voltages required inside the solid-state imaging device 1 on the basis of power supplied from the outside to the solid-state imaging device 1.

The input unit 510A may be provided with a memory interface circuit that, when the solid-state imaging device 1 is connected to an external memory device, receives data from the external memory device. The external memory device is, for example, a flash memory, an SRAM, a DRAM, or the like.

The output unit 510B outputs image data to the outside of the device. The image data is, for example, image data obtained by capturing an image using the solid-state imaging device 1, image data subjected to signal processing by the image signal processing unit 560, and the like. The output unit 510B includes, for example, an output data conversion circuit section 515, an output amplitude changing section 516, an output circuit section 517, and an output terminal 518.

The output data conversion circuit section 515 includes, for example, a parallel-to-serial conversion circuit, and in the output data conversion circuit section 515, a parallel signal used inside the solid-state imaging device 1 is converted into a serial signal. The output amplitude changing section 516 changes amplitude of a signal used inside the solid-state imaging device 1. The signal having the changed amplitude can be easily used in an external device connected to the outside of the solid-state imaging device 1. The output circuit section 517 is a circuit that outputs data from the inside of the solid-state imaging device 1 to the outside of the apparatus, and the output circuit section 517 drives wiring outside the solid-state imaging device 1 connected to the output terminal 518. At the output terminal 518, data is output from the solid-state imaging device 1 to the outside of the device. In the output unit 510B, the output data conversion circuit section 515 and the output amplitude changing section 516 may be omitted.

The output unit 510B may be provided with a memory interface circuit that, when the solid-state imaging device 1 is connected to an external memory device, outputs data to the external memory device. The external memory device is, for example, a flash memory, an SRAM, a DRAM, or the like.

### [Schematic Configuration of Solid-State Imaging Device 1>

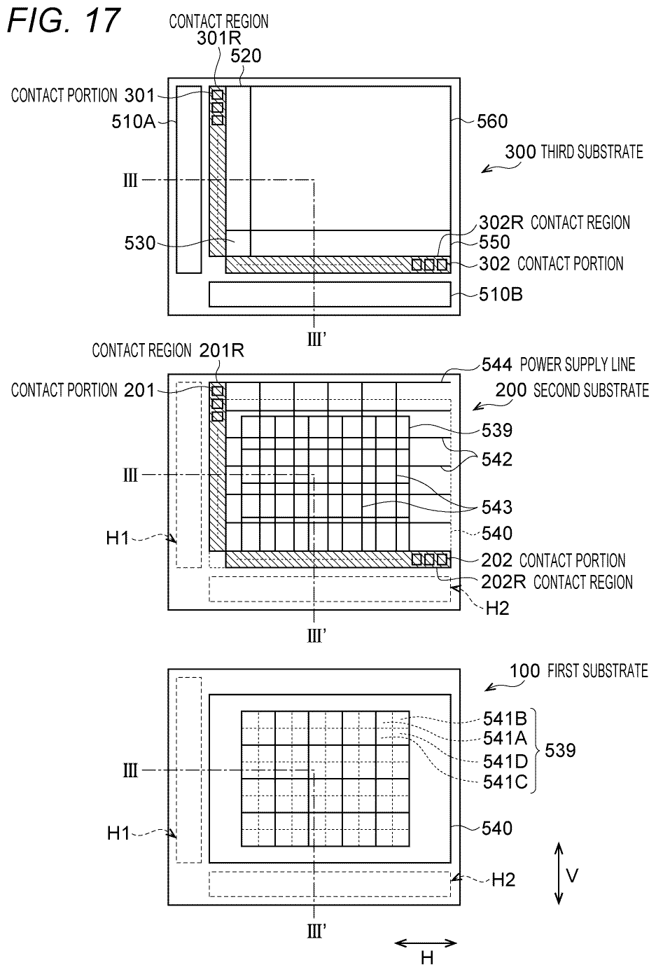

FIGS. 17 and 18 are diagrams illustrating an example of a schematic configuration of the solid-state imaging device 1. The solid-state imaging device 1 includes three substrates (a first substrate 100, a second substrate 200, and a third substrate 300). FIG. 17 schematically illustrates planar configurations of the first substrate 100, the second substrate 200, and the third substrate 300, and FIG. 18 schematically illustrates a cross-sectional configuration of the first substrate 100, the second substrate 200, and the third substrate 300 stacked on each other. FIG. 18 corresponds to a cross-sectional configuration taken along line III-III′ illustrated in FIG. 17. The solid-state imaging device 1 is a solid-state imaging device having a three-dimensional structure formed by bonding the three substrates (the first substrate 100, the second substrate 200, and the third substrate 300) together. The first substrate 100 includes a semiconductor layer 100S and a wiring layer 100T. The second substrate 200 includes a semiconductor layer 200S and a wiring layer 200T. The third substrate 300 includes a semiconductor layer 300S and a wiring layer 300T. Here, a combination of wiring included in each of the first substrate 100, the second substrate 200, and the third substrate 300 and an interlayer insulating film around the wiring will be referred to as a wiring layer (100T, 200T, or 300T) provided in each substrate (the first substrate 100, the second substrate 200, and the third substrate 300) for convenience. The first substrate 100, the second substrate 200, and the third substrate 300 are stacked on each other in this order, and the semiconductor layer 100S, the wiring layer 100T, the semiconductor layer 200S, the wiring layer 200T, the wiring layer 300T, and the semiconductor layer 300S are arranged in this order along a stacking direction. Specific configurations of the first substrate 100, the second substrate 200, and the third substrate 300 will be described later. An arrow illustrated in FIG. 18 indicates a direction in which the light L is incident on the solid-state imaging device 1. In the present specification, a light incident side in the solid-state imaging device 1 might be referred to as “down”, a “lower side”, and “below”, and a side opposite the light incident side might be referred to as “up”, an “upper side”, and “above” in the following cross-sectional views for convenience. In addition, in the present specification, with respect to a substrate including a semiconductor layer and a wiring layer, a side of the wiring layer might be referred to as a front surface, and a side of the semiconductor layer might be referred to as a back surface for convenience. Note that description of the specification is not limited to the above terms. The solid-state imaging device 1 is, for example, a back-illuminated solid-state imaging device on which light is incident from a back surface side of the first substrate 100 including a photodiode.

Both the pixel array unit 540 and the pixel sharing unit 539 included in the pixel array unit 540 are configured using both the first substrate 100 and the second substrate 200. The first substrate 100 is provided with the plurality of pixels 541A, 541B, 541C, and 541D included in the pixel sharing unit 539. Each of these pixels 541 includes a photodiode (a photodiode PD described later) and a transfer transistor (a transfer transistor TR described later). The second substrate 200 is provided with a pixel circuit (a pixel circuit 210 described later) included in the pixel sharing unit 539. The pixel circuit reads a pixel signal transferred from the photodiode of each of the pixels 541A, 541B, 541C, and 541D via the transfer transistor, or resets the photodiode. In addition to such a pixel circuit, the second substrate 200 includes a plurality of row drive signal lines 542 extending in the row direction and a plurality of vertical signal lines 543 extending in the column direction. The second substrate 200 further includes a power supply line 544 extending in the row direction. The third substrate 300 includes, for example, the input unit 510A, the row drive unit 520, the timing control unit 530, the column signal processing unit 550, the image signal processing unit 560, and the output unit 510B. The row drive unit 520 is provided, for example, in a region of the first substrate 100, the second substrate 200, and the third substrate 300 where a part thereof overlaps the pixel array unit 540 in the stacking direction (hereinafter simply referred to as a stacking direction). More specifically, the row drive unit 520 is provided in a region overlapping the vicinity of an end portion of the pixel array unit 540 in the H direction in the stacking direction (FIG. 17). The column signal processing unit 550 is provided, for example, in a region partially overlapping the pixel array unit 540 in the stacking direction. More specifically, the column signal processing unit 550 is provided in a region overlapping the vicinity of an end portion of the pixel array unit 540 in the V direction in the stacking direction (FIG. 17). Although not illustrated, the input unit 510A and the output unit 510B may be disposed in a portion other than the third substrate 300, and, for example, may be disposed on the second substrate 200, instead. Alternatively, the input unit 510A and the output unit 510B may be provided on a back surface (light incident surface) side of the first substrate 100. Note that the pixel circuit provided in the second substrate 200 described above might be referred to as a pixel transistor circuit, a pixel transistor group, a pixel transistor, a pixel readout circuit, or a readout circuit as another name. In the present specification, the term “pixel circuit” is used.

The first substrate 100 and the second substrate 200 are electrically connected to each other by, for example, through electrodes (through electrodes 120E and 121E in FIG. 21 described later). The second substrate 200 and the third substrate 300 are electrically connected to each other via, for example, contact portions 201, 202, 301, and 302. The contact portions 201 and 202 are provided in the second substrate 200, and the contact portions 301 and 302 are provided in the third substrate 300. The contact portion 201 of the second substrate 200 is in contact with the contact portion 301 of the third substrate 300, and the contact portion 202 of the second substrate 200 is in contact with the contact portion 302 of the third substrate 300. The second substrate 200 includes a contact region 201R in which a plurality of contact portions 201 is provided and a contact region 202R in which a plurality of contact portions 202 is provided. The third substrate 300 includes a contact region 301R in which a plurality of contact portions 301 is provided and a contact region 302R in which a plurality of contact portions 302 is provided. The contact regions 201R and 301R are provided between the pixel array unit 540 and the row drive unit 520 in the stacking direction (FIG. 18). In other words, the contact regions 201R and 301R are provided, for example, in a region where the row drive unit 520 (third substrate 300) and the pixel array unit 540 (second substrate 200) overlap in the stacking direction or in a region in the vicinity thereof. The contact regions 201R and 301R are disposed, for example, in an end portion of such a region in the H direction (FIG. 17). In the third substrate 300, for example, the contact region 301R is provided at a position overlapping a part of the row drive unit 520, or more specifically, an end portion of the row drive unit 520 in the H direction (FIGS. 17 and 18). The contact portions 201 and 301 connect, for example, the row drive unit 520 provided in the third substrate 300 and the row drive signal line 542 provided in the second substrate 200. For example, the contact portions 201 and 301 may connect the input unit 510A provided in the third substrate 300 to the power supply line 544 and a reference potential line (a reference potential line VSS described later). The contact regions 202R and 302R are provided between the pixel array unit 540 and the column signal processing unit 550 in the stacking direction (FIG. 18). In other words, the contact regions 202R and 302R are provided, for example, in a region where the column signal processing unit 550 (third substrate 300) and the pixel array unit 540 (second substrate 200) overlap in the stacking direction or in a region in the vicinity thereof. The contact regions 202R and 302R are disposed, for example, in an end portion of such a region in the V direction (FIG. 17). In the third substrate 300, for example, the contact region 301R is provided at a position overlapping with a part of the column signal processing unit 550, or more specifically, an end portion of the column signal processing unit 550 in the V direction (FIGS. 17 and 18). The contact portions 202 and 302 are, for example, used to connect a pixel signal (a signal corresponding to the amount of charge generated as a result of photoelectric conversion in the photodiode) output from each of the plurality of pixel sharing units 539 included in the pixel array unit 540 to the column signal processing unit 550 provided in the third substrate 300. The pixel signal is transmitted from the second substrate 200 to the third substrate 300.

FIG. 18 is an example of a cross-sectional view of the solid-state imaging device 1 as described above. The first substrate 100, the second substrate 200, and the third substrate 300 are electrically connected to each other via the wiring layers 100T, 200T, and 300T. For example, the solid-state imaging device 1 includes an electrical connection portion that electrically connects the second substrate 200 and the third substrate 300 to each other. Specifically, the contact portions 201, 202, 301, and 302 are constituted by electrodes constituted by a conductive material. The conductive material includes, for example, a metal material such as copper (Cu), aluminum (Al), or gold (Au). The contact regions 201R, 202R, 301R, and 302R electrically connect the second substrate and the third substrate by directly bonding wires formed as electrodes, for example, and enable signal input and/or output between the second substrate 200 and the third substrate 300.

The electrical connection portion that electrically connects the second substrate 200 and the third substrate 300 to each other can be provided at a desired location. For example, as described as the contact regions 201R, 202R, 301R, and 302R in FIG. 18, the electrical connection portion may be provided in a region overlapping the pixel array unit 540 in the stacking direction. In addition, the electrical connection portion may be provided in a region not overlapping the pixel array unit 540 in the stacking direction. Specifically, the electrical connection portion may be provided in a region overlapping a peripheral portion arranged outside the pixel array unit 540 in the stacking direction.

The first substrate 100 and the second substrate 200 are provided with, for example, connection holes H1 and H2. The connection holes H1 and H2 penetrate the first substrate 100 and the second substrate 200 (FIG. 18). The connection holes H1 and H2 are provided outside the pixel array unit 540 (or portions overlapping the pixel array unit 540) (FIG. 17). For example, the connection hole H1 is arranged outside the pixel array unit 540 in the H direction, and the connection hole H2 is arranged outside the pixel array unit 540 in the V direction. For example, the connection hole H1 reaches the input unit 510A provided in the third substrate 300, and the connection hole H2 reaches the output unit 510B provided in the third substrate 300. The connection holes H1 and H2 may be hollow, or at least a part thereof may contain a conductive material. For example, there is a configuration in which a bonding wire is connected to an electrode formed as the input unit 510A and/or the output unit 510B. Alternatively, there is a configuration in which the electrode formed as the input unit 510A and/or the output unit 510B is connected to the conductive material provided in the connection holes H1 and H2. The conductive material provided in the connection holes H1 and H2 may be embedded in a part or the entirety of the connection holes H1 and H2, and the conductive material may be formed on side walls of the connection holes H1 and H2.

Note that, in FIG. 18, the input unit 510A and the output unit 510B are provided in the third substrate 300, but the structure to be employed is not limited to this. For example, by sending a signal of the third substrate 300 to the second substrate 200 via the wiring layers 200T and 300T, the input unit 510A and/or the output unit 510B can be provided in the second substrate 200. Similarly, by sending a signal of the second substrate 200 to the first substrate 100 via the wiring layers 100T and 200T, the input unit 510A and/or the output unit 510B can be provided in the first substrate 100.

FIG. 19 is an equivalent circuit diagram illustrating an example of configuration of the pixel sharing unit 539. The pixel sharing unit 539 includes the plurality of pixels 541 (FIG. 19 illustrates the four pixels 541, namely the pixels 541A, 541B, 541C, and 541D), one pixel circuit 210 connected to the plurality of pixels 541, and a vertical signal line 543 connected to the pixel circuit 210. The pixel circuit 210 includes, for example, four transistors, or more specifically, an amplification transistor AMP, a selection transistor SEL, a reset transistor RST, and an FD conversion gain switching transistor FD. As described above, the pixel sharing unit 539 sequentially outputs the pixel signals of the four pixels 541 (the pixels 541A, 541B, 541C, and 541D) included in the pixel sharing unit 539 to the vertical signal line 543 by operating one pixel circuit 210 in a time division manner. One pixel circuit 210 is connected to the plurality of pixels 541, and a mode in which the pixel signals of the plurality of pixels 541 are output by the pixel circuit 210 in a time division manner will be referred to as “the plurality of pixels 541 shares one pixel circuit 210”.

The pixels 541A, 541B, 541C, and 541D include common components. In order to distinguish the components of the pixels 541A, 541B, 541C, and 541D from each other, an identification number 1 will be assigned to ends of reference signs of the components of the pixel 541A, an identification number 2 will be assigned to ends of reference signs of the components of the pixel 541B, an identification number 3 will be assigned to ends of reference signs of the components of the pixel 541C, and an identification number 4 will be assigned to ends of reference signs of the components of the pixel 541D hereinafter. In a case where it is not necessary to distinguish the components of the pixels 541A, 541B, 541C, and 541D from each other, the identification numbers at the ends of the reference signs of the components of the pixels 541A, 541B, 541C, and 541D are omitted.

The pixels 541A, 541B, 541C, and 541D each include, for example, a photodiode PD, a transfer transistor TR electrically connected to the photodiode PD, and a floating diffusion FD electrically connected to the transfer transistor TR. In the photodiode PD (PD1, PD2, PD3, or PD4), a cathode is electrically connected to a source of the transfer transistor TR, and an anode is electrically connected to a reference potential line (for example, ground). The photodiode PD performs photoelectric conversion on incident light to generate charge corresponding to the amount of light received. The transfer transistor TR (the transfer transistor TR1, TR2, TR3, or TR4) is, for example, an n-type complementary metal oxide semiconductor (CMOS) transistor. In the transfer transistor TR, a drain is electrically connected to the floating diffusion FD, and a gate is electrically connected to a drive signal line. The drive signal line is part of the plurality of row drive signal lines 542 (see FIG. 16) connected to one pixel sharing unit 539. The transfer transistor TR transfers the charge generated in the photodiode PD to the floating diffusion FD. The floating diffusion FD (the floating diffusion FD1, FD2, FD3, or FD4) is an n-type diffusion layer region formed in a p-type semiconductor layer. The floating diffusion FD is a charge holding means for temporarily holding the charge transferred from the photodiode PD, and is a charge-to-voltage conversion means for generating a voltage corresponding to the amount of charge.

The four floating diffusions FD (the floating diffusions FD1, FD2, FD3, and FD4) included in each pixel sharing unit 539 are electrically connected to each other, and are electrically connected to a gate of the amplification transistor AMP and a source of the FD conversion gain switching transistor FDG. A drain of the FD conversion gain switching transistor FDG is connected to a source of the reset transistor RST, and a gate of the FD conversion gain switching transistor FDG is connected to the drive signal line. This drive signal line is part of the plurality of row drive signal lines 542 connected to one pixel sharing unit 539. A drain of the reset transistor RST is connected to a power supply line VDD, and a gate of the reset transistor RST is connected to the drive signal line. This drive signal line is part of the plurality of row drive signal lines 542 connected to one pixel sharing unit 539. The gate of the amplification transistor AMP is connected to the floating diffusion FD, a drain of the amplification transistor AMP is connected to the power supply line VDD, and a source of the amplification transistor AMP is connected to a drain of the selection transistor SEL. A source of the selection transistor SEL is connected to the vertical signal line 543, and a gate of the selection transistor SEL is connected to the drive signal line. This drive signal line is part of the plurality of row drive signal lines 542 connected to one pixel sharing unit 539.

The transfer transistor TR transfers charge of the photodiode PD to the floating diffusion FD when turned on. A gate (transfer gate TG) of the transfer transistor TR includes, for example, a so-called vertical electrode, and is provided in such a way as to extend from a surface of a semiconductor layer (the semiconductor layer 100S in FIG. 21 described later) to a depth reaching the PD as illustrated in FIG. 21 described later. The reset transistor RST resets potentials of the floating diffusions FD to a predetermined potential. The reset transistor RST resets the potentials of the floating diffusions FD to a potential of the power supply line VDD when turned on. The selection transistor SEL controls output timing of a pixel signal from the pixel circuit 210. The amplification transistor AMP generates signals of voltages corresponding to levels of charge held in the floating diffusions FD as pixel signals. The amplification transistor AMP is connected to the vertical signal line 543 via the selection transistor SEL. The amplification transistor AMP constitutes a source follower together with a load circuit section (see FIG. 16) connected to the vertical signal line 543 in the column signal processing unit 550. When the selection transistor SEL is turned on, the amplification transistor AMP outputs voltages of the floating diffusions FD to the column signal processing unit 550 via the vertical signal line 543. The reset transistor RST, the amplification transistor AMP, and the selection transistor SEL are, for example, n-type CMOS transistors.

The FD conversion gain switching transistor FDG is used to change gain of charge-to-voltage conversion in the floating diffusions FD. In general, a pixel signal is small at a time of capture of an image in a dark place. Since Q=CV, if capacitance (FD capacitance C) of the floating diffusion FD is high when charge-to-voltage conversion is performed, V obtained by the amplification transistor AMP as a result of the conversion into a voltage becomes low. Since a pixel signal becomes large in a bright place, on the other hand, the floating diffusion FD cannot receive charge of the photodiode PD unless the FD capacitance C is high. Moreover, the FD capacitance C needs to be high so that V obtained by the amplification transistor AMP as a result of the conversion into a voltage does not become too high (in other words, becomes low). For these reasons, when the FD conversion gain switching transistor FDG is turned on, gate capacitance of the FD conversion gain switching transistor FDG increases, and entire FD capacitance C increases. When the FD conversion gain switching transistor FDG is turned off, on the other hand, the entire FD capacitance C decreases. The FD capacitance C can thus be made variable and conversion efficiency can be switched by turning on and off the FD conversion gain switching transistor FDG. The FD conversion gain switching transistor FDG is, for example, an n-type CMOS transistor.

Note that a configuration in which the FD conversion gain switching transistor FDG is not provided is also possible. At this time, for example, the pixel circuit 210 includes three transistors, namely, for example, an amplification transistor AMP, a selection transistor SEL, and a reset transistor RST. The pixel circuit 210 includes, for example, at least one of pixel transistors such as an amplification transistor AMP, a selection transistor SEL, a reset transistor RST, or an FD conversion gain switching transistor FDG.

The selection transistor SEL may be provided between the power supply line VDD and the amplification transistor AMP. In this case, a drain of the reset transistor RST is electrically connected to the power supply line VDD and a drain of the selection transistor SEL. A source of the selection transistor SEL is electrically connected to a drain of the amplification transistor AMP, and a gate of the selection transistor SEL is electrically connected to the row drive signal line 542 (see FIG. 16). A source of the amplification transistor AMP (an output terminal of the pixel circuit 210) is electrically connected to the vertical signal line 543, and a gate of the amplification transistor AMP is electrically connected to a source of the reset transistor RST. Note that although not illustrated, the number of pixels 541 that share one pixel circuit 210 may be other than four. For example, two or eight pixels 541 may share one pixel circuit 210, instead.

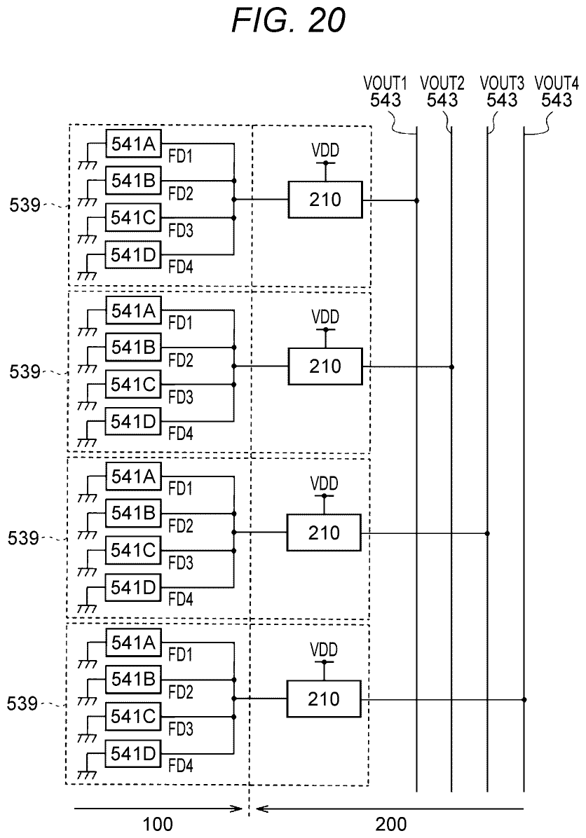

FIG. 20 illustrates an example of a connection mode between the plurality of pixel sharing units 539 and the vertical signal lines 543. For example, the four pixel sharing units 539 arranged in the column direction are divided into four groups, and a vertical signal line 543 is connected to each of the four groups. Although FIG. 20 illustrates an example in which four groups each include one pixel sharing unit 539 in order to simplify description, the four groups may each include a plurality of pixel sharing units 539. In the solid-state imaging device 1, the plurality of pixel sharing units 539 arranged in the column direction may thus be divided into groups each including one or a plurality of pixel sharing units 539. For example, a vertical signal line 543 and a column signal processing unit 550 are connected to each group, and pixel signals can be simultaneously read from each group. Alternatively, in the solid-state imaging device 1, one vertical signal line 543 may be connected to the plurality of pixel sharing units 539 arranged in the column direction. At this time, pixel signals are sequentially read, in a time division manner, from the plurality of pixel sharing units 539 connected to one vertical signal line 543.

### [Specific Configuration of Solid-State Imaging Device 1]

FIG. 21 illustrates an example of a cross-sectional configuration in a direction perpendicular to main surfaces of the first substrate 100, the second substrate 200, and the third substrate 300 of the solid-state imaging device 1. FIG. 21 schematically illustrates a positional relationship of the components for easy understanding, and may be different from an actual cross section. In the solid-state imaging device 1, the first substrate 100, the second substrate 200, and the third substrate 300 are laminated in this order. The solid-state imaging device 1 further includes a light receiving lens 401 on the back surface side (light incident surface side) of the first substrate 100. A color filter layer (not illustrated) may be provided between the light receiving lens 401 and the first substrate 100. The light receiving lens 401 is provided, for example, in each of the pixels 541A, 541B, 541C, and 541D. The solid-state imaging device 1 is, for example, a back-illuminated solid-state imaging device. The solid-state imaging device 1 includes a pixel array unit 540 arranged in a central portion and a peripheral portion 540B arranged outside the pixel array unit 540.

The first substrate 100 includes an insulating film 111, a fixed charge film 112, a semiconductor layer 100S, and a wiring layer 100T in this order from a light receiving lens 401 side. The semiconductor layer 100S includes, for example, a silicon substrate. The semiconductor layer 100S includes, for example, a p-well layer 115 in a part of a front surface (a surface on a wiring layer 100T side) thereof and in the vicinity of the part and an n-type semiconductor region 114 in another region (a region deeper than the p-well layer 115). For example, the n-type semiconductor region 114 and the p-well layer 115 constitute a photodiode PD of a p-n junction type. The p-well layer 115 is a p-type semiconductor region.

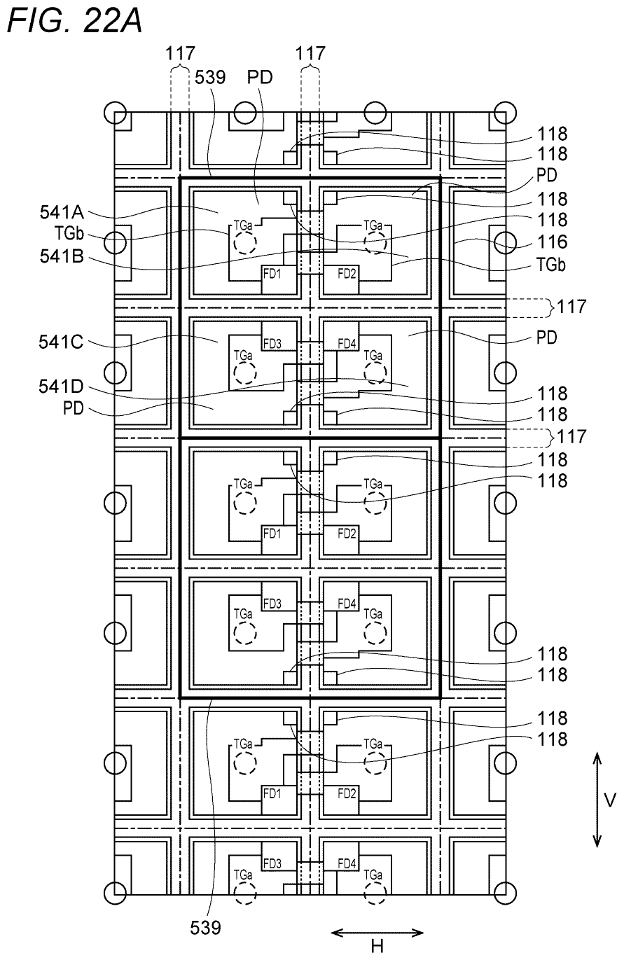

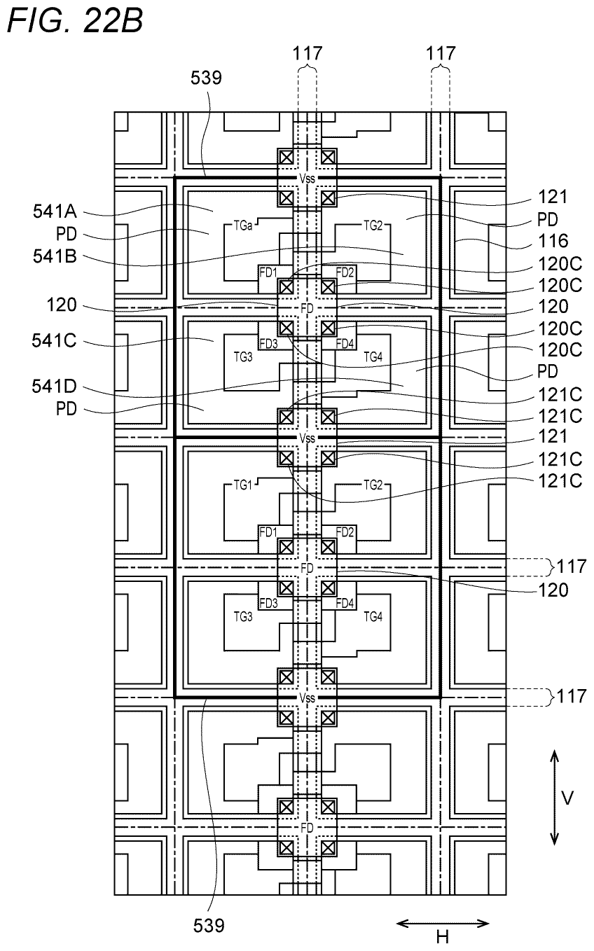

FIG. 22A illustrates an example of a planar configuration of the first substrate 100. FIG. 22A mainly illustrates a planar configuration of a pixel isolation portion 117, the photodiodes PD, floating diffusions FD, VSS contact regions 118, and transfer transistors TR of the first substrate 100. Configuration of the first substrate 100 will be described with reference to FIG. 22A together with FIG. 21.

The floating diffusions FD and the VSS contact regions 118 are provided in the vicinity of the surface of the semiconductor layer 100S. The floating diffusions FD each include an n-type semiconductor region provided in the p-well layer 115. The floating diffusions FD (the floating diffusion FD1, FD2, FD3, or FD4) of the individual pixels 541A, 541B, 541C, and 541D are provided, for example, close to each other in a central portion of the pixel sharing unit 539 (FIG. 22A). Although details will be described later, the four floating diffusions (the floating diffusions FD1, FD2, FD3, and FD4) included in the pixel sharing unit 539 are electrically connected to each other in the first substrate 100 (more specifically, in the wiring layer 100T) via an electrical connection means (a pad portion 120 described later). Moreover, the floating diffusions FD are connected from the first substrate 100 to the second substrate 200 (more specifically, from the wiring layer 100T to the wiring layer 200T) via an electrical means (a through electrode 120E described later). In the second substrate 200 (more specifically, inside the wiring layer 200T), the floating diffusions FD are electrically connected to the gate of the amplification transistor AMP and the source of the FD conversion gain switching transistor FDG by this electrical means.

The VSS contact regions 118 are regions electrically connected to the reference potential line VSS, and disposed away from the floating diffusions FD. For example, in each of the pixels 541A, 541B, 541C, and 541D, the floating diffusion FD is arranged at one end of the pixel in the V direction, and the VSS contact region 118 is arranged at another end (FIG. 22A). The VSS contact region 118 includes, for example, a p-type semiconductor region. The VSS contact region 118 is connected to, for example, a ground potential or a fixed potential. As a result, the reference potential is supplied to the semiconductor layer 100S.

The transfer transistors TR are provided in the first substrate 100 together with the photodiodes PD, the floating diffusions FD, and the VSS contact regions 118. The photodiode PD, the floating diffusion FD, the VSS contact region 118, and the transfer transistor TR are provided in each of the pixels 541A, 541B, 541C, and 541D. The transfer transistor TR is provided on the front surface side (a side opposite the light incident surface side, a second substrate 200 side) of the semiconductor layer 100S. The transfer transistor TR includes a transfer gate TG. The transfer gate TG includes, for example, a horizontal portion TGb facing the surface of the semiconductor layer 100S and a vertical portion TGa provided in the semiconductor layer 100S. The vertical portion TGa extends in a thickness direction of the semiconductor layer 100S. An end of the vertical portion TGa is in contact with the horizontal portion TGb, and another end is provided in the n-type semiconductor region 114. By configuring the transfer transistor TR with such a vertical transistor, transfer failure of a pixel signal hardly occurs, and readout efficiency of the pixel signal can be improved.

The horizontal portion TGb of the transfer gate TG extends from a position facing the vertical portion TGa toward, for example, the central portion of the pixel sharing unit 539 in the H direction (FIG. 22A). As a result, a position of a through electrode (a through electrode TGV described later) in the H direction reaching the transfer gate TG can be brought close to positions of through electrodes (through electrodes 120E and 121E described later) in the H direction connected to the floating diffusion FD and the VSS contact region 118. For example, the plurality of pixel sharing units 539 provided in the first substrate 100 has the same configuration (FIG. 22A).

The semiconductor layer 100S is provided with the pixel isolation portion 117 that isolates the pixels 541A, 541B, 541C, and 541D from each other. The pixel isolation portion 117 is formed in such a way as to extend in a normal direction of the semiconductor layer 100S (a direction perpendicular to the surface of the semiconductor layer 100S). The pixel isolation portion 117 is provided in such a way as to partition the pixels 541A, 541B, 541C, and 541D from each other, and has, for example, a grid-like planar shape (FIG. 22A and FIG. 22B). For example, the pixel isolation portion 117 electrically and optically isolates the pixels 541A, 541B, 541C, and 541D from each other. The pixel isolation portion 117 includes, for example, a light shielding film 117A and an insulating film 117B. For example, tungsten (W) or the like is used for the light shielding film 117A. The insulating film 117B is provided between the light shielding film 117A and the p-well layer 115 or the n-type semiconductor region 114. The insulating film 117B includes, for example, silicon oxide (SiO). The pixel isolation portion 117 has, for example, a full trench isolation (FTI) structure and penetrates the semiconductor layer 100S. Although not illustrated, the pixel isolation portion 117 is not limited to the FTI structure penetrating the semiconductor layer 100S. For example, a deep trench isolation (DTI) structure that does not penetrate the semiconductor layer 100S may be employed. The pixel isolation portion 117 extends in the normal direction of the semiconductor layer 100S and is formed in a part of the semiconductor layer 100S.

In the semiconductor layer 100S, for example, a first pinning region 113 and a second pinning region 116 are provided. The first pinning region 113 is provided in the vicinity of the back surface of the semiconductor layer 100S, and is disposed between the n-type semiconductor region 114 and the fixed charge film 112. The second pinning region 116 is provided on a side surface of the pixel isolation portion 117, or more specifically, between the pixel isolation portion 117 and the p-well layer 115 or the n-type semiconductor region 114. The first pinning region 113 and the second pinning region 116 include, for example, a p-type semiconductor region.

The fixed charge film 112 having negative fixed charge is provided between the semiconductor layer 100S and the insulating film 111. The first pinning region 113 of a hole accumulation layer is formed at an interface on a light receiving surface (back surface) side of the semiconductor layer 100S by an electric field induced by the fixed charge film 112. As a result, generation of a dark current due to an interface state on the light receiving surface side of the semiconductor layer 100S is suppressed. The fixed charge film 112 includes, for example, an insulating film having negative fixed charge. Examples of a material of the insulating film having negative fixed charge include hafnium oxide, zircon oxide, aluminum oxide, titanium oxide, and tantalum oxide.

The light shielding film 117A is provided between the fixed charge film 112 and the insulating film 111. The light shielding film 117A may be provided continuously with the light shielding film 117A constituting the pixel isolation portion 117. The light shielding film 117A between the fixed charge film 112 and the insulating film 111 is selectively provided, for example, in the semiconductor layer 100S at a position facing the pixel isolation portion 117. The insulating film 111 is provided in such a way as to cover the light shielding film 117A. The insulating film 111 includes, for example, silicon oxide.

The wiring layer 100T provided between the semiconductor layer 100S and the second substrate 200 includes an interlayer insulating film 119, pad portions 120 and 121, a passivation film 122, an interlayer insulating film 123, and a bonding film 124 in this order from a semiconductor layer 100S side. The horizontal portion TGb of the transfer gate TG is provided, for example, in the wiring layer 100T. The interlayer insulating film 119 is provided over the entire surface of the semiconductor layer 100S and in contact with the semiconductor layer 100S. The interlayer insulating film 119 includes, for example, a silicon oxide film. Note that configuration of the wiring layer 100T is not limited to the above, and may be a configuration including wiring and an insulating film.

FIG. 22B illustrates configuration of the pad portions 120 and 121 together with the planar configuration illustrated in FIG. 22A. The pad portions 120 and 121 are provided in a selective region on the interlayer insulating film 119. The pad portion 120 is used to connect the floating diffusions FD (the floating diffusions FD1, FD2, FD3, and FD4) of the pixels 541A, 541B, 541C, and 541D to each other. For example, the pad portion 120 is arranged for each of the pixel sharing units 539 at the central portion of the pixel sharing unit 539 in plan view (FIG. 22B). The pad portion 120 is provided across the pixel isolation portion 117, and is arranged in such a way as to overlap at least a part of each of the floating diffusions FD1, FD2, FD3, and FD4 (FIG. 21 and FIG. 22B). Specifically, the pad portion 120 is formed in a region overlapping at least a part of each of the plurality of floating diffusions FD (the floating diffusions FD1, FD2, FD3, and FD4) sharing the pixel circuit 210 and at least a part of the pixel isolation portion 117 formed between the plurality of photodiodes PD (the photodiodes PD1, PD2, PD3, and PD4) sharing the pixel circuit 210 in a direction perpendicular to the surface of the semiconductor layer 100S. The interlayer insulating film 119 is provided with a connection via 120C for electrically connecting the pad portion 120 and the floating diffusions FD1, FD2, FD3, and FD4 to each other. The connection via 120C is provided in each of the pixels 541A, 541B, 541C, and 541D. For example, by embedding a part of the pad portion 120 in the connection via 120C, the pad portion 120 and the floating diffusions FD1, FD2, FD3, and FD4 are electrically connected to each other.

The pad portion 121 is used to connect the plurality of VSS contact regions 118 to each other. For example, the VSS contact region 118 provided in the pixels 541C and 541D of one of pixel sharing unit 539 adjacent to each other in the V direction and the VSS contact region 118 provided in the pixels 541A and 541B of the other pixel sharing unit 539 are electrically connected to each other by the pad portion 121. The pad portion 121 is provided across the pixel isolation portion 117, for example, and is arranged in such a way as to overlap at least a part of each of the four VSS contact regions 118. Specifically, the pad portion 121 is formed in a region overlapping at least a part of each of the plurality of VSS contact regions 118 and at least a part of the pixel isolation portion 117 formed between the plurality of VSS contact regions 118 in a direction perpendicular to the surface of the semiconductor layer 100S. The interlayer insulating film 119 is provided with a connection via 121C for electrically connecting the pad portion 121 and the VSS contact region 118 to each other. The connection via 121C is provided in each of the pixels 541A, 541B, 541C, and 541D. For example, by embedding a part of the pad portion 121 in the connection via 121C, the pad portion 121 and the VSS contact region 118 are electrically connected to each other. For example, the pad portion 120 and the pad portion 121 of each of the plurality of pixel sharing units 539 arranged in the V direction are arranged at substantially the same position in the H direction (FIG. 22B).

By providing the pad portion 120, it is possible to reduce the number of wires for connecting each floating diffusion FD to the pixel circuit 210 (for example, the gate electrode of the amplification transistor AMP) in the entire chip. Similarly, by providing the pad portion 121, the number of wires for supplying a potential to each VSS contact region 118 can be reduced in the entire chip. As a result, it is possible to reduce the area of the entire chip, suppress electrical interference between the wires in the miniaturized pixels, and/or reduce a cost by reducing the number of components.

The pad portions 120 and 121 can be provided in the first substrate 100 and the second substrate 200 at desired positions. Specifically, the pad portions 120 and 121 can be provided in either the wiring layer 100T or an insulating region 212 of the semiconductor layer 200S. In a case where the pad portions 120 and 121 are provided in the wiring layer 100T, the pad portions 120 and 121 may be brought into direct contact with the semiconductor layer 100S. Specifically, the pad portions 120 and 121 may be directly connected to at least a part of each of the floating diffusion FD and/or the VSS contact region 118. In addition, connection vias 120C and 121C may be provided from each of the floating diffusion FD and/or the VSS contact region 118 connected to the pad portions 120 and 121, and the pad portions 120 and 121 may be provided in the wiring layer 100T and the insulating region 212 of the semiconductor layer 200S at desired positions.

In particular, in a case where the pad portions 120 and 121 are provided in the wiring layer 100T, it is possible to reduce the number of wires connected to the floating diffusion FD and/or the VSS contact region 118 in the insulating region 212 of the semiconductor layer 200S. As a result, in the second substrate 200 forming the pixel circuit 210, the area of the insulating region 212 for forming the through wiring for connecting the floating diffusion FD to the pixel circuit 210 can be reduced. Therefore, it is possible to secure a large area of the second substrate 200 forming the pixel circuit 210. By securing the area of the pixel circuit 210, it is possible to form a large pixel transistor and contribute to image quality improvement through noise reduction or the like.

In particular, since it is preferable to provide the floating diffusion FD and/or the VSS contact region 118 in each pixel 541 in a case where the FTI structure is used for the pixel isolation portion 117, the number of wires connecting the first substrate 100 and the second substrate 200 to each other can be greatly reduced by using the configuration of the pad portions 120 and 121.

In addition, as illustrated in FIG. 22B, for example, the pad portion 120 to which the plurality of floating diffusions FD is connected and the pad portion 121 to which the plurality of VSS contact regions 118 is connected are alternately arranged linearly in the V direction. In addition, the pad portions 120 and 121 are formed at positions surrounded by the plurality of photodiodes PD, the plurality of transfer gates TG, and the plurality of floating diffusions FD. As a result, elements other than the floating diffusion FD and the VSS contact region 118 can be freely arranged in the first substrate 100 forming a plurality of elements, and efficiency of the layout of the entire chip can be improved. Furthermore, symmetry in the layout of the elements formed in each pixel sharing unit 539 can be secured, and variation in characteristics of each pixel 541 can be suppressed.

The pad portions 120 and 121 include, for example, polysilicon (Poly Si), or more specifically, doped polysilicon doped with impurities. The pad portions 120 and 121 preferably include a conductive material having high heat resistance such as polysilicon, tungsten (W), titanium (Ti), or titanium nitride (TiN). As a result, the pixel circuit 210 can be formed after the semiconductor layer 200S of the second substrate 200 is bonded to the first substrate 100. A reason for this will be described hereinafter. Note that, in the following description, a method for forming the pixel circuit 210 after bonding the first substrate 100 and the semiconductor layer 200S of the second substrate 200 to each other will be referred to as a first manufacturing method.

Here, it is also conceivable to bond, after forming the pixel circuit 210 on the second substrate 200, the second substrate 200 to the first substrate 100 (hereinafter referred to as a second manufacturing method). In the second manufacturing method, an electrode for electrical connection is formed in advance on each of the surface of the first substrate 100 (the surface of the wiring layer 100T) and the surface of the second substrate 200 (the surface of the wiring layer 200T). When the first substrate 100 and the second substrate 200 are bonded to each other, the electrodes for electrical connection formed on the surface of the first substrate 100 and the surface of the second substrate 200 come into contact with each other. As a result, an electrical connection is formed between the wiring included in the first substrate 100 and the wiring included in the second substrate 200. Therefore, by employing the configuration of the solid-state imaging device 1 using the second manufacturing method, for example, manufacturing can be performed using an appropriate process in accordance with the configuration of each of the first substrate 100 and the second substrate 200, and a high-quality and high-performance solid-state imaging device can be manufactured.

In such a second manufacturing method, when the first substrate 100 and the second substrate 200 are bonded to each other, an error in alignment might occur due to a manufacturing apparatus for bonding. In addition, the first substrate 100 and the second substrate 200 have a size of, for example, about several tens of centimeters in diameter, but when the first substrate 100 and the second substrate 200 are bonded to each other, there is a possibility that expansion and contraction of the substrates occur in microscopic regions of the respective parts of the first substrate 100 and the second substrate 200. This expansion and contraction of the substrates is caused by a slight shift in the timing of contact between the substrates. Due to such expansion and contraction of the first substrate 100 and the second substrate 200, an error may occur in the positions of the electrodes for electrical connection formed on the surface of the first substrate 100 and the surface of the second substrate 200. In the second manufacturing method, even if such an error occurs, it is preferable to take measures so that the electrodes of the first substrate 100 and the second substrate 200 come into contact with each other. Specifically, at least one, preferably both, of the electrodes of the first substrate 100 or the second substrate 200 is increased in consideration of the above error. Therefore, when the second manufacturing method is used, for example, the size of the electrode formed on the surface of the first substrate 100 or the second substrate 200 (the size in the substrate planar direction) is larger than the size of the internal electrode extending from the inside of the first substrate 100 or the second substrate 200 to the surface in the thickness direction.

In a case where the pad portions 120 and 121 include a heat-resistant conductive material, on the other hand, the above-described first manufacturing method can be used. In the first manufacturing method, after the first substrate 100 including the photodiode PD, the transfer transistor TR, and the like is formed, the first substrate 100 and the second substrate 200 (semiconductor layer 200S) are bonded to each other. At this time, the second substrate 200 is in a state in which patterns such as active elements and wiring layers constituting the pixel circuit 210 are not formed. Since the second substrate 200 is in a state before the pattern is formed, even if an error occurs in the bonding position when the first substrate 100 and the second substrate 200 are bonded, an error does not occur in alignment between the pattern of the first substrate 100 and the pattern of the second substrate 200 due to the bonding error. This is because the pattern of the second substrate 200 is formed after the first substrate 100 and the second substrate 200 are bonded. Note that, when a pattern is formed on the second substrate, for example, in an exposure apparatus for pattern formation, the pattern is formed while the pattern formed on the first substrate is set as an alignment target. For the above reason, the error in the bonding position between the first substrate 100 and the second substrate 200 does not pose a problem in manufacturing the solid-state imaging device 1 in the first manufacturing method. For a similar reason, an error caused by expansion and contraction of the substrate caused by the second manufacturing method does not pose a problem in manufacturing the solid-state imaging device 1 in the first manufacturing method.

In the first manufacturing method, after the first substrate 100 and the second substrate 200 (semiconductor layer 200S) are bonded in this manner, an active element is formed on the second substrate 200. Thereafter, the through electrodes 120E and 121E and the through electrode TGV (FIG. 21) are formed. In the formation of the through electrodes 120E, 121E, and TGV, for example, a pattern of the through electrode is formed from above the second substrate 200 using reduced projection exposure by an exposure apparatus. Since the reduced exposure projection is used, even if an error occurs in the alignment between the second substrate 200 and the exposure apparatus, the magnitude of the error is only a fraction (inverse of the reduced exposure projection magnification) of the magnitude of the error of the above-described second manufacturing method in the second substrate 200. Therefore, by employing the configuration of the solid-state imaging device 1 using the first manufacturing method, it is easy to align the elements formed on each of the first substrate 100 and the second substrate 200, and it is possible to manufacture a high-quality and high-performance solid-state imaging device.

The solid-state imaging device 1 manufactured using such a first manufacturing method has features different from those of a solid-state imaging device manufactured by the second manufacturing method. Specifically, in the solid-state imaging device 1 manufactured by the first manufacturing method, for example, the through electrodes 120E, 121E, and TGV have substantially constant thicknesses (sizes in the substrate planar direction) from the second substrate 200 to the first substrate 100. Alternatively, in a case where the through electrodes 120E, 121E, and TGV have tapered shapes, they have tapered shapes with a constant inclination. In the solid-state imaging device 1 including such through electrodes 120E, 121E, and TGV, the pixels 541 can be easily miniaturized.

Here, when the solid-state imaging device 1 is manufactured by the first manufacturing method, since the active element is formed in the second substrate 200 after the first substrate 100 and the second substrate 200 (semiconductor layer 200S) are bonded together, the first substrate 100 is also affected by heating treatment necessary for forming the active element. Therefore, as described above, it is preferable to use a conductive material having high heat resistance for the pad portions 120 and 121 provided in the first substrate 100. For example, the pad portions 120 and 121 preferably include a material having a higher melting point (that is, higher heat resistance) than at least a part of the wiring material included in the wiring layer 200T of the second substrate 200. For example, a conductive material having high heat resistance such as doped polysilicon, tungsten, titanium, or titanium nitride is used for the pad portions 120 and 121. As a result, the solid-state imaging device 1 can be manufactured using the above-described first manufacturing method.

The passivation film 122 is provided over the entire surface of the semiconductor layer 100S, for example, in such a way as to cover the pad portions 120 and 121 (FIG. 21). The passivation film 122 includes, for example, a silicon nitride (SiN) film. The interlayer insulating film 123 covers the pad portions 120 and 121 with the passivation film 122 interposed therebetween. The interlayer insulating film 123 is provided, for example, over the entire surface of the semiconductor layer 100S. The interlayer insulating film 123 includes, for example, a silicon oxide (SiO) film. The bonding film 124 is provided on a bonding surface between the first substrate 100 (specifically, the wiring layer 100T) and the second substrate 200. That is, the bonding film 124 is in contact with the second substrate 200. The bonding film 124 is provided over the entire main surface of the first substrate 100. The bonding film 124 includes, for example, a silicon nitride film.

The light receiving lens 401 faces, for example, the semiconductor layer 100S with the fixed charge film 112 and the insulating film 111 interposed therebetween, for example (FIG. 21). The light receiving lens 401 is provided, for example, at a position facing the photodiode PD of each of the pixels 541A, 541B, 541C, and 541D.

The second substrate 200 includes the semiconductor layer 200S and the wiring layer 200T in this order from the first substrate 100 side. The semiconductor layer 200S includes a silicon substrate. In the semiconductor layer 200S, a well region 211 is provided over the thickness direction. The well region 211 is, for example, a p-type semiconductor region. The second substrate 200 is provided with a pixel circuit 210 arranged for each pixel sharing unit 539. The pixel circuit 210 is provided, for example, on the front surface side (wiring layer 200T side) of the semiconductor layer 200S. In the solid-state imaging device 1, the second substrate 200 is bonded to the first substrate 100 such that the back surface side (semiconductor layer 200S side) of the second substrate 200 faces the front surface side (wiring layer 100T side) of the first substrate 100. That is, the second substrate 200 is bonded to the first substrate 100 in a face-to-back manner.

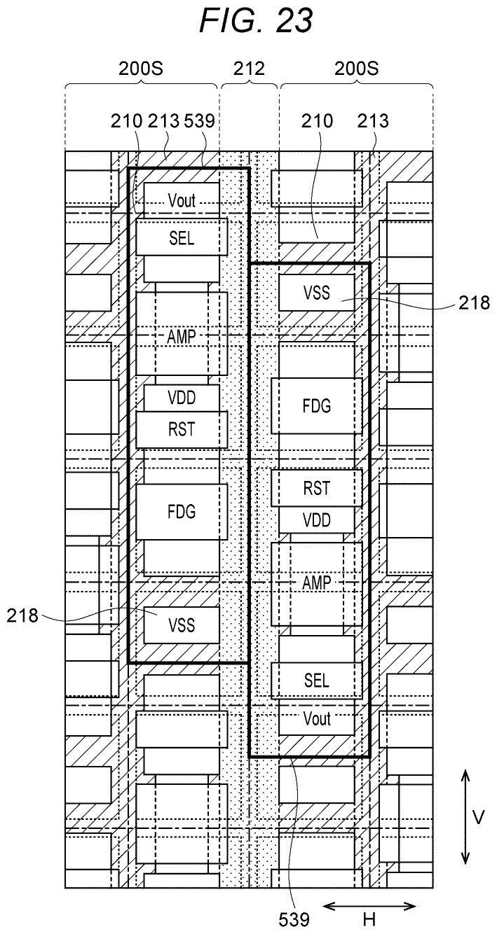

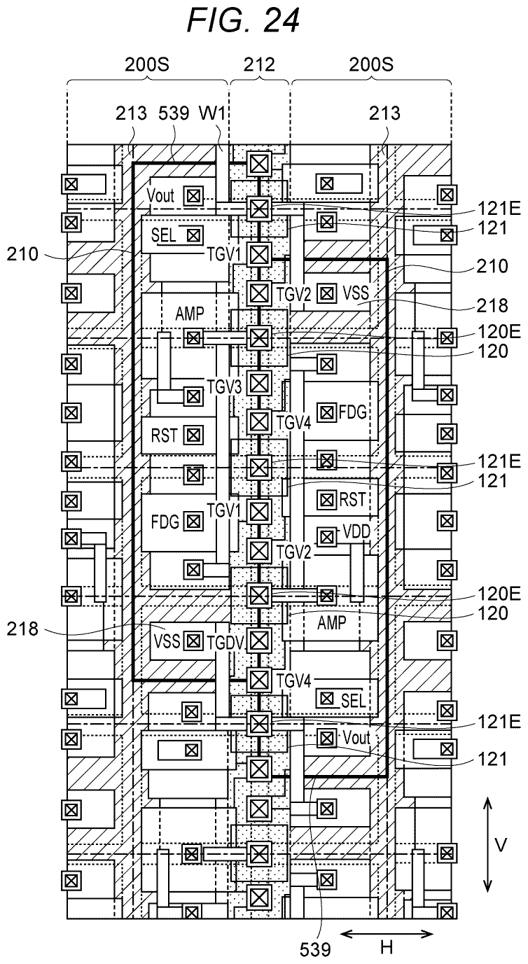

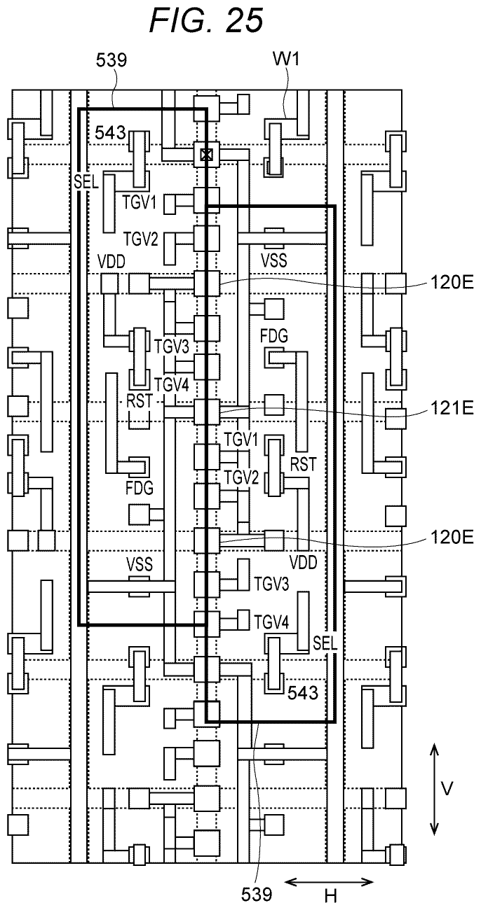

FIGS. 23 to 27 schematically illustrate an example of a planar configuration of the second substrate 200. FIG. 23 illustrates a configuration of the pixel circuit 210 provided in the vicinity of the surface of the semiconductor layer 200S. FIG. 24 schematically illustrates a configuration of each part of the wiring layer 200T (specifically, a first wiring layer W1 described later), the semiconductor layer 200S connected to the wiring layer 200T, and the first substrate 100. FIGS. 25 to 27 illustrate an example of a planar configuration of the wiring layer 200T. The configuration of the second substrate 200 will be described hereinafter with reference to FIGS. 23 to 27 together with FIG. 21. In FIGS. 23 and 24, the outer shape of the photodiode PD (the boundary between the pixel isolation portion 117 and the photodiode PD) is indicated by a broken line, and the boundary between the semiconductor layer 200S and an element isolation region 213 or an insulating region 212 in a portion overlapping the gate electrode of each transistor constituting the pixel circuit 210 is indicated by a dotted line. In a portion overlapping the gate electrode of the amplification transistor AMP, a boundary between the semiconductor layer 200S and the element isolation region 213 and a boundary between the element isolation region 213 and the insulating region 212 are provided on one side in the channel width direction.

The second substrate 200 is provided with the insulating region 212 that divides the semiconductor layer 200S and the element isolation region 213 provided in a part of the semiconductor layer 200S in the thickness direction (FIG. 21).

For example, the through electrodes 120E and 121E and the through electrodes TGV (through electrodes TGV1, TGV2, TGV3, and TGV4) of the two pixel sharing units 539 connected to the two pixel circuits 210 are arranged in the insulating region 212 provided between the two pixel circuits 210 adjacent in the H direction (FIG. 24).

The insulating region 212 has substantially the same thickness as the thickness of the semiconductor layer 200S (FIG. 21). The semiconductor layer 200S is divided by the insulating region 212. The through electrodes 120E and 121E and the through electrode TGV are disposed in the insulating region 212. The insulating region 212 includes, for example, silicon oxide.

The through electrodes 120E and 121E are provided in such a way as to penetrate the insulating region 212 in the thickness direction. The upper ends of the through electrodes 120E and 121E are connected to wiring (first wiring W1, second wiring W2, third wiring W3, and fourth wiring W4 described later) of the wiring layer 200T. The through electrodes 120E and 121E are provided to penetrate the insulating region 212, the bonding film 124, the interlayer insulating film 123, and the passivation film 122, and the lower end thereof is connected to the pad portions 120 and 121 (FIG. 21). The through electrode 120E is for electrically connecting the pad portion 120 and the pixel circuit 210. That is, the floating diffusion FD of the first substrate 100 is electrically connected to the pixel circuit 210 of the second substrate 200 by the through electrode 120E. The through electrode 121E is for electrically connecting the pad portion 121 and the reference potential line VSS of the wiring layer 200T. That is, the VSS contact region 118 of the first substrate 100 is electrically connected to the reference potential line VSS of the second substrate 200 by the through electrode 121E.

The through electrode TGV is provided to penetrate the insulating region 212 in the thickness direction. The upper end of the through electrode TGV is connected to the wiring of the wiring layer 200T. The through electrode TGV is provided to penetrate the insulating region 212, the bonding film 124, the interlayer insulating film 123, the passivation film 122, and the interlayer insulating film 119, and the lower end thereof is connected to the transfer gate TG (FIG. 21). Such a through electrode TGV is for electrically connecting the transfer gate TG (transfer gates TG1, TG2, TG3, and TG4) of each of the pixels 541A, 541B, 541C, and 541D to the wiring (a part of the row drive signal line 542, specifically, wiring lines TRG1, TRG2, TRG3, and TRG4 in FIG. 25 described later) of the wiring layer 200T. That is, the transfer gate TG of the first substrate 100 is electrically connected to the wiring TRG of the second substrate 200 by the through electrode TGV, and a drive signal is sent to each of the transfer transistors TR (transfer transistors TR1, TR2, TR3, and TR4).

The insulating region 212 is a region for insulating, from the semiconductor layer 200S, the through electrodes 120E and 121E and the through electrode TGV for electrically connecting the first substrate 100 and the second substrate 200 to each other. For example, the through electrodes 120E and 121E and the through electrode TGV (through electrodes TGV1, TGV2, TGV3, and TGV4) connected to the two pixel circuits 210 are arranged in the insulating region 212 provided between the two pixel circuits 210 (pixel sharing unit 539) adjacent in the H direction. The insulating region 212 is provided, for example, to extend in the V direction (FIG. 23 and FIG. 24). Here, by devising the arrangement of the horizontal portion TGb of the transfer gate TG, the through electrode TGV is arranged such that the position of the through electrode TGV in the H direction approaches the positions of the through electrodes 120E and 121E in the H direction as compared with the position of the vertical portion TGa (FIG. 22A, FIG. 24). For example, the through electrode TGV is disposed at substantially the same position as the through electrodes 120E and 120E in the H direction. As a result, the through electrodes 120E and 121E and the through electrode TGV can be collectively provided in the insulating region 212 extending in the V direction. As another arrangement example, it is also conceivable to provide the horizontal portion TGb only in a region overlapping the vertical portion TGa. In this case, the through electrode TGV is formed substantially immediately above the vertical portion TGa, and for example, the through electrode TGV is disposed substantially at the central portion in the H direction and the V direction of each pixel 541. At this time, the position of the through electrode TGV in the H direction greatly deviates from the positions of the through electrodes 120E and 121E in the H direction. For example, the insulating region 212 is provided around the through electrode TGV and the through electrodes 120E and 121E in order to electrically insulate them from the adjacent semiconductor layer 200S. In a case where the position of the through electrode TGV in the H direction and the positions of the through electrodes 120E and 121E in the H direction are greatly separated from each other, it is necessary to provide the insulating region 212 independently around each of the through electrodes 120E, 121E, and TGV. As a result, the semiconductor layer 200S is finely divided. In comparison, the layout in which the through electrodes 120E and 121E and the through electrode TGV are collectively arranged in the insulating region 212 extending in the V direction can increase the size of the semiconductor layer 200S in the H direction.

Therefore, a large area of the semiconductor element formation region in the semiconductor layer 200S can be secured. As a result, for example, the size of the amplification transistor AMP can be increased, and noise can be suppressed.

As described with reference to FIG. 19, the pixel sharing unit 539 has a structure in which the floating diffusion FD provided in each of the plurality of pixels 541 is electrically connected, and the plurality of pixels 541 shares one pixel circuit 210. Then, the floating diffusion FD is electrically connected to each other by the pad portion 120 provided on the first substrate 100 (FIG. 21 and FIG. 22B). The electrical connection portion (pad portion 120) provided on the first substrate 100 and the pixel circuit 210 provided on the second substrate 200 are electrically connected via one through electrode 120E. As another structural example, it is also conceivable to provide an electrical connection portion between the floating diffusions FD on the second substrate 200. In this case, the pixel sharing unit 539 is provided with four through electrodes connected to the floating diffusions FD1, FD2, FD3, and FD4, respectively. Therefore, in the second substrate 200, the number of through electrodes penetrating the semiconductor layer 200S increases, and the insulating region 212 that insulates the periphery of these through electrodes increases. In comparison, in the structure in which the pad portion 120 is provided on the first substrate 100 (FIG. 21 and FIG. 22B), the number of through electrodes can be reduced, and the insulating region 212 can be reduced. Therefore, a large area of the semiconductor element formation region in the semiconductor layer 200S can be secured. As a result, for example, the size of the amplification transistor AMP can be increased, and noise can be suppressed.

The element isolation region 213 is provided on the front surface side of the semiconductor layer 200S. The element isolation region 213 has a shallow trench isolation (STI) structure. In the element isolation region 213, the semiconductor layer 200S is dug in the thickness direction (the direction perpendicular to the main surface of the second substrate 200), and an insulating film is embedded in the dug. This insulating film includes, for example, silicon oxide. The element isolation region 213 isolates the plurality of transistors constituting the pixel circuit 210 from each other in accordance with the layout of the pixel circuit 210. The semiconductor layer 200S (specifically, a well region 211) extends below the element isolation region 213 (deep portion of the semiconductor layer 200S).

Here, a difference between the outer shape (outer shape in the substrate planar direction) of the pixel sharing unit 539 on the first substrate 100 and the outer shape of the pixel sharing unit 539 on the second substrate 200 will be described with reference to FIGS. 22A, 22B, and 23.

In the solid-state imaging device 1, the pixel sharing unit 539 is provided over both the first substrate 100 and the second substrate 200. For example, the outer shape of the pixel sharing unit 539 provided on the first substrate 100 is different from the outer shape of the pixel sharing unit 539 provided on the second substrate 200.

In FIGS. 22A and 22B, the outline of the pixels 541A, 541B, 541C, and 541D is indicated by a one-dot chain line, and the outer shape of the pixel sharing unit 539 is indicated by a thick line. For example, the pixel sharing unit 539 of the first substrate 100 includes two pixels 541 (pixels 541A and 541B) arranged adjacent to each other in the H direction and two pixels 541 (pixels 541C and 541D) arranged adjacent to each other in the V direction. That is, the pixel sharing unit 539 of the first substrate 100 includes four pixels 541 in adjacent two rows×two columns, and the pixel sharing unit 539 of the first substrate 100 has a substantially square outer shape. In the pixel array unit 540, such pixel sharing units 539 are arranged adjacent to each other at a two-pixel pitch (a pitch corresponding to two pixels 541) in the H direction and a two-pixel pitch (a pitch corresponding to two pixels 541) in the V direction.

In FIGS. 23 and 24, the outline of the pixels 541A, 541B, 541C, and 541D is indicated by a one-dot chain line, and the outer shape of the pixel sharing unit 539 is indicated by a thick line. For example, the outer shape of the pixel sharing unit 539 of the second substrate 200 is smaller than the pixel sharing unit 539 of the first substrate 100 in the H direction and larger than the pixel sharing unit 539 of the first substrate 100 in the V direction. For example, the pixel sharing unit 539 of the second substrate 200 is formed in a size (region) corresponding to one pixel in the H direction, and is formed in a size corresponding to four pixels in the V direction. That is, the pixel sharing unit 539 of the second substrate 200 is formed in a size corresponding to the pixels arranged in adjacent one row x four columns, and the pixel sharing unit 539 of the second substrate 200 has a substantially rectangular outer shape.

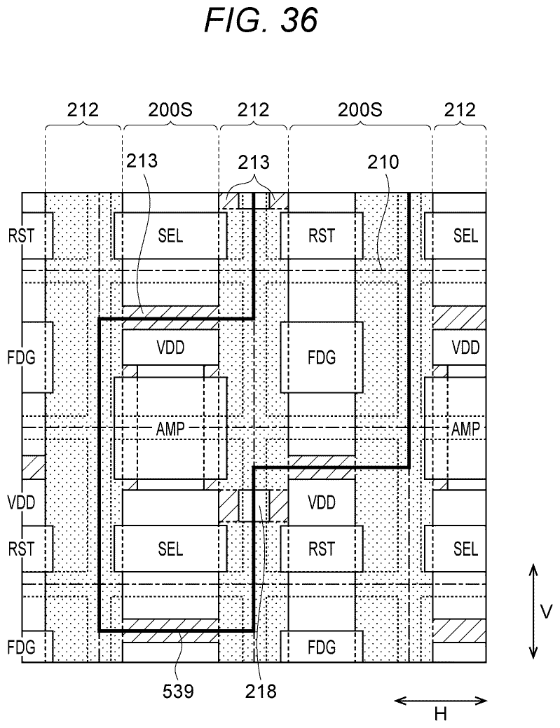

For example, in each pixel circuit 210, the selection transistor SEL, the amplification transistor AMP, the reset transistor RST, and the FD conversion gain switching transistor FDG are arranged in this order in the V direction (FIG. 23). By providing the outer shape of each pixel circuit 210 in a substantially rectangular shape as described above, four transistors (selection transistor SEL, amplification transistor AMP, reset transistor RST, and FD conversion gain switching transistor FDG) can be arranged side by side in one direction (V direction in FIG. 23). As a result, the drain of the amplification transistor AMP and the drain of the reset transistor RST can be shared by one diffusion region (diffusion region connected to the power supply line VDD). For example, the formation region of each pixel circuit 210 can be provided in a substantially square shape (see FIG. 36 described later). In this case, two transistors are arranged along one direction, and it is difficult to share the drain of the amplification transistor AMP and the drain of the reset transistor RST in one diffusion region. Therefore, by providing the formation region of the pixel circuit 210 in a substantially rectangular shape, the four transistors can be easily arranged close to each other, and the formation region of the pixel circuit 210 can be reduced. That is, the pixels can be miniaturized. Furthermore, when it is unnecessary to reduce the formation region of the pixel circuit 210, the formation region of the amplification transistor AMP can be increased to suppress noise.

For example, in the vicinity of the surface of the semiconductor layer 200S, a VSS contact region 218 connected to the reference potential line VSS is provided in addition to the selection transistor SEL, the amplification transistor AMP, the reset transistor RST, and the FD conversion gain switching transistor FDG. The VSS contact region 218 includes, for example, a p-type semiconductor region. The VSS contact region 218 is electrically connected to the VSS contact region 118 of the first substrate 100 (semiconductor layer 100S) via the wiring of the wiring layer 200T and the through electrode 121E. The VSS contact region 218 is provided, for example, at a position adjacent to the source of the FD conversion gain switching transistor FDG with the element isolation region 213 interposed therebetween (FIG. 23).

Next, a positional relationship between the pixel sharing unit 539 provided on the first substrate 100 and the pixel sharing unit 539 provided on the second substrate 200 will be described with reference to FIGS. 22B and 23. For example, one (for example, the upper side on the paper surface of FIG. 22B) pixel sharing unit 539 of the two pixel sharing units 539 arranged in the V direction on the first substrate 100 is connected to one (for example, the left side on the paper surface of FIG. 23) pixel sharing unit 539 of the two pixel sharing units 539 arranged in the H direction on the second substrate 200. For example, the other (for example, the lower side on the paper surface of FIG. 22B) pixel sharing unit 539 of the two pixel sharing units 539 arranged in the V direction on the first substrate 100 is connected to the other (for example, the right side on the paper surface of FIG. 23) pixel sharing unit 539 of the two pixel sharing units 539 arranged in the H direction on the second substrate 200.

For example, in the two pixel sharing units 539 arranged in the H direction of the second substrate 200, the internal layout (arrangement of transistors and the like) of one pixel sharing unit 539 is substantially equal to the layout obtained by inverting the internal layout of the other pixel sharing unit 539 in the V direction and the H direction. Hereinafter, effects obtained by this layout will be described.

In the two pixel sharing units 539 arranged in the V direction of the first substrate 100, each pad portion 120 is arranged at the central portion of the outer shape of the pixel sharing unit 539, that is, at the central portions in the V direction and the H direction of the pixel sharing unit 539 (FIG. 22B). On the other hand, since the pixel sharing unit 539 of the second substrate 200 has a substantially rectangular outer shape long in the V direction as described above, for example, the amplification transistor AMP connected to the pad portion 120 is arranged at a position shifted upward on the paper surface from the center of the pixel sharing unit 539 in the V direction. For example, when the internal layouts of the two pixel sharing units 539 arranged in the H direction of the second substrate 200 are the same, the distance between the amplification transistor AMP of one pixel sharing unit 539 and the pad portion 120 (for example, the pad portion 120 of the pixel sharing unit 539 on the upper side on the paper surface of FIG. 22) becomes relatively short. However, the distance between the amplification transistor AMP of the other pixel sharing unit 539 and the pad portion 120 (for example, the pad portion 120 of the pixel sharing unit 539 on the lower side on the paper surface of FIG. 22) becomes long. For this reason, the area of the wiring required for connecting the amplification transistor AMP and the pad portion 120 increases, and the wiring layout of the pixel sharing unit 539 may become complicated. This may affect miniaturization of the solid-state imaging device 1.

On the other hand, by inverting the internal layout of the two pixel sharing units 539 arranged in the H direction of the second substrate 200 at least in the V direction, the distance between the amplification transistor AMP and the pad portion 120 of both of the two pixel sharing units 539 can be shortened. Therefore, it is easy to miniaturize the solid-state imaging device 1 as compared with a configuration in which the internal layouts of the two pixel sharing units 539 arranged in the H direction of the second substrate 200 are the same. Note that the planar layout of each of the plurality of pixel sharing units 539 of the second substrate 200 is bilaterally symmetrical in the range illustrated in FIG. 23, but is bilaterally asymmetrical when including the layout of the first wiring layer W1 described later in FIG. 24.

Furthermore, it is preferable that the internal layouts of the two pixel sharing units 539 arranged in the H direction of the second substrate 200 are also inverted in the H direction. A reason for this will be described hereinafter. As illustrated in FIG. 24, each of the two pixel sharing units 539 arranged in the H direction on the second substrate 200 is connected to the pad portions 120 and 121 of the first substrate 100. For example, the pad portions 120 and 121 are arranged at the central portion in the H direction (between the two pixel sharing units 539 arranged in the H direction) of the two pixel sharing units 539 arranged in the H direction on the second substrate 200. Therefore, it is possible to reduce the distance between each of the plurality of pixel sharing units 539 of the second substrate 200 and the pad portions 120 and 121 by inverting the internal layouts of the two pixel sharing units 539 arranged in the H direction of the second substrate 200 in the H direction. That is, it is easier to miniaturize the solid-state imaging device 1.

Furthermore, the position of the outline of the pixel sharing unit 539 of the second substrate 200 may not be aligned with the position of any outline of the pixel sharing unit 539 of the first substrate 100. For example, in one (for example, the left side of the paper surface of FIG. 24) pixel sharing unit 539 of the two pixel sharing units 539 arranged in the H direction on the second substrate 200, the outline of one (for example, the upper side on the paper surface of FIG. 24) in the V direction is arranged outside the outline of one in the V direction of the pixel sharing unit 539 (for example, the upper side on the paper surface of FIG. 22B) of the corresponding first substrate 100. Furthermore, in the other (for example, the right side on the paper surface of FIG. 24) pixel sharing unit 539 of the two pixel sharing units 539 arranged in the H direction on the second substrate 200, the outline of the other (for example, the lower side on the paper surface of FIG. 24) in the V direction is arranged outside the outline of the other in the V direction of the pixel sharing unit 539 (for example, the lower side on the paper surface of FIG. 22B) of the corresponding first substrate 100. As described above, by arranging the pixel sharing unit 539 of the second substrate 200 and the pixel sharing unit 539 of the first substrate 100 to each other, the distance between the amplification transistor AMP and the pad portion 120 can be shortened. Therefore, it is easy to miniaturize the solid-state imaging device 1.

Furthermore, the positions of the outlines of the plurality of pixel sharing units 539 of the second substrate 200 may not be aligned. For example, the two pixel sharing units 539 arranged in the H direction of the second substrate 200 are arranged such that the positions of the outlines in the V direction are shifted. As a result, the distance between the amplification transistor AMP and the pad portion 120 can be shortened. Therefore, it is easy to miniaturize the solid-state imaging device 1.

The repetitive arrangement of the pixel sharing units 539 in the pixel array unit 540 will be described with reference to FIGS. 22B and 24. The pixel sharing unit 539 of the first substrate 100 has the sizes of two pixels 541 in the H direction and the sizes of two pixels 541 in the V direction (FIG. 22B). For example, in the pixel array unit 540 of the first substrate 100, the pixel sharing units 539 having sizes corresponding to the four pixels 541 are repeatedly arranged adjacent to each other at a pitch of two pixels in the H direction (a pitch corresponding to two pixels 541) and at a pitch of two pixels in the V direction (a pitch corresponding to two pixels 541). Alternatively, the pixel array unit 540 of the first substrate 100 may be provided with a pair of pixel sharing units 539 in which two pixel sharing units 539 are arranged adjacent to each other in the V direction. In the pixel array unit 540 of the first substrate 100, for example, the pair of pixel sharing units 539 is repeatedly arranged adjacent to each other at a pitch of two pixels in the H direction (a pitch corresponding to two pixels 541) and at a pitch of four pixels in the V direction (a pitch corresponding to four pixels 541). The pixel sharing unit 539 of the second substrate 200 has the size of one pixel 541 in the H direction and the size of four pixels 541 in the V direction (FIG. 24). For example, the pixel array unit 540 of the second substrate 200 is provided with a pair of pixel sharing units 539 including two pixel sharing units 539 having a size corresponding to the four pixels 541. The pixel sharing units 539 are arranged adjacent to each other in the H direction and are arranged to be shifted in the V direction. In the pixel array unit 540 of the second substrate 200, for example, the pair of pixel sharing units 539 is repeatedly arrayed adjacent to each other without a gap at a pitch of two pixels in the H direction (a pitch corresponding to two pixels 541) and at a pitch of four pixels in the V direction (a pitch corresponding to four pixels 541). Such repetitive arrangement of the pixel sharing units 539 enables the pixel sharing units 539 to be arranged without any gap. Therefore, it is easy to miniaturize the solid-state imaging device 1.

The amplification transistor AMP preferably has, for example, a three-dimensional structure such as a fin type (FIG. 21). As a result, the size of the effective gate width increases, and noise can be suppressed. The selection transistor SEL, the reset transistor RST, and the FD conversion gain switching transistor FDG have, for example, a planar structure. The amplification transistor AMP may have a planar structure. Alternatively, the selection transistor SEL, the reset transistor RST, or the FD conversion gain switching transistor FDG may have a three-dimensional structure.

The wiring layer 200T includes, for example, a passivation film 221, an interlayer insulating film 222, and a plurality of wirings (first wiring layer W1, second wiring layer W2, third wiring layer W3, and fourth wiring layer W4). The passivation film 221 is, for example, in contact with the surface of the semiconductor layer 200S and covers the entire surface of the semiconductor layer 200S. The passivation film 221 covers the gate electrodes of the selection transistor SEL, the amplification transistor AMP, the reset transistor RST, and the FD conversion gain switching transistor FDG. The interlayer insulating film 222 is provided between the passivation film 221 and the third substrate 300. A plurality of wirings (first wiring layer W1, second wiring layer W2, third wiring layer W3, and fourth wiring layer W4) is separated by the interlayer insulating film 222. The interlayer insulating film 222 includes, for example, silicon oxide.

In the wiring layer 200T, for example, a first wiring layer W1, a second wiring layer W2, a third wiring layer W3, a fourth wiring layer W4, and contact portions 201 and 202 are provided in this order from the semiconductor layer 200S side, and these layers are insulated from each other by an interlayer insulating film 222. The interlayer insulating film 222 is provided with a plurality of connection portions that connect the first wiring layer W1, the second wiring layer W2, the third wiring layer W3 or the fourth wiring layer W4 and lower layers thereof. The connection portion is a portion in which a conductive material is embedded in a connection hole provided in the interlayer insulating film 222. For example, the interlayer insulating film 222 is provided with a connection portion 218V that connects the first wiring layer W1 and the VSS contact region 218 of the semiconductor layer 200S. For example, the hole diameter of the connection portion connecting the elements of such a second substrate 200 is different from the hole diameters of the through electrodes 120E and 121E and the through electrode TGV. Specifically, the hole diameter of the connection hole connecting the elements of the second substrate 200 is preferably smaller than the hole diameters of the through electrodes 120E and 121E and the through electrode TGV. A reason for this will be described hereinafter. The depth of the connection portion (the connection portion 218V or the like) provided in the wiring layer 200T is smaller than the depths of the through electrodes 120E and 121E and the through electrode TGV. Therefore, the connection portion can easily fill the conductive material in the connection hole as compared with the through electrodes 120E and 121E and the through electrode TGV. By making the hole diameter of the connection portion smaller than the hole diameters of the through electrodes 120E and 121E and the through electrode TGV, it is easy to miniaturize the solid-state imaging device 1.

For example, the through electrode 120E is connected to the gate of the amplification transistor AMP and the source of the FD conversion gain switching transistor FDG (specifically, a connection hole reaching the source of the FD conversion gain switching transistor FDG) by the first wiring layer W1. The first wiring layer W1 connects, for example, the through electrode 121E and the connection portion 218V, whereby the VSS contact region 218 of the semiconductor layer 200S and the VSS contact region 118 of the semiconductor layer 100S are electrically connected.

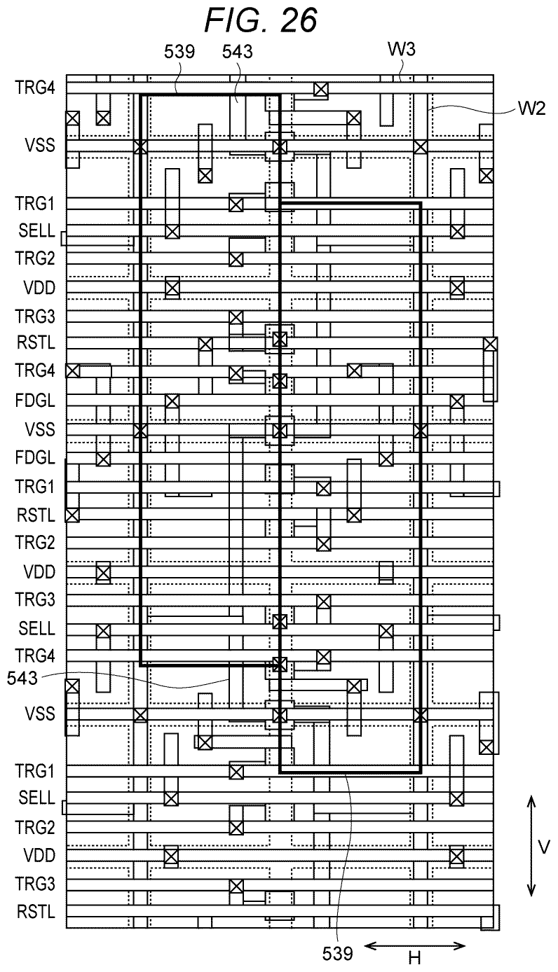

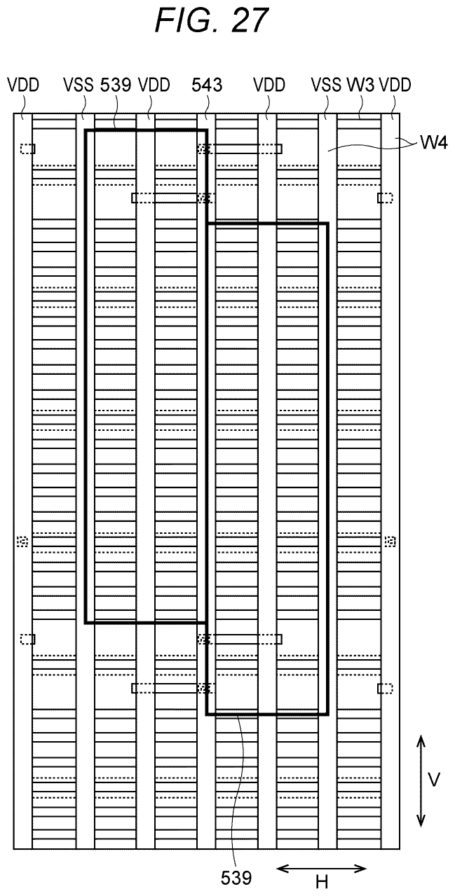

Next, a planar configuration of the wiring layer 200T will be described with reference to FIGS. 25 to 27. FIG. 25 illustrates an example of a planar configuration of the first wiring layer W1 and the second wiring layer W2. FIG. 26 illustrates an example of a planar configuration of the second wiring layer W2 and the third wiring layer W3. FIG. 27 illustrates an example of a planar configuration of the third wiring layer W3 and the fourth wiring layer W4.

For example, the third wiring layer W3 includes wiring lines TRG1, TRG2, TRG3, TRG4, SELL, RSTL, and FDGL extending in the H direction (row direction) (FIG. 26). These wirings correspond to the plurality of row drive signal lines 542 described with reference to FIG. 19. The wiring lines TRG1, TRG2, TRG3, and TRG4 are for sending drive signals to the transfer gates TG1, TG2, TG3, and TG4, respectively. The wiring lines TRG1, TRG2, TRG3, and TRG4 are connected to the transfer gates TG1, TG2, TG3, and TG4 via the second wiring layer W2, the first wiring layer W1, and the through electrode 120E, respectively. The wiring SELL is for sending a drive signal to the gate of the selection transistor SEL, the wiring RSTL is for sending a drive signal to the gate of the reset transistor RST, and the wiring FDGL is for sending a drive signal to the gate of the FD conversion gain switching transistor FDG. The wirings SELL, RSTL, and FDGL are connected to the gates of the selection transistor SEL, the reset transistor RST, and the FD conversion gain switching transistor FDG via the second wiring layer W2, the first wiring layer W1, and the connection portion, respectively.

For example, the fourth wiring layer W4 includes a power supply line VDD, a reference potential line VSS, and a vertical signal line 543 extending in the V direction (column direction) (FIG. 27). The power supply line VDD is connected to the drain of the amplification transistor AMP and the drain of the reset transistor RST via the third wiring layer W3, the second wiring layer W2, the first wiring layer W1, and the connection portion. The reference potential line VSS is connected to the VSS contact region 218 via the third wiring layer W3, the second wiring layer W2, the first wiring layer W1, and the connection portion 218V. In addition, the reference potential line VSS is connected to the VSS contact region 118 of the first substrate 100 via the third wiring layer W3, the second wiring layer W2, the first wiring layer W1, the through electrode 121E, and the pad portion 121. The vertical signal line 543 is connected to the source (Vout) of the selection transistor SEL via the third wiring layer W3, the second wiring layer W2, the first wiring layer W1, and the connection portion.

The contact portions 201 and 202 may be provided at a position overlapping the pixel array unit 540 in plan view (for example, FIG. 18), or may be provided in the peripheral portion 540B outside the pixel array unit 540 (for example, FIG. 21). The contact portions 201 and 202 are provided on the surface (surface on the wiring layer 200T side) of o the second substrate 200. The contact portions 201 and 202 are constituted by, for example, metal such as copper (Cu) and aluminum (Al). The contact portions 201 and 202 are exposed on the surface (surface on the third substrate 300 side) of the wiring layer 200T. The contact portions 201 and 202 are used for electrical connection between the second substrate 200 and the third substrate 300 and bonding between the second substrate 200 and the third substrate 300.

FIG. 21 illustrates an example in which a peripheral circuit is provided in the peripheral portion 540B of the second substrate 200. The peripheral circuit may include a part of the row drive unit 520, a part of the column signal processing unit 550, or the like. Furthermore, as illustrated in FIG. 18, the peripheral circuit may not be arranged in the peripheral portion 540B of the second substrate 200, and the connection holes H1 and H2 may be arranged in the vicinity of the pixel array unit 540.

The third substrate 300 includes, for example, a wiring layer 300T and a semiconductor layer 300S in this order from the second substrate 200 side. For example, the surface of the semiconductor layer 300S is provided on the second substrate 200 side. The semiconductor layer 300S includes a silicon substrate. A circuit is provided in a portion on the front surface side of the semiconductor layer 300S. Specifically, for example, at least a part of the input unit 510A, the row drive unit 520, the timing control unit 530, the column signal processing unit 550, the image signal processing unit 560, and the output unit 510B is provided in the portion on the front surface side of the semiconductor layer 300S. The wiring layer 300T provided between the semiconductor layer 300S and the second substrate 200 includes, for example, an interlayer insulating film, a plurality of wiring layers separated by the interlayer insulating film, and contact portions 301 and 302. The contact portions 301 and 302 are exposed on the surface (the surface on the second substrate 200 side) of the wiring layer 300T, the contact portion 301 is in contact with the contact portion 201 of the second substrate 200, and the contact portion 302 is in contact with the contact portion 202 of the second substrate 200. The contact portions 301 and 302 are electrically connected to a circuit (for example, at least one of the input unit 510A, the row drive unit 520, the timing control unit 530, the column signal processing unit 550, the image signal processing unit 560, or the output unit 510B) formed in the semiconductor layer 300S. The contact portions 301 and 302 are constituted by, for example, metal such as copper (Cu) and aluminum (Al). For example, the external terminal TA is connected to the input unit 510A via the connection hole H1, and the external terminal TB is connected to the output unit 510B via the connection hole H2.

Here, features of the solid-state imaging device 1 will be described.

In general, the solid-state imaging device 1 mainly includes a photodiode PD and a pixel circuit. Here, in a case where the area of the photodiode is increased, charge generated as a result of photoelectric conversion increases, and as a result, a signal/noise ratio (S/N ratio) of a pixel signal improves, and the solid-state imaging device can output better image data (image information). In a case where the size of the transistor (particularly, the size of the amplification transistor) included in the pixel circuit is increased, on the other hand, noise generated in the pixel circuit is reduced, and as a result, the S/N ratio of the imaging signal improves, and the solid-state imaging device can output better image data (image information).

If the area of the photodiode PD is increased in a limited area of the semiconductor substrate in an imaging device in which a photodiode PD and a pixel circuit are provided in the same semiconductor substrate, however, the size of a transistor included in the pixel circuit might be reduced. Furthermore, if the size of the transistor included in the pixel circuit is increased, the area of the photodiode PD might be reduced.

In order to solve these problems, for example, the solid-state imaging device 1 of the present embodiment uses a structure in which a plurality of pixels 541 shares one pixel circuit 210 and the shared pixel circuit 210 is arranged in such a way as to overlap the photodiode PD. As a result, it is possible to realize making the area of the photodiode PD as large as possible and making the size of the transistor included in the pixel circuit 210 as large as possible within the limited area of the semiconductor substrate. As a result, the S/N ratio of the pixel signal can be improved, and the solid-state imaging device 1 can output better image data (image information).

When a structure in which the plurality of pixels 541 shares one pixel circuit 210 and the pixel circuit is superimposed and arranged on the photodiode PD is realized, a plurality of wirings connected to one pixel circuit 210 extends from the floating diffusion FD of each of the plurality of pixels 541. In order to secure a large area of the semiconductor layer 200S forming the pixel circuit 210, for example, a connection wiring can be formed in which a plurality of extending wirings is connected to each other and integrated into one. Similarly, for the plurality of wirings extending from the VSS contact region 118, it is possible to form a connection wiring in which the plurality of extending wirings is connected to each other and integrated into one.

For example, in a case where a connection wiring that mutually connects a plurality of wirings extending from the floating diffusion FD of each of the plurality of pixels 541 is formed in the semiconductor layer 200S forming the pixel circuit 210, it is conceivable that an area for forming a transistor included in the pixel circuit 210 is reduced. Similarly, in a case where a connection wiring that interconnects a plurality of wirings extending from the VSS contact region 118 of each of the plurality of pixels 541 and combines the plurality of wirings into one is formed on the semiconductor layer 200S forming the pixel circuit 210, it is conceivable that an area for forming a transistor included in the pixel circuit 210 is reduced.

In order to solve these problems, for example, the solid-state imaging device 1 of the present embodiment can have a structure in which a plurality of pixels 541 shares one pixel circuit 210, and the shared pixel circuit 210 is arranged to be superimposed on the photodiode PD, and a structure in which a connection wiring that connects the floating diffusions FD of each of the plurality of pixels 541 to each other and integrates them into one, and a connection wiring that connects the VSS contact regions 118 included in each of the plurality of pixels 541 to each other and integrates them into one are provided on the first substrate 100.

Here, in a case where the above-described second manufacturing method is used as a manufacturing method for providing, on the first substrate 100, the connection wiring that connects the floating diffusions FD of each of the plurality of pixels 541 to each other and integrates them into one and the connection wiring that connects the VSS contact regions 118 of each of the plurality of pixels 541 to each other and integrates them into one, for example, it is possible to manufacture a solid-state imaging device 1 with high quality and high performance using an appropriate process according to the configuration of each of the first substrate 100 and the second substrate 200. In addition, the connection wiring of the first substrate 100 and the second substrate 200 can be formed by an easy process. Specifically, in the case of using the second manufacturing method described above, an electrode connected to the floating diffusion FD and an electrode connected to the VSS contact region 118 are provided on the surface of the first substrate 100 and the surface of the second substrate 200, which are the bonding boundary surfaces of the first substrate 100 and the second substrate 200, respectively. Moreover, it is preferable to enlarge the electrodes formed on the two substrate surfaces so that the electrodes formed on the two substrate surfaces come into contact with each other even if positional deviation occurs between the electrodes provided on the two substrate surfaces when the first substrate 100 and the second substrate 200 are bonded together. In this case, it is conceivable that it becomes difficult to arrange the electrode described above in a limited area of each pixel included in the solid-state imaging device 1.

In order to solve the problem that a large electrode is required at the bonding boundary surface between the first substrate 100 and the second substrate 200, for example, the solid-state imaging device 1 of the present embodiment can use the first manufacturing method described above as a manufacturing method in which a plurality of pixels 541 shares one pixel circuit 210, and the shared pixel circuit 210 is arranged to be superimposed on the photodiode PD. As a result, it is easy to align the elements formed on the first substrate 100 and the second substrate 200, and a high-quality and high-performance solid-state imaging device 1 can be manufactured. Moreover, a unique structure generated by using this manufacturing method can be provided. That is, the solid-state imaging device includes a structure in which the semiconductor layer 100S and the wiring layer 100T of the first substrate 100 and the semiconductor layer 200S and the wiring layer 200T of the second substrate 200 are laminated in this order, in other words, a structure in which the first substrate 100 and the second substrate 200 are laminated in a face-to-back manner, and the through electrodes 120E and 121E that penetrate the semiconductor layer 200S, the wiring layer 100T of the first substrate 100, and reach the surface of the semiconductor layer 100S of the first substrate 100 from the front surface side of the semiconductor layer 200S of the second substrate 200.

In a structure in which the connection wiring that connects the floating diffusions FD of the plurality of pixels 541 to each other and integrates them into one and the connection wiring that connects the VSS contact regions 118 of the plurality of pixels 541 to each other and integrates them into one are provided on the first substrate 100, when this structure and the second substrate 200 are laminated using the first manufacturing method to form the pixel circuit 210 on the second substrate 200, there is a possibility that the influence of the heating treatment required when the active element included in the pixel circuit 210 is formed may reach the above-described connection wiring formed on the first substrate 100.

Therefore, in order to solve the problem that the above-described connection wiring is affected by the heating treatment when the above-described active element is formed, it is desirable that the solid-state imaging device 1 of the present embodiment use a conductive material having high heat resistance for the connection wiring that connects the floating diffusions FD of the plurality of pixels 541 to each other and integrates them into one and the connection wiring that connects the VSS contact regions 118 of the plurality of pixels 541 to each other and integrates them into one. Specifically, as the conductive material having high heat resistance, a material having a melting point higher than that of at least a part of the wiring material included in the wiring layer 200T of the second substrate 200 can be used.

As described above, for example, the solid-state imaging device 1 of the present embodiment includes: (1) a structure in which the first substrate 100 and the second substrate 200 are laminated in a face-to-back manner (specifically, a structure in which the semiconductor layer 100S and the wiring layer 100T of the first substrate 100 and the semiconductor layer 200S and the wiring layer 200T of the second substrate 200 are laminated in this order); (2) a structure in which the through electrodes 120E and 121E are provided from the front surface side of the semiconductor layer 200S of the second substrate 200, penetrating the semiconductor layer 200S and the wiring layer 100T of the first substrate 100, and reaching the surface of the semiconductor layer 100S of the first substrate 100; and (3) a structure in which the connection wiring that connects the floating diffusions FD included in the plurality of pixels 541 to each other and integrates them into one and the connection wiring that connects the VSS contact regions 118 included in the plurality of pixels 541 to each other and integrates them into one are constituted by a conductive material having high heat resistance. Therefore, without providing a large electrode at the interface between the first substrate 100 and the second substrate 200, the first substrate 100 can be provided with the connection wiring that connects the floating diffusions FD included in the plurality of pixels 541 to each other and integrates them into one and the connection wiring that connects the VSS contact regions 118 included in the plurality of pixels 541 to each other and integrates them into one.

### [Operation of Solid-State Imaging Device 1]

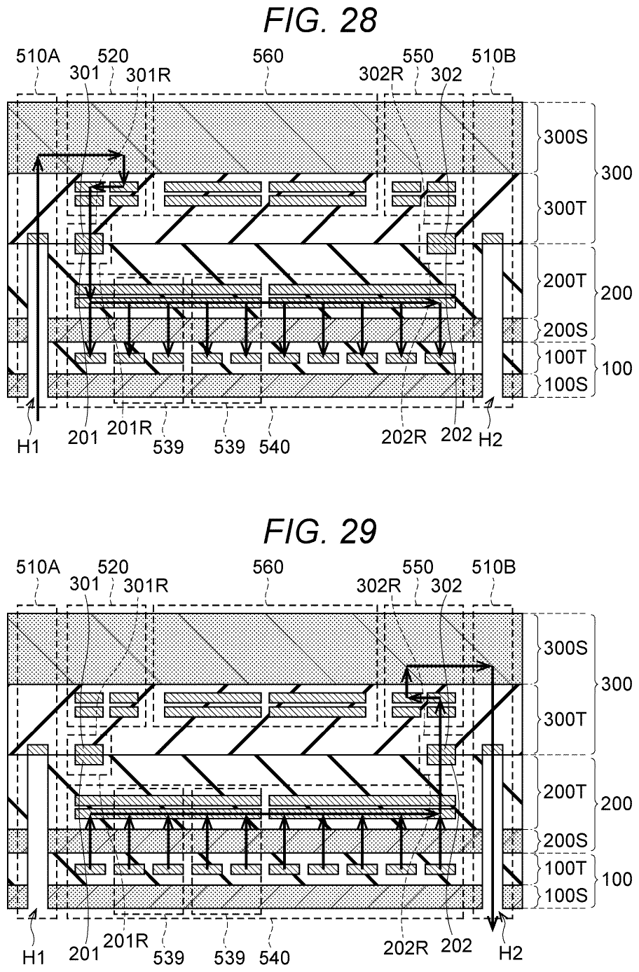

Next, the operation of the solid-state imaging device 1 will be described with reference to FIGS. 28 and 29. In FIGS. 28 and 29, an arrow representing a path of each signal is added to FIG. 18. In FIG. 28, an input signal input to the solid-state imaging device 1 from the outside, and paths of a power supply potential and a reference potential are indicated by arrows. In FIG. 29, a signal path of a pixel signal output from the solid-state imaging device 1 to the outside is indicated by an arrow. For example, an input signal (for example, a pixel clock and a synchronization signal) input to the solid-state imaging device 1 via the input unit 510A is transmitted to the row drive unit 520 of the third substrate 300, and the row drive unit 520 creates a row drive signal. The row drive signal is sent to the second substrate 200 via the contact portions 301 and 201. Moreover, the row drive signal reaches each of the pixel sharing units 539 of the pixel array unit 540 via the row drive signal line 542 in the wiring layer 200T. Among the row drive signals reaching the pixel sharing unit 539 of the second substrate 200, drive signals other than the transfer gate TG are input to the pixel circuit 210, and each transistor included in the pixel circuit 210 is driven. A drive signal of the transfer gate TG is input to the transfer gates TG1, TG2, TG3, and TG4 of the first substrate 100 via the through electrode TGV, and the pixels 541A, 541B, 541C, and 541D are driven (FIG. 28). Furthermore, the power supply potential and the reference potential supplied from the outside of the solid-state imaging device 1 to the input unit 510A (input terminal 511) of the third substrate 300 are sent to the second substrate 200 via the contact portions 301 and 201, and supplied to the pixel circuit 210 of each of the pixel sharing units 539 via the wiring in the wiring layer 200T. The reference potential is further supplied to the pixels 541A, 541B, 541C, and 541D of the first substrate 100 via the through electrode 121E. On the other hand, the pixel signal photoelectrically converted by the pixels 541A, 541B, 541C, and 541D of the first substrate 100 is sent to the pixel circuit 210 of the second substrate 200 for each pixel sharing unit 539 via the through electrode 120E. The pixel signal based on this pixel signal is sent from the pixel circuit 210 to the third substrate 300 via the vertical signal line 543 and the contact portions 202 and 302. This pixel signal is processed by the column signal processing unit 550 and the image signal processing unit 560 of the third substrate 300, and then output to the outside via the output unit 510B.

### Effects

In the present embodiment, the pixels 541A, 541B, 541C, and 541D (pixel sharing unit 539) and the pixel circuit 210 are provided on different substrates (first substrate 100 and second substrate 200). As a result, the areas of the pixels 541A, 541B, 541C, and 541D and the pixel circuit 210 can be enlarged as compared with a case where the pixels 541A, 541B, 541C, and 541D and the pixel circuit 210 are formed on the same substrate. As a result, the amount of pixel signals obtained by photoelectric conversion can be increased, and transistor noise of the pixel circuit 210 can be reduced. As a result, the signal/noise ratio of the pixel signal is improved, and the solid-state imaging device 1 can output better pixel data (image information).

Furthermore, the solid-state imaging device 1 can be miniaturized (in other words, the pixel size can be reduced and the solid-state imaging device 1 can be downsized). The solid-state imaging device 1 can increase the number of pixels per unit area by reducing the pixel size, and can output a high-quality image.

Furthermore, in the solid-state imaging device 1, the first substrate 100 and the second substrate 200 are electrically connected to each other by the through electrodes 120E and 121E provided in the insulating region 212. For example, a method of connecting the first substrate 100 and the second substrate 200 by bonding pad electrodes to each other, or a method of connecting the first substrate 100 and the second substrate 200 by through wiring (for example, through Si via (TSV)) penetrating the semiconductor layer may be considered. As compared with such a method, by providing the through electrodes 120E and 121E in the insulating region 212, the area required for connecting the first substrate 100 and the second substrate 200 can be reduced. As a result, the pixel size can be reduced, and the solid-state imaging device 1 can be further downsized. Furthermore, the resolution can be further increased by further miniaturizing the area per pixel. In a case where it is not necessary to reduce the chip size, the formation region of the pixels 541A, 541B, 541C, and 541D and the pixel circuit 210 can be enlarged. As a result, the amount of pixel signals obtained by photoelectric conversion can be increased, and noise of the transistor included in the pixel circuit 210 can be reduced. As a result, the signal/noise ratio of the pixel signal can be improved, and the solid-state imaging device 1 can output better pixel data (image information).

Furthermore, in the solid-state imaging device 1, the pixel circuit 210 and the column signal processing unit 550 and the image signal processing unit 560 are provided on different substrates (the second substrate 200 and the third substrate 300). As a result, the area of the pixel circuit 210 and the areas of the column signal processing unit 550 and the image signal processing unit 560 can be enlarged as compared with a case where the pixel circuit 210 and the column signal processing unit 550 and the image signal processing unit 560 are formed on the same substrate. As a result, noise generated in the column signal processing unit 550 can be reduced, and an advanced image processing circuit can be mounted by the image signal processing unit 560. Therefore, the signal/noise ratio of the pixel signal can be improved, and the solid-state imaging device 1 can output better pixel data (image information).

Furthermore, in the solid-state imaging device 1, the pixel array unit 540 is provided on the first substrate 100 and the second substrate 200, and the column signal processing unit 550 and the image signal processing unit 560 are provided on the third substrate 300. In addition, the contact portions 201, 202, 301, and 302 connecting the second substrate 200 and the third substrate 300 is formed above the pixel array unit 540. Therefore, the contact portions 201, 202, 301, and 302 can be freely laid out without receiving layout interference from various wirings provided in the pixel array. Accordingly, the contact portions 201, 202, 301, and 302 can be used for electrical connection between the second substrate 200 and the third substrate 300. By using the contact portions 201, 202, 301, and 302, for example, the column signal processing unit 550 and the image signal processing unit 560 have a higher degree of freedom in layout. As a result, noise generated in the column signal processing unit 550 can be reduced, and an advanced image processing circuit can be mounted by the image signal processing unit 560. Therefore, the signal/noise ratio of the pixel signal can be improved, and the solid-state imaging device 1 can output better pixel data (image information).

Furthermore, in the solid-state imaging device 1, the pixel isolation portion 117 penetrates the semiconductor layer 100S. As a result, color mixing among the pixels 541A, 541B, 541C, and 541D can be suppressed even in a case where the distance between adjacent pixels (pixels 541A, 541B, 541C, and 541D) is shortened due to miniaturization of the area per pixel. As a result, the signal/noise ratio of the pixel signal can be improved, and the solid-state imaging device 1 can output better pixel data (image information).

Furthermore, in the solid-state imaging device 1, a pixel circuit 210 is provided for each pixel sharing unit 539. As a result, as compared with a case where the pixel circuit 210 is provided in each of the pixels 541A, 541B, 541C, and 541D, the formation region of the transistor (amplification transistor AMP, reset transistor RST, selection transistor SEL, and FD conversion gain switching transistor FDG) constituting the pixel circuit 210 can be enlarged. For example, noise can be suppressed by increasing the formation region of the amplification transistor AMP. As a result, the signal/noise ratio of the pixel signal can be improved, and the solid-state imaging device 1 can output better pixel data (image information).

Moreover, in the solid-state imaging device 1, the pad portion 120 that electrically connects the floating diffusions FD (floating diffusions FD1, FD2, FD3, and FD4) of the four pixels (pixels 541A, 541B, 541C, and 541D) is provided on the first substrate 100. As a result, the number of through electrodes (through electrodes 120E) connecting the first substrate 100 and the second substrate 200 can be reduced as compared with the case where such a pad portion 120 is provided on the second substrate 200. Therefore, the insulating region 212 can be made small, and the transistor formation region (semiconductor layer 200S) constituting the pixel circuit 210 can be secured with a sufficient size. As a result, noise of the transistor included in the pixel circuit 210 can be reduced, the signal/noise ratio of the pixel signal can be improved, and the solid-state imaging device 1 can output better pixel data (image information).

Hereinafter, modifications of the solid-state imaging device 1 according to the above embodiments will be described. In the following modifications, the same reference signs are given to the same configurations as those of the above embodiments.

### <2. Modification 1>

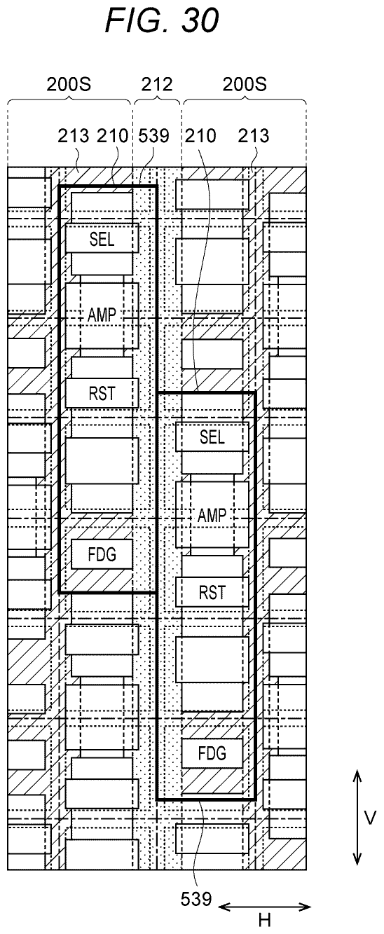

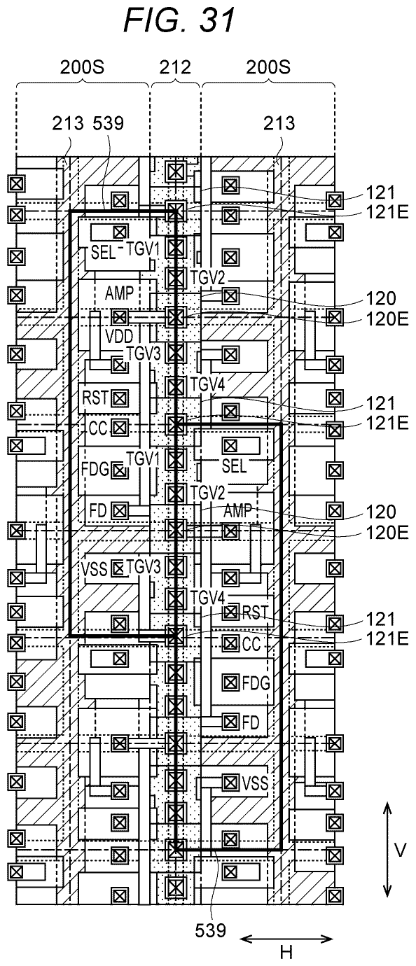

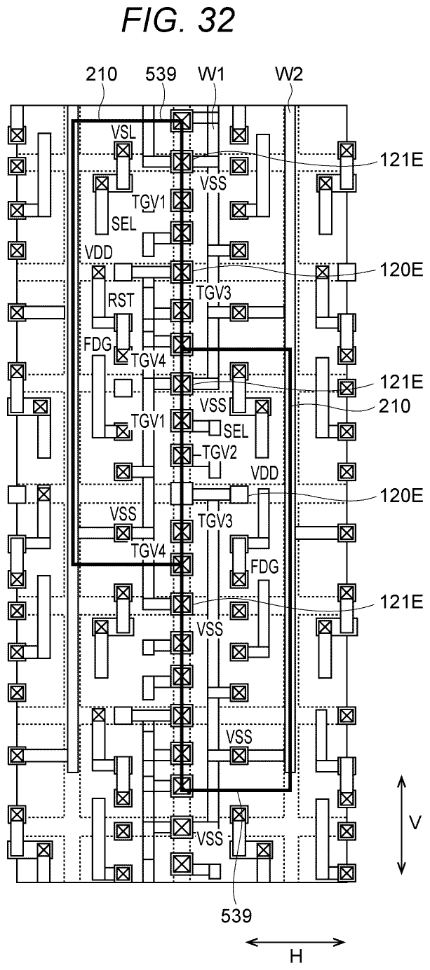

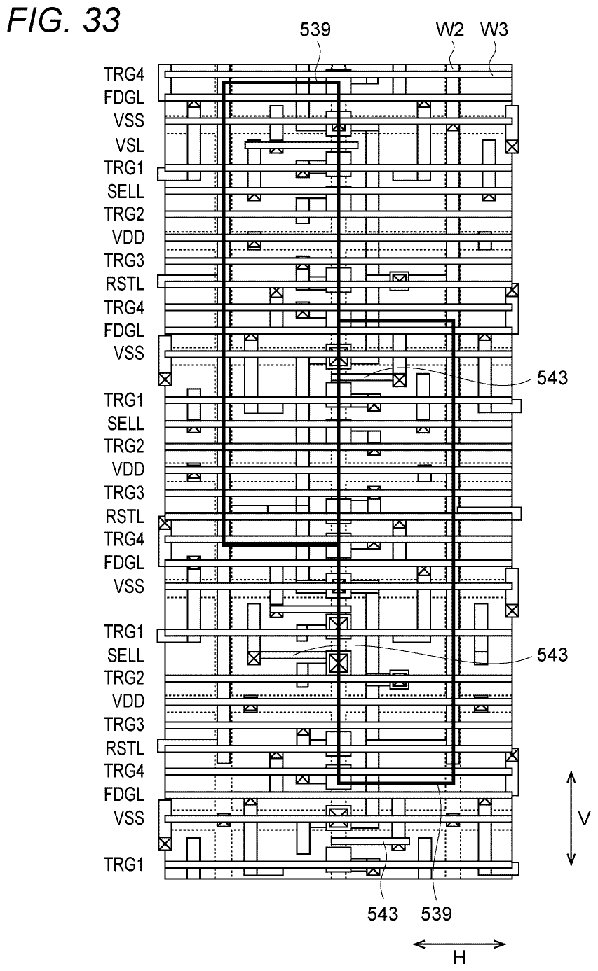

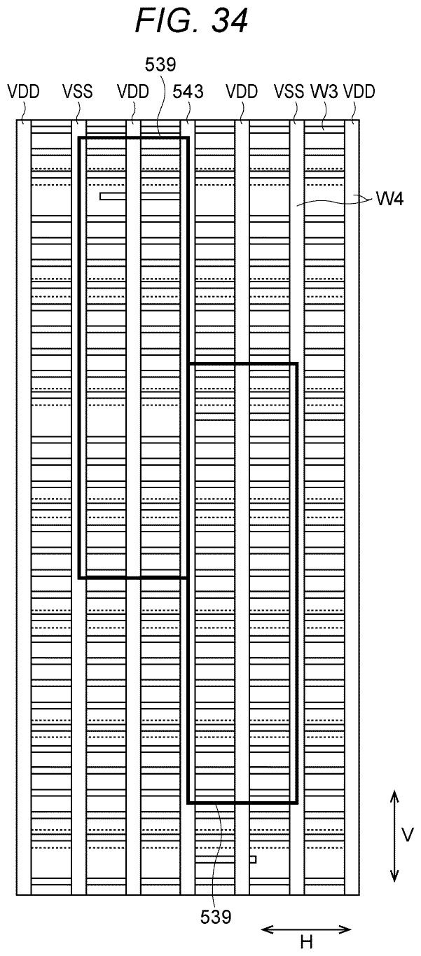

FIGS. 30 to 34 illustrate a modification of the planar configuration of the solid-state imaging device 1 according to the above embodiments. FIG. 30 schematically illustrates a planar configuration in the vicinity of the surface of the semiconductor layer 200S of the second substrate 200, and corresponds to FIG. 23 described in the above embodiments. FIG. 31 schematically illustrates a configuration of each part of the first wiring layer W1, the semiconductor layer 200S connected to the first wiring layer W1, and the first substrate 100, and corresponds to FIG. 24 described in the above embodiments. FIG. 32 illustrates an example of a planar configuration of the first wiring layer W1 and the second wiring layer W2, and corresponds to FIG. 25 described in the above embodiments. FIG. 33 illustrates an example of a planar configuration of the second wiring layer W2 and the third wiring layer W3, and corresponds to FIG. 26 described in the above embodiments. FIG. 34 illustrates an example of a planar configuration of the third wiring layer W3 and the fourth wiring layer W4, and corresponds to FIG. 27 described in the above embodiments.

In the present modification, as illustrated in FIG. 31, among the two pixel sharing units 539 arranged in the H direction on the second substrate 200, the internal layout of one (for example, the right side on the paper surface) pixel sharing unit 539 has a configuration in which the internal layout of the other (for example, the left side on the paper surface) pixel sharing unit 539 is inverted only in the H direction. In addition, the deviation in the V direction between the outline of one pixel sharing unit 539 and the outline of the other pixel sharing unit 539 is larger than the deviation (FIG. 24) described in the above embodiments. In this manner, by increasing the deviation in the V direction, the distance between the amplification transistor AMP of the other pixel sharing unit 539 and the pad portion 120 (the pad portion 120 of the other (lower side on the paper surface) of the two pixel sharing units 539 arranged in the V direction illustrated in FIG. 22) connected thereto can be reduced. With such a layout, Modification 1 of the solid-state imaging device 1 illustrated in FIGS. 30 to 34 can make the area of the planar layout of the two pixel sharing units 539 arranged in the H direction the same as the area of the pixel sharing unit 539 of the second substrate 200 described in the above embodiments without inverting the planar layout of the two pixel sharing units 539 with each other in the V direction. Note that the planar layout of the pixel sharing unit 539 of the first substrate 100 is the same as the planar layout (FIG. 22A, FIG. 22B) described in the above embodiments. Therefore, the solid-state imaging device 1 of the present modification can obtain effects similar to those of the solid-state imaging device 1 described in the above embodiments. The arrangement of the pixel sharing unit 539 of the second substrate 200 is not limited to the arrangement described in the above embodiments and the present modification.

### <3. Modification 2>

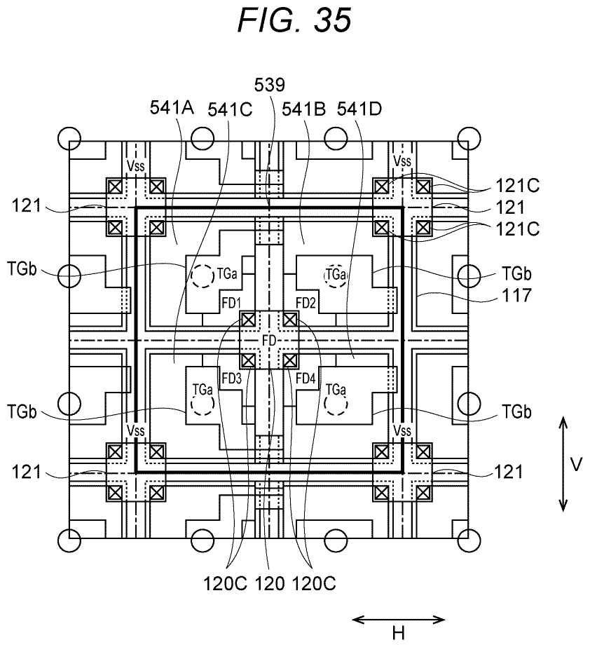

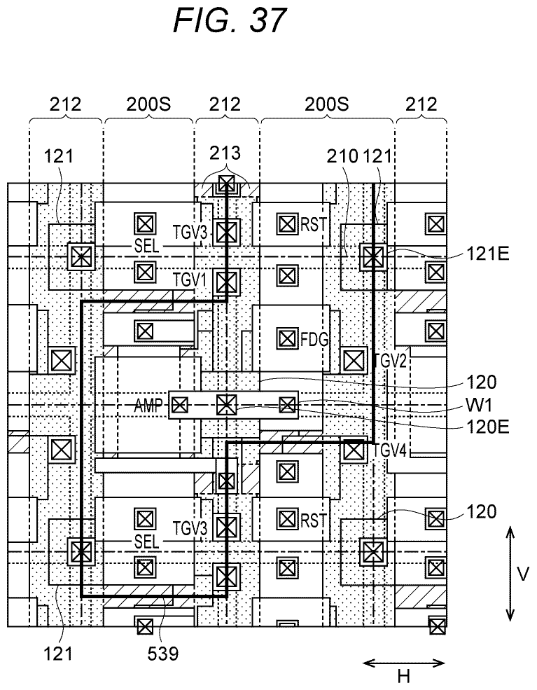

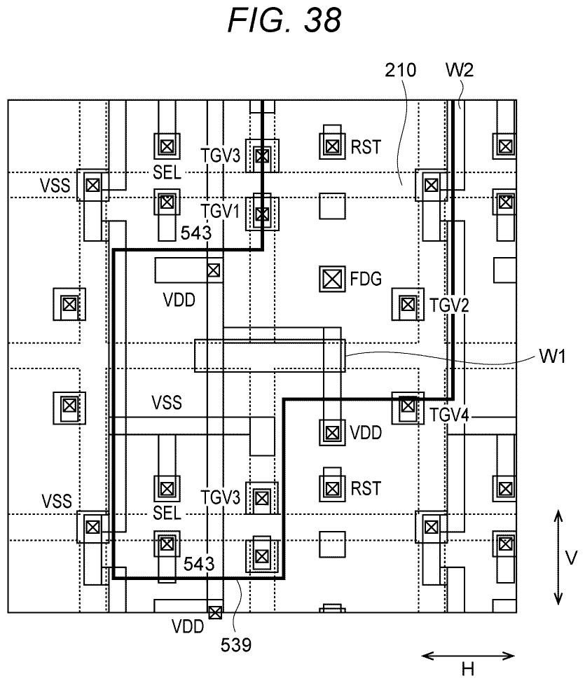

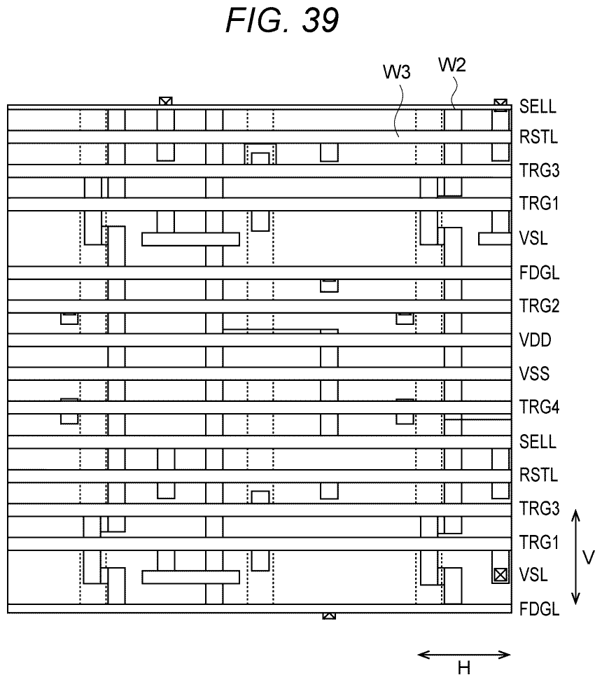

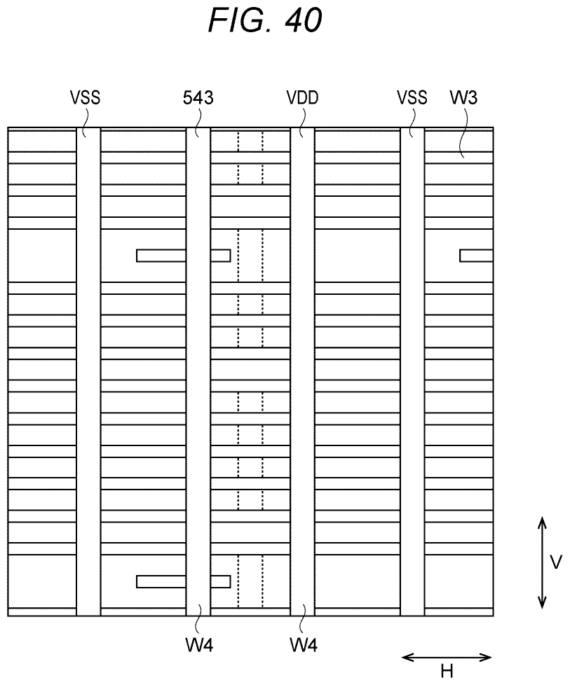

FIGS. 35 to 40 illustrate a modification of the planar configuration of the solid-state imaging device 1 according to the above embodiments. FIG. 35 schematically illustrates a planar configuration of the first substrate 100, and corresponds to FIG. 22A described in the above embodiments. FIG. 36 schematically illustrates a planar configuration in the vicinity of the surface of the semiconductor layer 200S of the second substrate 200, and corresponds to FIG. 23 described in the above embodiments. FIG. 37 schematically illustrates a configuration of each part of the first wiring layer W1, the semiconductor layer 200S connected to the first wiring layer W1, and the first substrate 100, and corresponds to FIG. 24 described in the above embodiments. FIG. 38 illustrates an example of a planar configuration of the first wiring layer W1 and the second wiring layer W2, and corresponds to FIG. 25 described in the above embodiments. FIG. 39 illustrates an example of a planar configuration of the second wiring layer W2 and the third wiring layer W3, and corresponds to FIG. 26 described in the above embodiments. FIG. 40 illustrates an example of a planar configuration of the third wiring layer W3 and the fourth wiring layer W4, and corresponds to FIG. 27 described in the above embodiments.

In the present modification, the outer shape of each pixel circuit 210 has a substantially square planar shape (FIG. 36 and the like). In this respect, the planar configuration of the solid-state imaging device 1 of the present modification is different from the planar configuration of the solid-state imaging device 1 described in the above embodiments.

For example, the pixel sharing unit 539 of the first substrate 100 is formed over a pixel region of two rows×two columns, and has a substantially square planar shape (FIG. 35), as described in the above embodiments. For example, in each pixel sharing unit 539, the horizontal portions TGb of the transfer gates TG1 and TG3 of the pixel 541A and the pixel 541C of one pixel column extend in the direction from the position overlapping the vertical portion TGa toward the central portion of the pixel sharing unit 539 in the H direction (more specifically, a direction toward the outer edges of the pixels 541A and 541C and a direction toward the central portion of the pixel sharing unit 539), and the horizontal portions TGb of the transfer gates TG2 and TG4 of the pixel 541B and the pixel 541D of the other pixel column extend in the direction from the position overlapping the vertical portion TGa toward the outside of the pixel sharing unit 539 in the H direction (more specifically, a direction toward the outer edges of the pixels 541B and 541D and a direction toward the outside of the pixel sharing unit 539). The pad portion 120 connected to the floating diffusion FD is provided at a central portion of the pixel sharing unit 539 (a central portion of the pixel sharing unit 539 in the H direction and the V direction), and the pad portion 121 connected to the VSS contact region 118 is provided at an end portion of the pixel sharing unit 539 at least in the H direction (in the H direction and the V direction in FIG. 35).

As another arrangement example, it is also conceivable to provide the horizontal portions TGb of the transfer gates TG1, TG2, TG3, and TG4 only in a region facing the vertical portion TGa. At this time, the semiconductor layer 200S is likely to be finely divided as described in the above embodiments. Therefore, it is difficult to form a large transistor of the pixel circuit 210. On the other hand, when the horizontal portions TGb of the transfer gates TG1, TG2, TG3, and TG4 are extended in the H direction from the position overlapping the vertical portion TGa as in the above modification, the width of the semiconductor layer 200S can be increased as described in the above embodiments. Specifically, the positions in the H direction of the through electrodes TGV1 and TGV3 connected to the transfer gates TG1 and TG3 can be arranged close to the position in the H direction of the through electrode 120E, and the positions in the H direction of the through electrodes TGV2 and TGV4 connected to the transfer gates TG2 and TG4 can be arranged close to the position in the H direction of the through electrode 121E (FIG. 37). As a result, the width (size in the H direction) of the semiconductor layer 200S extending in the V direction can be increased as described in the above embodiments. Therefore, it is possible to increase the size of the transistor of the pixel circuit 210, particularly, the size of the amplification transistor AMP. As a result, the signal/noise ratio of the pixel signal is improved, and the solid-state imaging device 1 can output better pixel data (image information).

The pixel sharing unit 539 of the second substrate 200 has, for example, substantially the same size in the H direction and the V direction as that of the pixel sharing unit 539 of the first substrate 100, and is provided over, for example, a region corresponding to a pixel region of approximately two rows x two columns. For example, in each pixel circuit 210, the selection transistor SEL and the amplification transistor AMP are arranged side by side in the V direction in one semiconductor layer 200S extending in the V direction, and the FD conversion gain switching transistor FDG and the reset transistor RST are arranged side by side in the V direction in one semiconductor layer 200S extending in the V direction. One semiconductor layer 200S provided with the selection transistor SEL and the amplification transistor AMP and one semiconductor layer 200S provided with the FD conversion gain switching transistor FDG and the reset transistor RST are arranged in the H direction via the insulating region 212. The insulating region 212 extends in the V direction (FIG. 36).

Here, the outer shape of the pixel sharing unit 539 of the second substrate 200 will be described with reference to FIGS. 36 and 37. For example, the pixel sharing unit 539 of the first substrate 100 illustrated in FIG. 35 is connected to the amplification transistor AMP and the selection transistor SEL provided on one side (the left side on the paper surface of FIG. 37) of the pad portion 120 in the H direction, and the FD conversion gain switching transistor FDG and the reset transistor RST provided on the other side (the right side on the paper surface of FIG. 37) of the pad portion 120 in the H direction. The outer shape of the pixel sharing unit 539 of the second substrate 200 including the amplification transistor AMP, the selection transistor SEL, the FD conversion gain switching transistor FDG, and the reset transistor RST is determined by the following four outer edges.

The first outer edge is an outer edge of one end (end on the upper side on the paper surface of FIG. 37) in the V direction of the semiconductor layer 200S including the selection transistor SEL and the amplification transistor AMP. The first outer edge is provided between the amplification transistor AMP included in the pixel sharing unit 539 and the selection transistor SEL included in the pixel sharing unit 539 adjacent to one side (the upper side on the paper surface of FIG. 37) of the pixel sharing unit 539 in the V direction. More specifically, the first outer edge is provided at the central portion in the V direction of the element isolation region 213 between the amplification transistor AMP and the selection transistor SEL. The second outer edge is an outer edge of the other end (the lower side on the paper surface of FIG. 37) in the V direction of the semiconductor layer 200S including the selection transistor SEL and the amplification transistor AMP. The second outer edge is provided between the selection transistor SEL included in the pixel sharing unit 539 and the amplification transistor AMP included in the pixel sharing unit 539 adjacent to the other side (the lower side on the paper surface of FIG. 37) of the pixel sharing unit 539 in the V direction. More specifically, the second outer edge is provided at the central portion in the V direction of the element isolation region 213 between the selection transistor SEL and the amplification transistor AMP. The third outer edge is an outer edge of the other end (the lower side on the paper surface of FIG. 37) in the V direction of the semiconductor layer 200S including the reset transistor RST and the FD conversion gain switching transistor FDG. The third outer edge is provided between the FD conversion gain switching transistor FDG included in the pixel sharing unit 539 and the reset transistor RST included in the pixel sharing unit 539 adjacent to the other side (the lower side on the paper surface of FIG. 37) of the pixel sharing unit 539 in the V direction. More specifically, the third outer edge is provided at the central portion in the V direction of the element isolation region 213 between the FD conversion gain switching transistor FDG and the reset transistor RST. The fourth outer edge is an outer edge of one end (the upper side on the paper surface of FIG. 37) in the V direction of the semiconductor layer 200S including the reset transistor RST and the FD conversion gain switching transistor FDG. The fourth outer edge is provided between the reset transistor RST included in the pixel sharing unit 539 and the FD conversion gain switching transistor FDG (not illustrated) included in the pixel sharing unit 539 adjacent to one side (the upper side on the paper surface of FIG. 37) of the pixel sharing unit 539 in the V direction. More specifically, the fourth outer edge is provided at the central portion in the V direction of the element isolation region 213 (not illustrated) between the reset transistor RST and the FD conversion gain switching transistor FDG.

In the outer shape of the pixel sharing unit 539 of the second substrate 200 including such first, second, third, and fourth outer edges, the third and fourth outer edges are arranged to be shifted to one side in the V direction (in other words, offset to one side in the V direction) with respect to the first and second outer edges. By using such a layout, both the gate of the amplification transistor AMP and the source of the FD conversion gain switching transistor FDG can be arranged as close as possible to the pad portion 120. Therefore, the area of the wiring connecting them is reduced, and the solid-state imaging device 1 can be easily miniaturized. Note that the VSS contact region 218 is provided between the semiconductor layer 200S including the selection transistor SEL and the amplification transistor AMP and the semiconductor layer 200S including the reset transistor RST and the FD conversion gain switching transistor FDG. For example, the plurality of pixel circuits 210 has the same arrangement.

The solid-state imaging device 1 including such a second substrate 200 can also obtain effects similar to those described in the above embodiments. The arrangement of the pixel sharing unit 539 of the second substrate 200 is not limited to the arrangement described in the above embodiments and the present modification.

### <4. Modification 3>

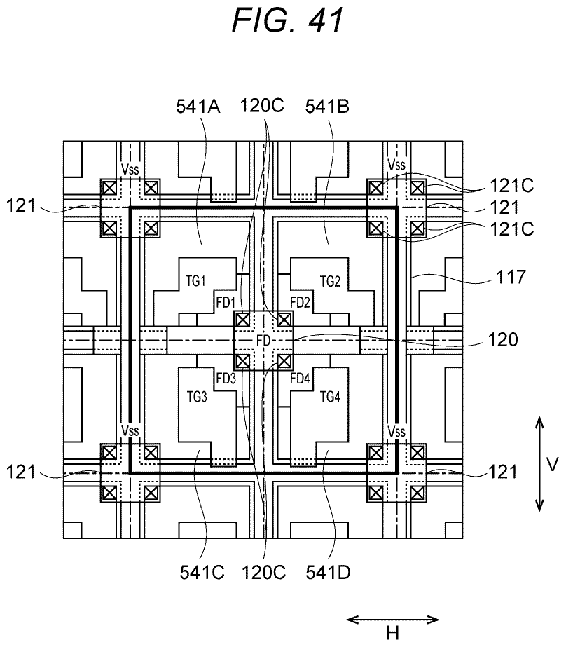

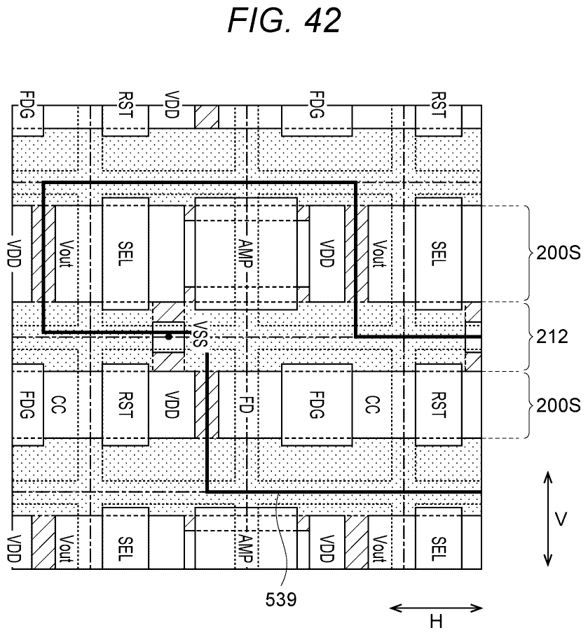

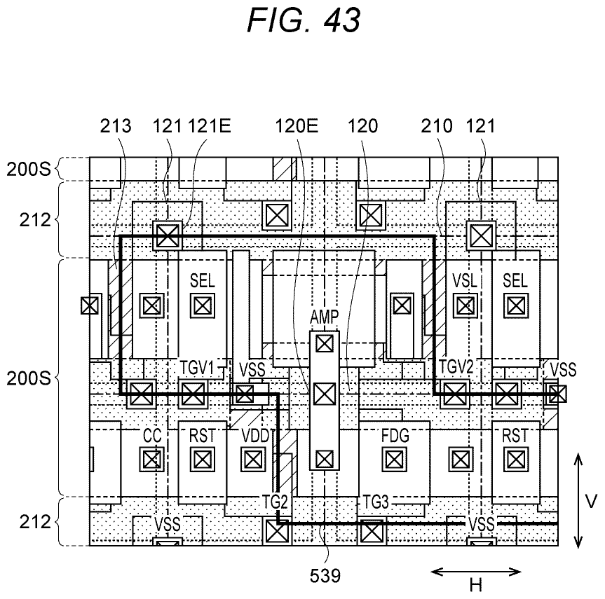

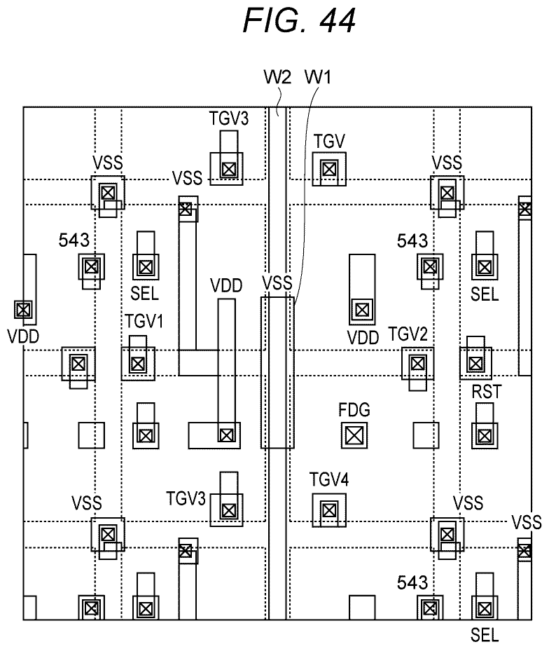

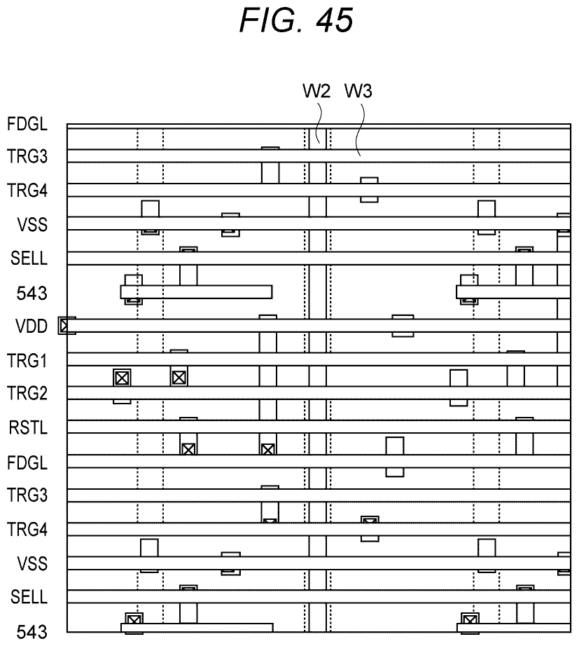

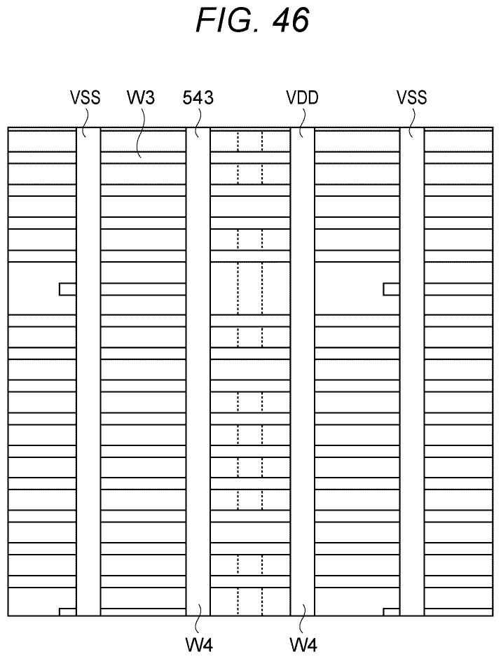

FIGS. 41 to 46 illustrate a modification of the planar configuration of the solid-state imaging device 1 according to the above embodiments. FIG. 41 schematically illustrates a planar configuration of the first substrate 100, and corresponds to FIG. 22B described in the above embodiments. FIG. 42 schematically illustrates a planar configuration in the vicinity of the surface of the semiconductor layer 200S of the second substrate 200, and corresponds to FIG. 23 described in the above embodiments. FIG. 43 schematically illustrates a configuration of each part of the first wiring layer W1, the semiconductor layer 200S connected to the first wiring layer W1, and the first substrate 100, and corresponds to FIG. 24 described in the above embodiments. FIG. 44 illustrates an example of a planar configuration of the first wiring layer W1 and the second wiring layer W2, and corresponds to FIG. 25 described in the above embodiments. FIG. 45 illustrates an example of a planar configuration of the second wiring layer W2 and the third wiring layer W3, and corresponds to FIG. 26 described in the above embodiments. FIG. 46 illustrates an example of a planar configuration of the third wiring layer W3 and the fourth wiring layer W4, and corresponds to FIG. 27 described in the above embodiments.

In the present modification, the semiconductor layer 200S of the second substrate 200 extends in the H direction (FIG. 43). That is, it substantially corresponds to the configuration in which the planar configuration of the solid-state imaging device 1 illustrated in FIG. 36 described above and the like is rotated by 90 degrees.

For example, the pixel sharing unit 539 of the first substrate 100 is formed over a pixel region of two rows x two columns, and has a substantially square planar shape (FIG. 41), as described in the above embodiments. For example, in each pixel sharing unit 539, the transfer gates TG1 and TG2 of the pixel 541A and the pixel 541B of one pixel row extend toward the central portion of the pixel sharing unit 539 in the V direction, and the transfer gates TG3 and TG4 of the pixel 541C and the pixel 541D of the other pixel row extend in the outer direction of the pixel sharing unit 539 in the V direction. The pad portion 120 connected to the floating diffusion FD is provided at a central portion of the pixel sharing unit 539, and the pad portion 121 connected to the VSS contact region 118 is provided at an end portion of the pixel sharing unit 539 at least in the V direction (in the V direction and the H direction in FIG. 41). At this time, the positions in the V direction of the through electrodes TGV1 and TGV2 of the transfer gates TG1 and TG2 approach the positions in the V direction of the through electrode 120E, and the positions in the V direction of the through electrodes TGV3 and TGV4 of the transfer gates TG3 and TG4 approach the positions in the V direction of the through electrode 121E (FIG. 43). Therefore, the width (the size in the V direction) of the semiconductor layer 200S extending in the H direction can be increased for reasons similar to those described in the above embodiments. Therefore, it is possible to increase the size of the amplification transistor AMP and suppress noise.

In each pixel circuit 210, the selection transistor SEL and the amplification transistor AMP are arranged side by side in the H direction, and the reset transistor RST is arranged at a position adjacent in the V direction with the selection transistor SEL and the insulating region 212 interposed therebetween (FIG. 42). The FD conversion gain switching transistor FDG is arranged side by side with the reset transistor RST in the H direction. The VSS contact region 218 is provided in an island shape in the insulating region 212. For example, the third wiring layer W3 extends in the H direction (FIG. 45), and the fourth wiring layer W4 extends in the V direction (FIG. 46).

The solid-state imaging device 1 including such a second substrate 200 can also obtain effects similar to those described in the above embodiments. The arrangement of the pixel sharing unit 539 of the second substrate 200 is not limited to the arrangement described in the above embodiments and the present modification. For example, the semiconductor layer 200S described in the above embodiments and Modification 1 may extend in the H direction.

### <5. Modification 4>

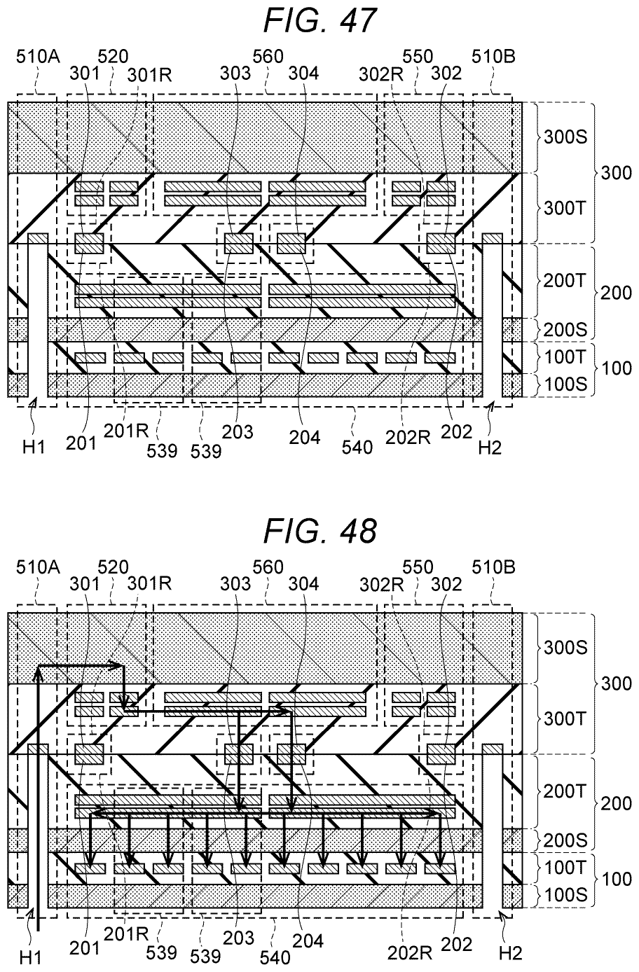

FIG. 47 schematically illustrates a modification of the cross-sectional configuration of the solid-state imaging device 1 according to the above embodiments. FIG. 47 corresponds to FIG. 18 described in the above embodiments. In the present modification, in addition to the contact portions 201, 202, 301, and 302, the solid-state imaging device 1 includes contact portions 203, 204, 303, and 304 at a position facing the central portion of the pixel array unit 540. In this respect, the solid-state imaging device 1 of the present modification is different from the solid-state imaging device 1 described in the above embodiments.

The contact portions 203 and 204 are provided on the second substrate 200, and a bonding surface with the third substrate 300 is exposed. The contact portions 303 and 304 are provided on the third substrate 300 and is exposed on a bonding surface with the second substrate 200. The contact portion 203 is in contact with the contact portion 303, and the contact portion 204 is in contact with the contact portion 304. That is, in the solid-state imaging device 1, the second substrate 200 and the third substrate 300 are connected by the contact portions 203, 204, 303, and 304 in addition to the contact portions 201, 202, 301, and 302.

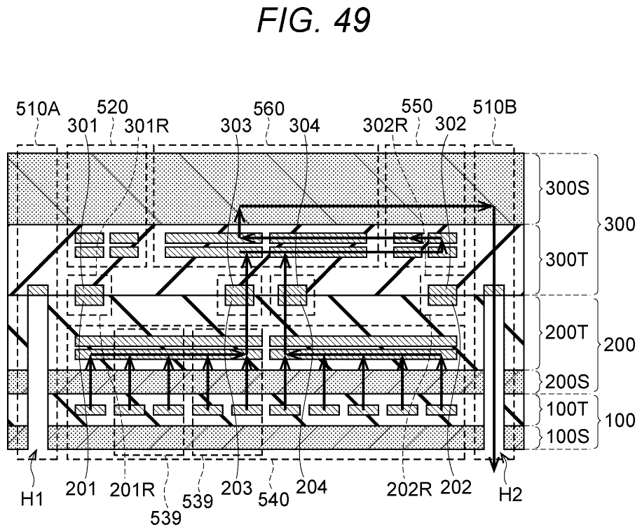

Next, the operation of the solid-state imaging device 1 will be described with reference to FIGS. 48 and 49. In FIG. 48, an input signal input to the solid-state imaging device 1 from the outside, and paths of a power supply potential and a reference potential are indicated by arrows. In FIG. 49, a signal path of a pixel signal output from the solid-state imaging device 1 to the outside is represented by an arrow. For example, an input signal input to the solid-state imaging device 1 via the input unit 510A is transmitted to the row drive unit 520 of the third substrate 300, and the row drive unit 520 creates a row drive signal. The row drive signal is sent to the second substrate 200 via the contact portions 303 and 203. Moreover, the row drive signal reaches each of the pixel sharing units 539 of the pixel array unit 540 via the row drive signal line 542 in the wiring layer 200T. Among the row drive signals reaching the pixel sharing unit 539 of the second substrate 200, drive signals other than the transfer gate TG are input to the pixel circuit 210, and each transistor included in the pixel circuit 210 is driven. A drive signal of the transfer gate TG is input to the transfer gates TG1, TG2, TG3, and TG4 of the first substrate 100 via the through electrode TGV, and the pixels 541A, 541B, 541C, and 541D are driven. Furthermore, the power supply potential and the reference potential supplied from the outside of the solid-state imaging device 1 to the input unit 510A (input terminal 511) of the third substrate 300 are sent to the second substrate 200 via the contact portions 303 and 203, and supplied to the pixel circuit 210 of each of the pixel sharing units 539 via the wiring in the wiring layer 200T. The reference potential is further supplied to the pixels 541A, 541B, 541C, and 541D of the first substrate 100 via the through electrode 121E. On the other hand, the pixel signal photoelectrically converted by the pixels 541A, 541B, 541C, and 541D of the first substrate 100 is sent to the pixel circuit 210 of the second substrate 200 for each pixel sharing unit 539. The pixel signal based on this pixel signal is sent from the pixel circuit 210 to the third substrate 300 via the vertical signal line 543 and the contact portions 204 and 304. This pixel signal is processed by the column signal processing unit 550 and the image signal processing unit 560 of the third substrate 300, and then output to the outside via the output unit 510B.

The solid-state imaging device 1 including such contact portions 203, 204, 303, and 304 can also obtain effects similar to those described in the above embodiments. The position, the number, and the like of the contact portions can be changed according to the design of the circuit or the like of the third substrate 300 to which the wiring is connected via the contact portions 303 and 304.

### <6. Modification 5>

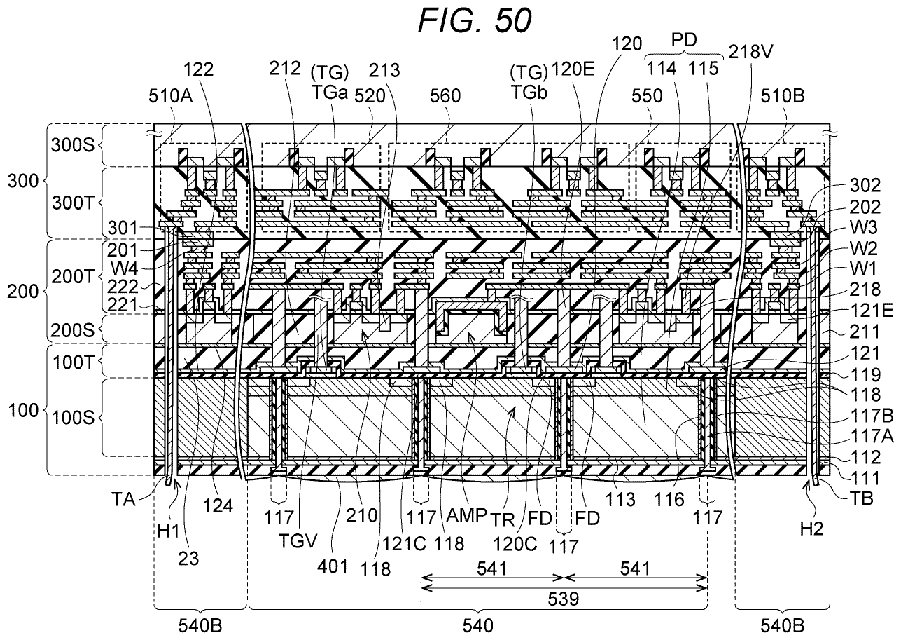

FIG. 50 illustrates a modification of the cross-sectional configuration of the solid-state imaging device 1 according to the above embodiments. FIG. 50 corresponds to FIG. 21 described in the above embodiments. In the present modification, the transfer transistor TR having a planar structure is provided on the first substrate 100. In this respect, the solid-state imaging device 1 of the present modification is different from the solid-state imaging device 1 described in the above embodiments.

In the transfer transistor TR, the transfer gate TG is configured only by the horizontal portion TGb. In other words, the transfer gate TG does not have the vertical portion TGa, and is provided to face the semiconductor layer 100S.

The solid-state imaging device 1 including the transfer transistor TR having such a planar structure can also obtain effects similar to those described in the above embodiments. Moreover, it is also conceivable to form the photodiode PD closer to the surface of the semiconductor layer 100S by providing the planar transfer gate TG on the first substrate 100 as compared with the case where the vertical transfer gate TG is provided on the first substrate 100, thereby increasing the Saturation signal amount (Qs). In addition, it can be considered that the method of forming the planar transfer gate TG on the first substrate 100 has a smaller number of manufacturing processes than the method of forming the vertical transfer gate TG on the first substrate 100, and the photodiode PD is less likely to be adversely affected due to the manufacturing process.

### <7. Modification 6>

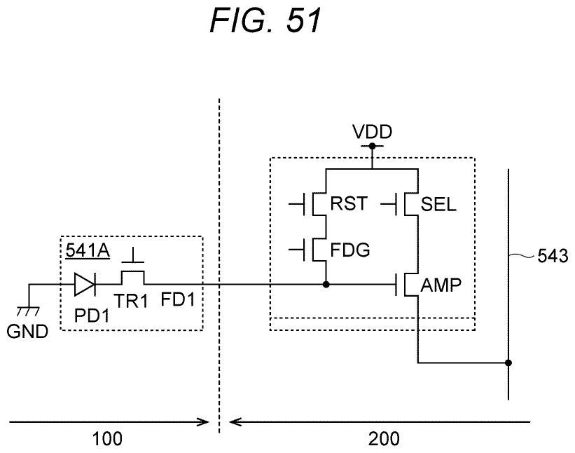

FIG. 51 illustrates a modification of the pixel circuit of the solid-state imaging device 1 according to the above embodiments. FIG. 51 corresponds to FIG. 19 described in the above embodiments. In the present modification, the pixel circuit 210 is provided for each pixel (pixel 541A). That is, the pixel circuit 210 is not shared by a plurality of pixels. In this respect, the solid-state imaging device 1 of the present modification is different from the solid-state imaging device 1 described in the above embodiments.

The solid-state imaging device 1 of the present modification is the same as the solid-state imaging device 1 described in the above embodiments in that the pixel 541A and the pixel circuit 210 are provided on different substrates (the first substrate 100 and the second substrate 200). Therefore, the solid-state imaging device 1 according to the present modification can also obtain effects similar to those described in the above embodiments.

### <8. Modification 7>

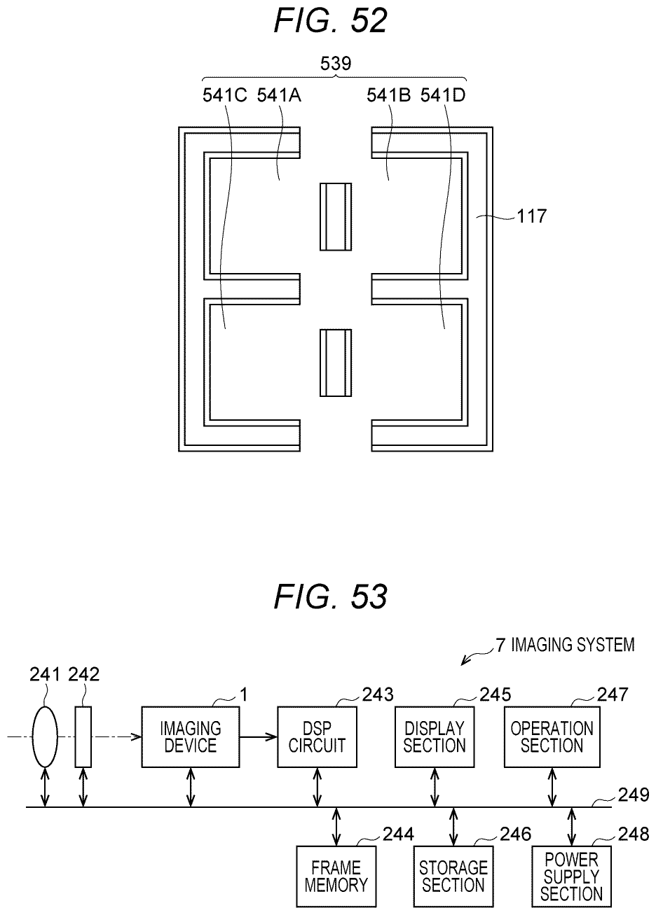

FIG. 52 illustrates a modification of the planar configuration of the pixel isolation portion 117 described in the above embodiments. A gap may be provided in the pixel isolation portion 117 surrounding each of the pixels 541A, 541B, 541C, and 541D. That is, the entire circumference of the pixels 541A, 541B, 541C, and 541D need not be surrounded by the pixel isolation portion 117. For example, the gap of the pixel isolation portion 117 is provided in the vicinity of the pad portions 120 and 121 (see FIG. 22B).

In the above embodiments, the example in which the pixel isolation portion 117 has the FTI structure penetrating the semiconductor layer 100S (see FIG. 21) has been described, but the pixel isolation portion 117 may have a configuration other than the FTI structure. For example, the pixel isolation portion 117 may not be provided so as to completely penetrate the semiconductor layer 100S, and may have a so-called deep trench isolation (DTI) structure.

### 9. Application Example

FIG. 53 illustrates an example of a schematic configuration of an imaging system 7 including the solid-state imaging device 1 according to one of the above embodiments and the modifications thereof.

The imaging system 7 is, for example, an electronic device such as an imaging apparatus such as a digital still camera or a video camera, or a portable terminal apparatus such as a smartphone or a tablet terminal. The imaging system 7 includes, for example, the solid-state imaging device 1 according to one of the above-described embodiments and the modifications thereof, a DSP circuit 243, a frame memory 244, a display section 245, a storage section 246, an operation section 247, and a power supply section 248. In the imaging system 7, the solid-state imaging device 1 according to one of the above-described embodiments and the modifications thereof, the DSP circuit 243, the frame memory 244, the display section 245, the storage section 246, the operation section 247, and the power supply section 248 are connected to each other via a bus line 249.

The solid-state imaging device 1 according to one of the above-described embodiments and the modification thereof outputs image data according to incident light. The DSP circuit 243 is a signal processing circuit that processes a signal (image data) output from the solid-state imaging device 1 according to one of the above-described embodiments and the modifications thereof. The frame memory 244 temporarily holds the image data processed by the DSP circuit 243 in units of frames. The display section 245 includes, for example, a panel-type display apparatus such as a liquid crystal panel or an organic electro luminescence (EL) panel, and displays a moving image or a still image captured by the solid-state imaging device 1 according to one of the above-described embodiments and the modifications thereof. The storage section 246 records image data of a moving image or a still image captured by the solid-state imaging device 1 according to one of the above-described embodiments and the modifications thereof in a recording medium such as a semiconductor memory or a hard disk. The operation section 247 issues operation commands for various functions of the imaging system 7 in accordance with an operation by the user. The power supply section 248 appropriately supplies various power supplies serving as operation power supplies of the solid-state imaging device 1 according to one of the above-described embodiments and the modifications thereof, the DSP circuit 243, the frame memory 244, the display section 245, the storage section 246, and the operation section 247 to these supply targets.

Next, an imaging procedure in the imaging system 7 will be described.

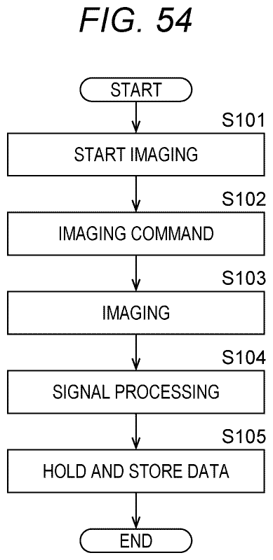

FIG. 54 illustrates an example of a flowchart of an imaging operation in the imaging system 7. The user instructs start of imaging by operating the operation section 247 (step S101).

Then, the operation section 247 transmits an imaging command to the solid-state imaging device 1 (step S102). Upon receiving the imaging command, the solid-state imaging device 1 executes imaging by a predetermined imaging method (step S103).

The solid-state imaging device 1 outputs image data obtained as a result of the imaging to the DSP circuit 243. Here, the image data is data for all the pixels of the pixel signal generated on the basis of the charge temporarily held in the floating diffusion FD. The DSP circuit 243 performs predetermined signal processing (for example, noise reduction processing or the like) on the basis of the image data inputted from the solid-state imaging device 1 (step S104). The DSP circuit 243 causes the frame memory 244 to hold the image data subjected to predetermined signal processing, and the frame memory 244 causes the storage section 246 to store the image data (step S105). In this manner, imaging in the imaging system 7 is performed.

In the present application example, the solid-state imaging device 1 according to one of the above-described embodiments and the modifications thereof is applied to the imaging system 7. As a result, since the solid-state imaging device 1 can be reduced in size or increased in definition, it is possible to provide a small or high-definition imaging system 7.

### 10. Application Examples

### Application Example 1

The technology according to the present disclosure (present technology) can be applied to various products. For example, the technology of the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

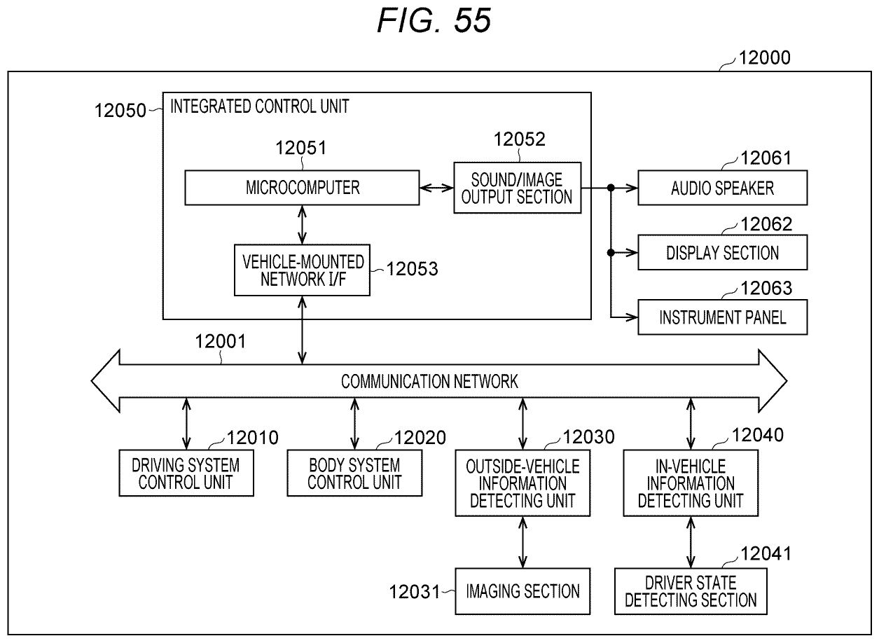

FIG. 55 is a block diagram illustrating a schematic configuration example of a vehicle control system which is an example of a mobile body control system to which the technology according to the present disclosure may be applied.

The vehicle control system 12000 includes a plurality of electronic control units connected to each other via a communication network 12001. In the example illustrated in FIG. 55, the vehicle control system 12000 is provided with a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 55, as the output device, an audio speaker 12061, a display section 12062, and an instrument panel 12063 are illustrated. The display section 12062 may, for example, include at least one of an on-board display and a head-up display.

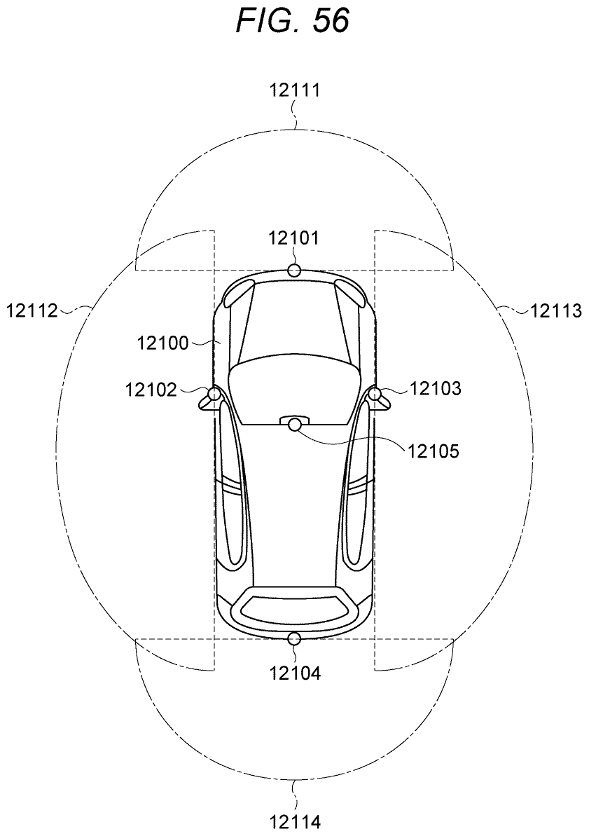

FIG. 56 is a view illustrating an example of an installation position of the imaging section 12031.

In FIG. 56, a vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided on the rear bumper or the rear door principally obtains an image behind the vehicle 12100. The forward images obtained by the imaging sections 12101 and 12105 are used mainly to detect a preceding vehicle, a pedestrian, an obstacle, a traffic signal, a traffic sign, a lane, or the like.

Note that, in FIG. 56, an example of imaging ranges of the imaging sections 12101 to 12104 is illustrated. An imaging range 12111 indicates an imaging range of the imaging section 12101 provided at the front nose, imaging ranges 12112 and 12113 indicate imaging ranges of the imaging sections 12102 and 12103 each provided at the side mirrors, and an imaging range 12114 indicates an imaging range of the imaging section 12104 provided at the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour) . Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is higher than or equal to a set value and there is thus a possibility of collision, the microcomputer 12051 can output a warning to the driver via the audio speaker 12061 or the display section 12062 and perform forced deceleration or avoidance steering via the driving system control unit 12010 to perform driving assistance for collision avoidance.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the moving body control system to which the technology according to the present disclosure can be applied has been described above. The technology of the present disclosure can be applied to the imaging section 12031 among the configurations described above. Specifically, the solid-state imaging device 1 according to one of the above-described embodiments and the modifications thereof can be applied to the imaging section 12031. By applying the technology according to the present disclosure to the imaging section 12031, it is possible to obtain a high-definition captured image with little noise, and thus, it is possible to perform high-accuracy control using the captured image in the moving body control system.

### Application Example 2

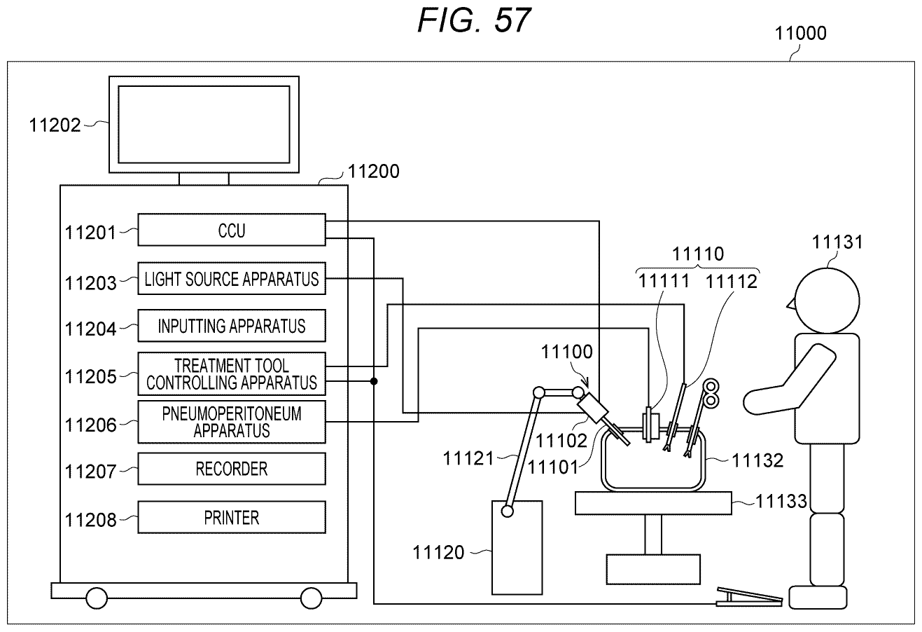

FIG. 57 is a view illustrating an example of a schematic configuration of an endoscopic surgery system to which the technology according to an embodiment of the present disclosure (present technology) can be applied.

In FIG. 57, a state is depicted in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Moreover, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as a light emitting diode (LED), for example, and supplies irradiation light for imaging a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, r green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be output is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

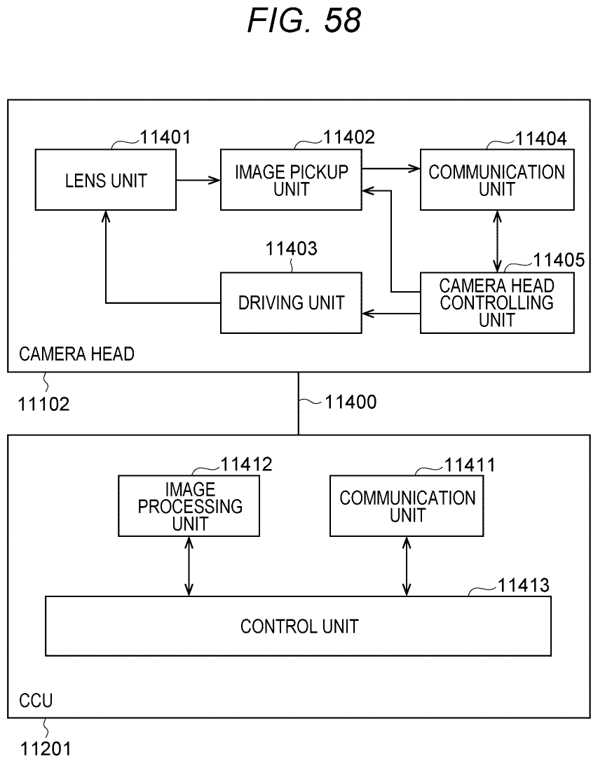

FIG. 58 is a block diagram illustrating an example of a functional configuration of the camera head 11102 and the CCU 11201 illustrated in FIG. 57.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals corresponding to three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Furthermore, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be suitably applied to the image pickup unit 11402 provided in the camera head 11102 of the endoscope 11100 among the above-described configurations. By applying the technology according to the present disclosure to the image pickup unit 11402, the image pickup unit 11402 can be downsized or high definition, so that the endoscope 11100 having a small size or high definition can be provided.

Although the present disclosure has been described with reference to the embodiments, the modifications, application examples, and applied examples thereof above, the present disclosure is not limited to the embodiments and the like, and various modifications can be made. Note that the effects described in the present specification are merely examples. The effects of the present disclosure are not limited to the effects described herein. The present disclosure may have effects other than those described herein.

In addition, for example, the present disclosure may also have the following configuration.

(1)

Amplifier circuit including: an active load; and
a plurality of input transistors electrically connected to the active load, in which
gates of the plurality of input transistors are electrically connected to each other, and
the plurality of input transistors includes two or more input transistors connected in series with each other.
   (2)

The amplifier circuit according to (1), in which the two or more input transistors include a first input transistor and a second input transistor having a drain electrically connected to a source of the first input transistor.

(3)

The amplifier circuit according to (2), in which the two or more input transistors further include a third input transistor having a drain electrically connected to a source of the second input transistor.

(4)

The amplifier circuit according to (2), in which an active region that functions as the source of the first input transistor is an active region different from an active region that functions as the drain of the second input transistor.

(5)

The amplifier circuit according to (2), in which an active region that functions as the source of the first input transistor is a same active region as an active region that functions as the drain of the second input transistor.

(6)

The amplifier circuit according to (1), in which the plurality of input transistors includes two or more input transistors of a first group connected in series with each other and two or more input transistors of a second group connected in series with each other, and
all or a subset of the two or more input transistors of the first group and all or a subset of the two or more input transistors of the second group are connected in parallel to each other.
   (7)

The amplifier circuit according to (1), in which each of the plurality of input transistors has a planar structure or a fin structure.

(8)

The amplifier circuit according to (1), in which the two or more input transistors include a first input transistor and a second input transistor having a gate length different from a gate length of the first input transistor.

(9)

The amplifier circuit according to (8), in which the gate length of the first input transistor is the shortest among the two or more input transistors,
a drain of the first input transistor is electrically connected to the active load and a first power supply, and
a source of the second input transistor is electrically connected to a second power supply.
   (10)

The amplifier circuit according to (9), in which the two or more input transistors are NMOS and a voltage of the first power supply is higher than a voltage of the second power supply, or the two or more input transistors are PMOS and the voltage of the second power supply is higher than the voltage of the first power supply.

(11)

The amplifier circuit according to (8), in which at least one of the two or more input transistors has a voltage threshold different from voltage thresholds of others of the two or more input transistors.

(12)

A comparator including: a first amplifier circuit to which a reference signal is input;
a second amplifier circuit to which a comparison signal is input; and
a tail portion that controls a tail current, the tail portion being electrically connected to the first amplifier circuit and the second amplifier circuit, in which
each of the first amplifier circuit and the second amplifier circuit includes:
an active load; and
a plurality of input transistors electrically connected to the active load,
gates of the plurality of input transistors are electrically connected to each other, and
the plurality of input transistors includes two or more input transistors connected in series with each other.
   (13)

The comparator according to (12), in which the tail portion includes a plurality of transistors electrically connected to the first amplifier circuit and the second amplifier circuit,
gates of the plurality of transistors of the tail portion are electrically connected to each other, and
the plurality of transistors of the tail portion includes two or more transistors connected in series with each other.
   (14)

A solid-state imaging device including: a pixel array in which a plurality of pixels each including a photoelectric conversion unit is arranged in a matrix; and
an AD conversion unit that converts pixel signals output from the pixels of the pixel array from analog signals to digital signals, the AD conversion unit including a comparator, in which
the comparator includes:
a first amplifier circuit to which a reference signal is input;
a second amplifier circuit to which the analog signal is input as a comparison signal; and
a tail portion that controls a tail current, the tail portion being electrically connected to the first amplifier circuit and the second amplifier circuit,
each of the first amplifier circuit and the second amplifier circuit includes:
an active load; and
a plurality of input transistors electrically connected to the active load,
gates of the plurality of input transistors are electrically connected to each other, and
the plurality of input transistors includes two or more input transistors connected in series with each other.
   (15)

The solid-state imaging device according to (14), further including: a first substrate provided with the photoelectric conversion unit and a pixel transistor; and
a second substrate provided with the comparator.
   (16)

The solid-state imaging device according to (14), further including:
a first substrate provided with the photoelectric conversion unit; and
a second substrate provided with a pixel transistor and the comparator, in which
the first substrate and the second substrate are stacked on each other with an insulating layer interposed therebetween.
   (17)

The solid-state imaging device according to (16), in which the first substrate is disposed on the second substrate.

(18)

The solid-state imaging device according to (14), further including: a first substrate provided with the photoelectric conversion unit;
a second substrate provided with a pixel transistor; and
a third substrate provided with the comparator, in which
the first substrate and the second substrate are stacked on each other with an insulating layer interposed therebetween.
   (19)

The solid-state imaging device according to (18), in which the first substrate is disposed on the second substrate, and the second substrate is disposed on the third substrate.

(20)

The solid-state imaging device according to (14), in which the solid-state imaging device is provided in an electronic device that receives data output from the solid-state imaging device.

### REFERENCE SIGNS LIST

1 Solid-state imaging device
2 Amplifier circuit
3 Input transistor
3a Input transistor
3b Input transistor
3c Input transistor
3a′ Input transistor
3b′ Input transistor
3c′ Input transistor
4 Active load
5 Comparator
6a First power supply
6b Second power supply
7 Imaging system
8 Reference signal amplifier circuit
9 Comparison signal amplifier circuit
10 Tail current control transistor
11 Pixel
11a Pixel
11b Pixel
11c Pixel
11d Pixel
12 Pixel sharing unit
13 Counter circuit
14 Ramp generator
24 Filter layer
25 On-chip lens layer
26 Through plug
31 Semiconductor substrate
31a N-type region
31b P-type region
31c Floating diffusion portion
32 Element isolation insulating film
33 Gate insulating film
34 Gate electrode
35 Electrode portion
36 Interlayer insulating film
41 Semiconductor substrate
41a Diffusion region
42 Gate insulating film
43 Gate electrode
44 Interlayer insulating film
45 Interlayer insulating film
46a Plug
46b Plug
46c Plug
46d Plug
47a Wiring layer
47b Wiring layer
47c Wiring layer
48 Pad
51 Semiconductor substrate
51a Diffusion region
52 Gate insulating film
53 Gate electrode
54 Interlayer insulating film
55 Interlayer insulating film
56a Plug
56b Plug
56c Plug
57a Wiring layer
57b Wiring layer
58 Pad
62 Active load
63 Differential pair circuit
70 Photoelectric conversion unit
71 Pixel transistor
72 Pixel
73 Pixel array
74 Logic circuit
80 Gate
81 Drain
82 Source
83 Gate insulating film
84 Insulating film
85 Silicon substrate
86 Wiring
87 Active region
89 Contact plug
90 Gate electrode
91 Gate insulating film
92 Sidewall insulating film
93 Interlayer insulating film
94 Substrate
100 First substrate
100S Semiconductor layer
100T Wiring layer
111 Insulating film
112 Fixed charge film
113 First pinning region
114 N-type semiconductor region
115 P-well layer
116 Second pinning region
117 Pixel isolation portion
117A Light shielding film
117B Insulating film
118 VSS contact region
119 Interlayer insulating film
120 Pad portion
121 Pad portion
120C Connection via
120E Through electrode
121C Connection via
121E Through electrode
122 Passivation film
123 Interlayer insulating film
124 Bonding film
200 Second substrate
200S Semiconductor layer
200T Wiring layer
201 Contact portion
201R Contact region
202R Contact region
202 Contact portion
203 Contact portion
204 Contact portion
210 Pixel circuit
211 Well region
212 Insulating region
213 Element isolation region
218 VSS contact region
218V Connection portion
221 Passivation film
222 Interlayer insulating film
243 DSP circuit
244 Frame memory
245 Display section
246 Storage section
247 Operation section
248 Power supply section
249 Bus line
300 Third substrate
300S Semiconductor layer
300T Wiring layer
301 Contact portion
301R Contact region
302 Contact portion
302R Contact region
303 Contact portion
304 Contact portion
401 Light receiving lens
510A Input unit
510B Output unit
511 Input terminal
512 Input circuit section
513 Input amplitude changing section
514 Input data conversion circuit section
515 Output data conversion circuit section
516 Output amplitude changing section
517 Output circuit section
518 Output terminal
520 Row drive unit
530 Timing control unit
539 Pixel sharing unit
540 Pixel array unit
540B Peripheral portion
541A Pixel
541B Pixel
541C Pixel
541D Pixel
542 Row drive signal line
543 Vertical signal line
550 Column signal processing unit
560 Image signal processing unit
TR Transfer transistor
TG Transfer gate
RST Reset transistor
AMP Amplification transistor
SEL Selection transistor
FDG FD conversion gain switching transistor
FD Floating diffusion
PD Photodiode
TGV Through electrode
W1 First wiring layer
W2 Second wiring layer
W3 Third wiring layer
W4 Fourth wiring layer
SELL Wiring
RSTL Wiring
FDGL Wiring
H1 Connection hole
H2 Connection hole
TA External terminal
TB External terminal

1. Amplifier circuit comprising:
an active load; and
a plurality of input transistors electrically connected to the active load, wherein
gates of the plurality of input transistors are electrically connected to each other, and
the plurality of input transistors includes two or more input transistors connected in series with each other.

2. The amplifier circuit according to claim 1, wherein the two or more input transistors include a first input transistor and a second input transistor having a drain electrically connected to a source of the first input transistor.

3. The amplifier circuit according to claim 2, wherein the two or more input transistors further include a third input transistor having a drain electrically connected to a source of the second input transistor.

4. The amplifier circuit according to claim 2, wherein an active region that functions as the source of the first input transistor is an active region different from an active region that functions as the drain of the second input transistor.

5. The amplifier circuit according to claim 2, wherein an active region that functions as the source of the first input transistor is a same active region as an active region that functions as the drain of the second input transistor.

6. The amplifier circuit according to claim 1, wherein the plurality of input transistors includes two or more input transistors of a first group connected in series with each other and two or more input transistors of a second group connected in series with each other, and
all or a subset of the two or more input transistors of the first group and all or a subset of the two or more input transistors of the second group are connected in parallel to each other.

7. The amplifier circuit according to claim 1, wherein each of the plurality of input transistors has a planar structure or a fin structure.

8. The amplifier circuit according to claim 1, wherein the two or more input transistors include a first input transistor and a second input transistor having a gate length different from a gate length of the first input transistor.

9. The amplifier circuit according to claim 8, wherein the gate length of the first input transistor is the shortest among the two or more input transistors,
a drain of the first input transistor is electrically connected to the active load and a first power supply, and
a source of the second input transistor is electrically connected to a second power supply.

10. The amplifier circuit according to claim 9, wherein the two or more input transistors are NMOS and a voltage of the first power supply is higher than a voltage of the second power supply, or the two or more input transistors are PMOS and the voltage of the second power supply is higher than the voltage of the first power supply.

11. The amplifier circuit according to claim 8, wherein at least one of the two or more input transistors has a voltage threshold different from voltage thresholds of others of the two or more input transistors.

12. A comparator comprising:
a first amplifier circuit to which a reference signal is input;
a second amplifier circuit to which a comparison signal is input; and
a tail portion that controls a tail current, the tail portion being electrically connected to the first amplifier circuit and the second amplifier circuit, wherein
each of the first amplifier circuit and the second amplifier circuit includes:
an active load; and
a plurality of input transistors electrically connected to the active load,
gates of the plurality of input transistors are electrically connected to each other, and
the plurality of input transistors includes two or more input transistors connected in series with each other.

13. The comparator according to claim 12, wherein the tail portion includes a plurality of transistors electrically connected to the first amplifier circuit and the second amplifier circuit,
gates of the plurality of transistors of the tail portion are electrically connected to each other, and
the plurality of transistors of the tail portion includes two or more transistors connected in series with each other.

14. A solid-state imaging device comprising:
a pixel array in which a plurality of pixels each including a photoelectric conversion unit is arranged in a matrix; and
an AD conversion unit that converts pixel signals output from the pixels of the pixel array from analog signals to digital signals, the AD conversion unit including a comparator, wherein
the comparator includes:
a first amplifier circuit to which a reference signal is input;
a second amplifier circuit to which the analog signal is input as a comparison signal; and
a tail portion that controls a tail current, the tail portion being electrically connected to the first amplifier circuit and the second amplifier circuit,
each of the first amplifier circuit and the second amplifier circuit includes:
an active load; and
a plurality of input transistors electrically connected to the active load,
gates of the plurality of input transistors are electrically connected to each other, and
the plurality of input transistors includes two or more input transistors connected in series with each other.

15. The solid-state imaging device according to claim 14, further comprising: a first substrate provided with the photoelectric conversion unit and a pixel transistor; and
a second substrate provided with the comparator.

16. The solid-state imaging device according to claim 14, further comprising:
a first substrate provided with the photoelectric conversion unit; and
a second substrate provided with a pixel transistor and the comparator, wherein
the first substrate and the second substrate are stacked on each other with an insulating layer interposed therebetween.

17. The solid-state imaging device according to claim 16, wherein the first substrate is disposed on the second substrate.

18. The solid-state imaging device according to claim 14, further comprising: a first substrate provided with the photoelectric conversion unit;
a second substrate provided with a pixel transistor; and
a third substrate provided with the comparator, wherein
the first substrate and the second substrate are stacked on each other with an insulating layer interposed therebetween.

19. The solid-state imaging device according to claim 18, wherein the first substrate is disposed on the second substrate, and the second substrate is disposed on the third substrate.

20. The solid-state imaging device according to claim 14, wherein the solid-state imaging device is provided in an electronic device that receives image data output from the solid-state imaging device.
